(19) United States
(12) Patent Application Publication
(10) Pub. No.: US 2024/0083764 A1
(43) Pub. Date: Mar. 14, 2024

(54) QLED AND PREPARATION METHOD THEREOF

(71) Applicant: TCL TECHNOLOGY GROUP CORPORATION, Huizhou (CN)

(72) Inventors: Longjia WU, Huizhou (CN); Tianshuo ZHANG, Huizhou (CN); Junjie LI, Huizhou (CN); Yulin GUO, Huizhou (CN); Kai TONG, Huizhou (CN)

(21) Appl. No.: 18/270,609

(22) PCT Filed: Dec. 30, 2021
(86) PCT No.: PCT/CN2021/143433

§ 371 Date: Jun. 30, 2023

(30) Foreign Application Priority Data
Dec. 31, 2020 (CN) 202011636998.6
Dec. 31, 2020 (CN) 202011637282.8
Dec. 31, 2020 (CN) 202011639878.1
Dec. 31, 2020 (CN) 202011640040.4
Dec. 31, 2020 (CN) 202011640060.1
Dec. 31, 2020 (CN) 202011640396.8

(51) Int. Cl. C01G 9/02; C09K 11/88; H10K 85/60

(52) U.S. Cl. CPC C01G 9/02; C09K 11/883; H10K 85/60; C01P 2006/40; H10K 50/165

(57) ABSTRACT

The present application discloses a QLED and a preparation method thereof. The QLED comprises an anode and a cathode being oppositely arranged, a quantum dot luminescent layer arranged between the anode and cathode, and an ETL arranged between the quantum dot luminescent layer and the cathode. Where the ETL includes a first ETL, and the first ETL is a zinc oxide film with a surface hydroxyl content being greater than or equal to 0.6. Or alternatively, the ETL contains zinc oxide, and the surface of at least some of the zinc oxide contains amino ligands and/or carboxyl ligands with 8-18 carbon atoms. The QLED provided in the present application improves an external quantum efficiency of the QLED device effectively.

### CROSS-REFERENCE TO RELATED APPLICATIONS

This application is a 35 U.S.C. § 371 national stage application of PCT patent application No. PCT/CN2021/143433, filed on Dec. 30, 2021, which claims priority to Chinese patent application No. 202011636998.6, filed with CNIPA on Dec. 31, 2020, and entitled “preparation method of QLED”, claims priority to Chinese patent application No. 202011640060.1, filed with CNIPA on Dec. 31, 2020, and entitled “QLED and preparation method thereof”, claims priority to Chinese patent application No. 202011639878.1, filed with CNIPA on Dec. 31, 2020, and entitled “QLED and preparation method thereof”, claims priority to Chinese patent application No. 202011640040.4, filed with CNIPA on Dec. 31, 2020, and entitled “preparation method of QLED”, claims priority to Chinese patent application No. 202011640396.8, filed with CNIPA on Dec. 31, 2020, and entitled “preparation method of QLED”, and claims priority to Chinese patent application No. 202011637282.8, filed with CNIPA on Dec. 31, 2020, and entitled “preparation method of QLED”. The entire contents of these Chinese patent applications which this application claims priority to are incorporated herein by reference.

### FIELD

The present application relates to the field of displaying technologies, and more particularly, to a QLED, a preparation method of the QLED.

### DESCRIPTION OF RELATED ART

Quantum dots (QDs) are a type of nanomaterials composed of a small number of atoms, with radii generally smaller than or approaches to an exciton Bohr radius, QDs reflect significant quantum confinement effects and have unique optical properties. Recently, with the continuous development of displaying technology, QLED (QLED, QLED), which uses a quantum dot material as a luminescent layer, has drawn more and more attentions. QLED has the characteristics of high luminous efficiency, controllable luminous color, high color purity, excellent device stability, and being used for flexible application, and thus has great application prospect in the field such as displaying technology, solid-state lighting, etc.

QLED mainly comprises a cathode, an anode, and a quantum dot luminescent layer. In order to improve device performance, one or more layers of hole transport injection layer, hole transport layer, ETL, and electron injection layer are introduced as functional layer(s) in the QLED. Zinc oxide is taken as a widely used ETL material in QLED, has an excellent energy level matching relationship with the cathode and the quantum dot luminescent layer, and significantly reduces injection barrier of electrons from the cathode to the quantum dot luminescent layer. Moreover, deep valence band energy level of the Zinc oxide can effectively block holes. In addition, zinc oxide material also has excellent electron transfer capability, and an electron mobility of the Zinc oxide material is up to 10⁻³ cm²/V·S. Due to these characteristics, zinc oxide material becomes the most preferable material for the ETL in the QLED device, the stability and the luminous efficiency of the QLED device are significantly improved.

Due to the similarity in the luminescence principles between QLED display technology and organic light-emitting diode (Organic Light-emitting Diode, OLED) display technology, the interpretation of device physics, the selection of functional layer material energy levels, and the matching principles in the QLED device are in compliance with the existing theoretical systems in OLED currently. For example, in order to achieve higher device performance of the OLED device, carrier injection of holes and electrons on two sides of the QLED device needs to be finely regulated to achieve injection balance of carriers in the luminescent layer of the QLED device. When applying the abovementioned classical physics theory of OLED device to QLED device system, considering that an electron mobility of the zinc oxide layer is usually higher than a hole mobility of the hole transport layer, in order to achieve a better injection balance of carriers in the QLED device, the electron mobility of the zinc oxide layer needs to be reduced by using a method such as inserting an electron barrier layer between the quantum dot luminescent layer and the zinc oxide layer. When the above method is applied to the QLED device, the performance of the QLED device, especially the efficiency of the QLED device, has indeed been significantly improved. This method achieves an external quantum efficiency of the QLED device that is greater than 20% and approaches an upper limit of theoretical value.

However, there are certain constraints in the method of inserting the electron barrier layer to change the device structure so as to improve the injection balance of carriers. In one aspect, it is difficult to implement this method in actual device preparation, this method has strict thickness requirements for the electron barrier layer, and it is difficult to achieve effective action when the electron barrier layer is too thick or too thin, the performance of the QLED device may even be reduced due to too thick or too thin thickness of the electron barrier layer. Thus, the thickness of the electron barrier layer is difficult to be controlled in practical operation. In addition, the method of changing the structure of the QLED device (i.e., adding the electron barrier layer) may also increase the cost of preparation of the QLED device, cost burden of mass production of the QLED device in the future will be increased. Thus, it is desirable to seek for a more effective and cost efficient method to reduce the electron mobility of the zinc oxide layer, thereby realizing the injection balance of carriers of the QLED device and improving the external quantum efficiency of the QLED.

### SUMMARY

One of the objectives of the embodiments of the present application is to provide a QLED and a preparation method of the QLED.

The technical solutions adopted in the embodiments of the present application are described below:

In the first aspect, a quantum dot light-emitting diode (QLED), including an anode and a cathode being oppositely arranged, a quantum dot luminescent layer arranged between the anode and cathode, and an electron transport layer (ETL) arranged between the quantum dot luminescent layer and the cathode;
where the ETL includes a first ETL, and the first ETL is a zinc oxide film with a surface hydroxyl content being greater than or equal to 0.6; or alternatively,
the ETL contains zinc oxide, and a surface of at least some of the zinc oxide contains amino ligands and/or carboxyl ligands with 8-18 carbon atoms.

In some embodiments, the ETL is the first ETL, and the zinc oxide in the first ETL is a metal doped zinc oxide or an undoped zinc oxide.

In some embodiments, when the ETL contains the zinc oxide, the ETL comprises the first ETL containing the zinc oxide, and the surface of the zinc oxide forming the first ETL contains the amino ligands and/or the carboxyl ligands with 8-18 carbon atoms.

In some embodiments, the ETL is the first ETL, and the zinc oxide forming the first ETL is an undoped zinc oxide or a metal doped zinc oxide.

In some embodiments, the ETL further comprises a second ETL arranged on a surface of one side of the first ETL adjacent to the cathode or the quantum dot luminescent layer, and the second ETL is a zinc oxide film or a metal doped zinc oxide with a surface hydroxyl content being less than or equal to 0.4.

In some embodiments, the ETL is composed of the first ETL and the second ETL, and the second ETL is more adjacent to the quantum dot luminescent layer as compared to the first ETL.

In some embodiments, the ETL comprises n thin film laminated layer units, each of the n film lamination layer units is composed of the first ETL and the second ETL, wherein n is greater than or equal to 2.

In some embodiments, the ETL further comprises a third ETL.

In some embodiments, the third ETL is a zinc oxide film with a surface hydroxyl content being greater than or equal to 0.6.

In some embodiments, the third ETL is arranged on a surface of a side of the second ETL away from the first ETL, and the second ETL is a zinc oxide film with a surface hydroxyl content less than or equal to 0.4.

In some embodiments, the third ETL is a zinc oxide film with a surface hydroxyl content less than or equal to 0.4.

In some embodiments, the second ETL is a zinc oxide film with a surface hydroxyl content less than or equal to 0.4, and the third ETL is arranged on a surface on one side of the first ETL away from the second ETL; or alternatively,
the second ETL is a metal doped zinc oxide film, and the third ETL is arranged between the second ETL and the first ETL.

In some embodiments, the third ETL is a metal doped zinc oxide film.

In some embodiments, the third ETL is arranged on a surface of one side of the second ETL away from the first ETL.

In some embodiments, the second ETL is a zinc oxide film with a surface hydroxyl content less than or equal to 0.4.

In some embodiments, the third ETL is selected from the zinc oxide film which has the surface bonded with the amino ligands and/or the carboxyl ligands with 8-18 carbon atoms, and the second ETL is bonded to a surface of one side of the first ETL, and the third ETL is bonded to a surface of one side of the second ETL away from the first ETL.

In some embodiments, the amino ligands and/or the carboxyl ligands having the carbon atom number of 8-18 are selected from at least one of octanoic acid, octylamine, dodecanoic acid, dodecylamine, oleic acid, and oleylamine.

In some embodiments, in the zinc oxide film which has the surface bonded with the amino ligands and/or the carboxyl ligands with 8-18 carbon atoms, a molar ratio of the amino ligand and/or the carboxyl ligand having the carbon atom number of 8-18 to the zinc oxide is 1:4-10:1.

In some embodiments, the amino ligands and/or the carboxyl ligands with 8-18 carbon atoms contained in the surface are selected from the amino ligands and/or the carboxyl ligands with 8-12 carbon atoms, and the molar ratio of the amino ligands and/or the carboxyl ligands with 8-12 carbon atoms to the zinc oxide is 1:1-10:1; or alternatively,

the amino ligands and/or the carboxyl ligands with 8-18 carbon atoms contained in the surface are selected from the amino ligands and/or the carboxyl ligands with 13-18 carbon atoms, and the molar ratio of the amino ligands and/or the carboxyl ligands with 13-18 carbon atoms to the zinc oxide is 1:4-5:1.

In some embodiments, a thickness of the ETL ranges from 10 nm to 100 nm; and/or
a thickness of the zinc oxide film with the surface hydroxyl content being greater than or equal to 0.6 ranges from 10 nm to 30 nm; and/or
a thickness of the first ETL ranges from 10 nm to 80 nm.

In some embodiments, a thickness of the zinc oxide film with the surface hydroxyl content less than or equal to 0.4 ranges from 20 nm to 60 nm; or alternatively,
a thickness of the metal doped zinc oxide film ranges from 10 nm to 30 nm.

In some embodiments, quantum dots in the quantum dot luminescent layer are selected from single core quantum dots or core-shell structured quantum dots, and core compounds and shell compounds of the quantum dots are respectively and independently selected from at least one of CdS, CdSe, CdTe, ZnO, ZnS, ZnSe, ZnTe, GaAs, GaP, GaSb, HgS, HgSe, HgTe, InAs, InP, InSb, AlAs, AlP, CuInS, CuInSe, CuInSe, and core-shell structure quantum dots or alloy structure quantum dots formed by the aforesaid substances; and/or
a material of the anode comprises at least one of the zinc oxide, indium oxide, tin oxide, indium tin oxide, indium zinc oxide, and fluorine doped tin oxide; and/or
materials of the cathode are Ag, Al, Au, Mg, Ca, Yb, Ba or alloys thereof.

In some embodiments, the QLED further comprises a hole functional layer arranged in the anode and the quantum dot luminescent layer, and the hole functional layer comprises at least one of a hole injection layer and a hole transport layer.

In some embodiments, a material of the hole injection layer is selected from at least one of poly (ethylenedioxythiophene):polystyrene sulfonate (PEDOT:PSS), HTL-1, and HTL-2; and/or

a material of the hole transport layer is selected from at least one of 4,4′-N,N′-dicarbazolyl biphenyl, poly [(9,9′-dioctylfluoren-2,7-diyl)-co-(4,4′-(N-(4-sec-butylphenyl)diphenylamine)], poly (4-butylphenyl diphenylamine), 4,4′,4′-tri (N-carbazolyl)-triphenylamine, poly (N-vinylcarbazole) and derivatives thereof.

In some embodiments, the doped metal in the metal doped zinc oxide film is selected from at least one of Mg²⁺ and Mn²⁺; or alternatively, the doped metal in the metal doped zinc oxide film is selected from at least one of Al³⁺, Y³⁺, La³⁺, Li⁺, Gd³⁺, Zr⁴⁺, and Ce⁴⁺.

In some embodiments, a doping content of the doped metal is as follows:
when the doped metal is Mg²⁺, a doping molar concentration of Mg²⁺ in the metal doped zinc oxide film is between 0.1% and 35%;
when the doped metal is Mn²⁺, a doping molar concentration of Mn²⁺ in the metal doped zinc oxide film is between 0.1% and 30%;
when the doped metal is Al³⁺, a doping molar concentration of Al³⁺ in the metal doped zinc oxide film is between 0.1% and 15%;
when the doped metal is Y³⁺, a doping molar concentration of Y³⁺ in the metal doped zinc oxide film is between 0.1% and 10%;
when the doped metal is La³⁺, a doping molar concentration of La³⁺ in the metal doped zinc oxide film is between 0.1% and 7%;
when the doped metal is Li⁺, a doping molar concentration of Li⁺ in the metal doped zinc oxide film is between 0.1% and 45%;
when the doped metal is Gd³⁺, a doping molar concentration of Gd³⁺ in the metal doped zinc oxide film is between 0.01% and 8%;
when the doped metal is Zr⁴⁺, a doping molar concentration of Zr⁴⁺ in the metal doped zinc oxide film is between 0.1% and 45%;
when the doped metal is Ce⁴⁺, the doping molar concentration of Ce⁴⁺ in the metal doped zinc oxide film is between 0.1% and 10%.

In the first aspect, some preparation methods of a QLED are provided.

A first preparation method of the QLED, the QLED comprises an anode and a cathode being oppositely arranged, a quantum dot luminescent layer arranged between the anode and cathode, and an electron transport layer (ETL) arranged between the quantum dot luminescent layer and the cathode; wherein the ETL comprises a first ETL, and the first ETL is a zinc oxide film with a surface hydroxyl content being greater than or equal to 0.6;
a preparation method of the zinc oxide film with the surface hydroxyl content being greater than or equal to 0.6, comprises:
mixing a zinc salt solution with a first alkaline solution for reaction, and adding a precipitating agent to the mixed solution to collect a precipitate after the reaction is completed; after cleaning the precipitate two times or less than two times with a reaction solvent, dissolving obtained white precipitate to obtain a zinc oxide colloidal solution;
forming the zinc oxide colloidal solution on a prefabricated device substrate for preparing the zinc oxide film with a surface hydroxyl content being greater than or equal to 0.6, removing a solvent to prepare the zinc oxide film with the surface hydroxyl content being greater than or equal to 0.6.

In some embodiments, an alkali in the first alkaline solution is selected from alkalis with Kb>10⁻¹, and a number of times of cleaning is less than or equal to 2;
the alkali in the first alkaline solution is selected from alkalis with Kb<10⁻¹, and the number of times of cleaning is less than or equal to 1.

In some embodiments, the alkalis with Kb>10⁻¹ is selected from at least one of potassium hydroxide, sodium hydroxide and Lithium hydroxide, and the alkalis with Kb<10⁻¹ is selected from at least one of tetramethylammonium hydroxide (TMAH), ammonium hydroxide, ethanolamine and ethylenediamine.

In some embodiments, the reaction solvent is selected from at least one of water, organic alcohols, organic ethers, and sulfones.

In some embodiments, the reaction solvent is selected from at least one of water, methanol, ethanol, propanol, butanol, ethylene glycol, 2-methoxyethanol and dimethylsulfoxide (DMSO).

In some embodiments, in the step of mixing the zinc salt solution with the first alkaline solution, mixing the zinc salt solution with the first alkaline solution according to a molar ratio of 1.5:1 to 2.5:1 of hydroxide ions to zinc ions.

In some embodiments, the zinc oxide film with the surface hydroxyl content being greater than or equal to 0.6 is the metal doped zinc oxide film, and the zinc salt solution contains doped metal ions, too.

In some embodiments, the doped metal in the metal doped zinc oxide film is selected from at least one of Mg²⁺ and Mn²⁺; or alternatively, the doped metal in the metal doped zinc oxide film is selected from at least one of Al³⁺, Y³⁺, La³⁺, Li⁺, Gd³⁺, Zr⁴⁺, and Ce⁴⁺.

In some embodiments, a doping content of the doped metal is as follows:
when the doped metal is Mg²⁺, a doping molar concentration of Mg²⁺ in the metal doped zinc oxide film is between 0.1% and 35%;
when the doped metal is Mn²⁺, a doping molar concentration of Mn²⁺ in the metal doped zinc oxide film is between 0.1% and 30%;
when the doped metal is Al³⁺, a doping molar concentration of Al³⁺ in the metal doped zinc oxide film is between 0.1% and 15%;
when the doped metal is Y³⁺, a doping molar concentration of Y³⁺ in the metal doped zinc oxide film is between 0.1% and 10%;
when the doped metal is La³⁺, a doping molar concentration of La³⁺ in the metal doped zinc oxide film is between 0.1% and 7%;
when the doped metal is Li⁺, a doping molar concentration of Li⁺ in the metal doped zinc oxide film is between 0.1% and 45%;
when the doped metal is Gd³⁺, a doping molar concentration of Gd³⁺ in the metal doped zinc oxide film is between 0.01% and 8%;
when the doped metal is Zr⁴⁺, a doping molar concentration of Zr⁴⁺ in the metal doped zinc oxide film is between 0.1% and 45%;
when the doped metal is Ce⁴⁺, the doping molar concentration of Ce⁴⁺ in the metal doped zinc oxide film is between 0.1% and 10%.

In some embodiments, in a step of mixing the zinc salt solution containing doped metal ions with the first alkaline solution, the additive amount of alkali meets the following requirement: the ratio of the product of the molar amount and the valence number of metal ions to the molar amount of hydroxide ions is in the range of 0.75:1-1.25:1.

A second preparation method for a QLED, the QLED comprises an anode and a cathode being oppositely arranged, a quantum dot luminescent layer arranged between the anode and cathode, and an electron transport layer (ETL) arranged between the quantum dot luminescent layer and the cathode; wherein the ETL comprises a first ETL, and a surface of zinc oxide that forms the first ETL contains amino ligands and/or carboxyl ligands with 8-18 carbon atoms;
a preparation method of the first ETL is as follows:
preparing a zinc oxide colloidal solution through a solution method by using a zinc salt solution, an alkaline solution, and amino ligands and/or carboxyl ligands with 8-18 carbon atoms as raw materials; where the zinc oxide surface in the zinc oxide solution is bonded with the amino ligands and/or the carboxyl ligands with 8-18 carbon atoms;
forming the zinc oxide colloidal solution on a prefabricated device substrate for preparing the first ETL, and removing the solvent to obtain the first ETL.

In some embodiments, the step of preparing the zinc oxide colloidal solution through the solution method comprises:
mixing the zinc salt solution, the alkaline solution, with the amino ligands and/or carboxyl ligands with 8-18 carbon atoms for reaction, and preparing zinc oxide nanoparticles having surfaces bonded with the amino ligands and/or the carboxyl ligands with 8-18 carbon atoms;
dissolving the zinc oxide nanoparticles to obtain the zinc oxide colloidal solution.

In some embodiments, the step of preparing the zinc oxide colloidal solution through the solution method comprises:
mixing the zinc salt solution with the alkaline solution for reaction, and adding the amino ligands and/or the carboxyl ligands with 8-18 carbon atoms during a reaction process to prepare zinc oxide nanoparticles having surfaces bonded with the amino ligands and/or the carboxyl ligands with 8-18 carbon atoms; where a reaction time after adding the amino ligands and/or the carboxyl ligands with 8-18 carbon atoms is greater than or equal to 10 minutes;
dissolving the zinc oxide nanoparticles to obtain the zinc oxide colloidal solution.

In some embodiments, the step of preparing the zinc oxide colloidal solution through the solution method comprises:
after mixing the zinc salt solution with the alkaline solution to prepare the zinc oxide nanoparticles, adding the amino ligands and/or the carboxyl ligands with 8-18 carbon atoms, and reacting continuously to prepare the zinc oxide nanoparticles with surfaces bonded with the amino ligands and/or the carboxyl ligands with 8-18 carbon atoms;
dissolving the zinc oxide nanoparticles to obtain the zinc oxide colloidal solution.

In some embodiments, the step of preparing the zinc oxide colloidal solution through the solution method comprises:
mixing the zinc salt solution with the alkaline solution for reaction, collecting and cleaning products to obtain zinc oxide nanoparticles;
after dissolving the zinc oxide nanoparticles, adding the amino ligands and/or the carboxyl ligands with 8-18 carbon atoms for reaction, and binding the amino ligands and/or the carboxyl ligands with 8-18 carbon atoms with surfaces of zinc oxide to obtain the zinc oxide colloidal solution.

In some embodiments, after adding the amino ligands and/or the carboxyl ligands with 8-18 carbon atoms, the reaction takes 10 minutes to 2 hours.

In some embodiments, the amino ligands and/or the carboxyl ligands with 8-18 carbon atoms is a ligand solution, and a concentration of the ligand solution is in a range of 0.2-0.4 mmol/L.

In some embodiments, an additive amount of the amino ligands and/or the carboxyl ligands with 8-18 carbon atoms satisfies a following requirement: a molar ratio of the amino ligands and/or the carboxyl ligands with 8-18 carbon atoms to the zinc salt in the zinc salt solution is in a range of 1:1-10:1.

In some embodiments, the number of carbon atoms of the amino ligands and/or the carboxyl ligands is between 8 and 12, and the additive amount of the amino ligands and/or the carboxyl ligand meets a following requirement: a molar ratio of the amino ligands and/or the carboxyl ligands to the zinc salt in the zinc salt solution is in a range of 4:1-10:1;

the number of the carbon atoms of the amino ligands and/or the carboxyl ligands is between 13 and 18, and the additive amount of the amino ligands and/or the carboxyl ligands meets a following requirement: a molar ratio of the amino ligands and/or the carboxyl ligands to the zinc salt in the zinc salt solution is in a range of 1:1-5:1.

In some embodiments, wherein the amino ligands and/or the carboxyl ligands with 8-18 carbon atoms is a ligand solution, and a concentration of the ligand solution is in a range of 0.05-0.1 mmol/L.

In some embodiments, the additive amount of the amino ligands and/or the carboxyl ligands with 8-18 carbon atoms satisfies a following requirement: a molar ratio of the amino ligands and/or the carboxyl ligands with 8-18 carbon atoms to the zinc salt in the zinc salt solution is in a range of 1:4-4:1.

In some embodiments, the number of the carbon atoms of the amino ligands and/or carboxyl ligands is between 8 and 12, and an additive amount of the amino ligands and/or the carboxyl ligands meets a following requirement: a molar ratio of the amino ligands and/or the carboxyl ligands to the zinc salt in the zinc salt solution is in a range of 1:1-10:1;

the number of carbon atoms of the amino ligands and/or carboxyl ligands is between 13 and 18, and the additive amount of the amino ligands and/or carboxyl ligands meets a following requirement: a molar ratio of the amino ligands and/or the carboxyl ligands to the zinc salt in the zinc salt solution is in a range of 1:4-5:1.

In some embodiments, the amino ligands and/or carboxyl ligands with 8-18 carbon atoms are selected from at least one of octanoic acid, octylamine, dodecanoic acid, lauryl amine, oleic acid, and oleylamine.

A third preparation method of an QLED, the QLED comprises an anode and a cathode being oppositely arranged, a quantum dot luminescent layer arranged between the anode and cathode, and an electron transport layer (ETL) arranged between the quantum dot luminescent layer and the cathode; wherein the ETL comprises a first ETL containing zinc oxide, and at least one side surface of the first ETL contains amino ligands and/or carboxyl ligands with 8-18 carbon atoms;
a preparation method of the first ETL comprises:
preparing a prefabricated zinc oxide film on a prefabricated device substrate for preparing the first ETL;
depositing a solution of amino ligands and/or carboxyl ligands with 8-18 carbon atoms on a surface of the prefabricated zinc oxide film, and then performing a drying treatment to obtain a zinc oxide film.

In some embodiments, a concentration of the solution of the amino ligands and/or the carboxyl ligands with 8-18 carbon atoms is in a range of 0.05-0.1 mmol/L.

In some embodiments, a number of carbon atoms of the amino ligands and/or the carboxyl ligands with 8-18 carbon atoms is between 8 and 12, and an additive amount of the amino ligands and/or the carboxyl ligands with 8-18 carbon atoms meets a following requirement: the solution of the amino ligands and/or the carboxyl ligands with 8-12 carbon atoms with a volume of 100 μL-500 μL is deposited for every 5 mg of the prefabricated zinc oxide film.

In some embodiments, a number of carbon atoms of the amino ligands and/or the carboxyl ligands with 8-18 carbon atoms is between 13 and 18, and an additive amount of the amino ligands and/or the carboxyl ligands with 8-18 carbon atoms meets a following requirement: the solution of the amino ligands and/or the carboxyl ligands with 8-12 carbon atoms with a volume of 50 μL-300 μL is deposited for every 5 mg of the prefabricated zinc oxide film.

In some embodiments, the amino ligands and/or the carboxyl ligands with 8-18 carbon atoms are selected from at least one of propionic acid, propylamine, butyric acid, butylamine, caproic acid, and hexylamine.

In some embodiments, a temperature for the drying treatment ranges from 10° C. to 100° C., and a drying time is between 10 minutes and 2 hours.

In some embodiments, the first ETL is metal doped zinc oxide film.

In some embodiments, the doped metal in the metal doped zinc oxide film is selected from at least one of Mg²⁺ and Mn²⁺; or alternatively, the doped metal in the metal doped zinc oxide film is selected from at least one of Al³⁺, Y³⁺, La³⁺, Li⁺, Gd³⁺, Zr⁴⁺, and Ce⁴⁺.

In some embodiments, a doping content of the doped metal is as follows:
when the doped metal is Mg²⁺, a doping molar concentration of Mg²⁺ in the metal doped zinc oxide film is between 0.1% and 35%;
when the doped metal is Mn²⁺, a doping molar concentration of Mn²⁺ in the metal doped zinc oxide film is between 0.1% and 30%;
when the doped metal is Al³⁺, a doping molar concentration of Al³⁺ in the metal doped zinc oxide film is between 0.1% and 15%;
when the doped metal is Y³⁺, a doping molar concentration of Y³⁺ in the metal doped zinc oxide film is between 0.1% and 10%;
when the doped metal is La³⁺, a doping molar concentration of La³⁺ in the metal doped zinc oxide film is between 0.1% and 7%;
when the doped metal is Li⁺, a doping molar concentration of Li⁺ in the metal doped zinc oxide film is between 0.1% and 45%;
when the doped metal is Gd³⁺, a doping molar concentration of Gd³⁺ in the metal doped zinc oxide film is between 0.01% and 8%;
when the doped metal is Zr⁴⁺, a doping molar concentration of Zr⁴⁺ in the metal doped zinc oxide film is between 0.1% and 45%;
when the doped metal is Ce⁴⁺, the doping molar concentration of Ce⁴⁺ in the metal doped zinc oxide film is between 0.1% and 10%.

In some embodiments, a preparation method of a prefabricated zinc oxide film comprises: mixing a zinc salt solution with an alkaline solution to prepare zinc oxide nanoparticles; dissolving the zinc oxide nanoparticles to obtain a zinc oxide colloidal solution; forming a zinc oxide colloidal solution on a prefabricated device substrate, removing a solvent to prepare the prefabricated zinc oxide film.

A fourth preparation method for a quantum dot light-emitting diode (QLED), the QLED comprises an anode and a cathode being oppositely arranged, a quantum dot luminescent layer arranged between the anode and cathode, and an electron transport layer (ETL) arranged between the quantum dot luminescent layer and the cathode, wherein the ETL comprises a first ETL, and the first ETL is a zinc oxide film with a surface hydroxyl content being greater than or equal to 0.6;
a preparation method for the zinc oxide film with the surface hydroxyl content being greater than or equal to 0.6, comprises:
mixing a zinc salt solution with a first alkaline solution for reaction to prepare zinc oxide; dissolving the zinc oxide to obtain a zinc oxide colloidal solution; adding a second alkaline solution into the zinc oxide colloidal solution to adjust a pH of the zinc oxide colloidal solution to be greater than or equal to 8 to obtain the zinc oxide solution;
forming the zinc oxide solution on a prefabricated device substrate for preparing a zinc oxide film with the surface hydroxyl content being greater than or equal to 0.6, and removing a solvent to prepare the zinc oxide film with the surface hydroxyl content being greater than or equal to 0.6.

In some embodiments, the method further comprises: adding the second alkaline solution into the zinc oxide colloidal solution to obtain a mixed solution with a pH value of 9-12, in the step of adding the second alkaline solution into the zinc oxide colloidal solution to adjust the pH of the zinc oxide colloidal solution to be greater than or equal to 8.

In some embodiments, the method further comprises: adding the second alkaline solution into the zinc oxide colloidal solution to obtain the mixed solution with a pH value of 9-10, in the step of adding the second alkaline solution into the zinc oxide colloidal solution to adjust the pH of the zinc oxide colloidal solution to be greater than or equal to 8.

In some embodiments, alkalis in the second alkaline solution are selected from at least one of potassium hydroxide, sodium hydroxide, Lithium hydroxide, TMAH, ammonium hydroxide, ethanolamine and ethylenediamine.

In some embodiments, the first alkaline solution is selected from the first alkaline solution formed by at least one of potassium hydroxide, sodium hydroxide, Lithium hydroxide, TMAH, ammonium hydroxide, ethanolamine and ethylenediamine.

In some embodiments, a solvent in the zinc salt solution and the solvent in the first alkaline solution are respectively and independently selected from at least one of water, organic alcohols, organic ethers, and sulfones.

In some embodiments, a solvent in the second alkaline solution is selected from at least one of water, methanol, ethanol, propanol, butanol, ethylene glycol, 2-methoxyethanol and DMSO.

In some embodiments, the zinc oxide film with the surface hydroxyl content being greater than or equal to 0.6 is a metal doped zinc oxide film, and the zinc salt solution contains doped metal ions, too.

In some embodiments, the doped metal in the metal doped zinc oxide film is selected from at least one of Mg²⁺ and Mn²⁺; or alternatively, the doped metal in the metal doped zinc oxide film is selected from at least one of Al³⁺, Y³⁺, La³⁺, Li⁺, Gd³⁺, Zr⁴⁺, and Ce⁴⁺.

In some embodiments, a doping content of the doped metal is as follows:
when the doped metal is Mg²⁺, a doping molar concentration of Mg²⁺ in the metal doped zinc oxide film is between 0.1% and 35%;
when the doped metal is Mn²⁺, a doping molar concentration of Mn²⁺ in the metal doped zinc oxide film is between 0.1% and 30%;
when the doped metal is Al³⁺, a doping molar concentration of Al³⁺ in the metal doped zinc oxide film is between 0.1% and 15%;
when the doped metal is Y³⁺, a doping molar concentration of Y³⁺ in the metal doped zinc oxide film is between 0.1% and 10%;
when the doped metal is La³⁺, a doping molar concentration of La³⁺ in the metal doped zinc oxide film is between 0.1% and 7%;
when the doped metal is Li⁺, a doping molar concentration of Li⁺ in the metal doped zinc oxide film is between 0.1% and 45%;
when the doped metal is Gd³⁺, a doping molar concentration of Gd³⁺ in the metal doped zinc oxide film is between 0.01% and 8%;
when the doped metal is Zr⁴⁺, a doping molar concentration of Zr⁴⁺ in the metal doped zinc oxide film is between 0.1% and 45%;
when the doped metal is Ce⁴⁺, the doping molar concentration of Ce⁴⁺ in the metal doped zinc oxide film is between 0.1% and 10%.

In some embodiments, in a step of mixing the zinc salt solution containing doped metal ions with the first alkaline solution, the additive amount of alkali meets the following requirement: the ratio of the product of the molar amount and the valence number of metal ions to the molar amount of hydroxide ions is in the range of 0.75:1-1.25:1.

A fifth preparation method of a quantum dot light-emitting diode (QLED), wherein the QLED comprises an anode and a cathode being oppositely arranged, a quantum dot luminescent layer arranged between the anode and cathode, and an electron transport layer (ETL) arranged between the quantum dot luminescent layer and the cathode; wherein the ETL comprises a first ETL, the first ETL is a zinc oxide film with a surface hydroxyl content being greater than or equal to 0.6;
a preparation method for the zinc oxide film with the surface hydroxyl content being greater than or equal to 0.6, comprises:
preparing a prefabricated zinc oxide film on a prefabricated device substrate for preparing the zinc oxide film with the surface hydroxyl content being greater than or equal to 0.6;
performing a drying treatment to obtain the zinc oxide film, after depositing a second alkaline solution on a surface of the prefabricated zinc oxide film.

In some embodiments, the second alkaline solution is selected from at least one of potassium hydroxide, sodium hydroxide, lithium hydroxide, TMAH, ammonium hydroxide, ethanolamine and ethylenediamine.

In some embodiments, a concentration of the second alkaline solution is between 0.05 mmol/L and 0.5 mmol/L.

In some embodiments, the alkali in the second alkaline solution is an inorganic alkali, and the concentration of the second alkaline solution is in a range of 0.05-0.1 mmol/L.

In some embodiments, in the step of depositing the second alkaline solution on the surface of the prefabricated zinc oxide film, an additive amount of the second alkaline solution meets a following requirement: the second alkaline solution with a volume of 50 μL-400 μL is used for treatment for every 5 mg of the prefabricated zinc oxide film.

In some embodiments, the alkali in the second alkaline solution is organic alkali, and the concentration of the second alkaline solution is in a range of 0.2-0.4 mmol/L.

In some embodiments, in the step of depositing the second alkaline solution on the surface of the prefabricated zinc oxide film, an additive amount of the second alkaline solution meets a following requirement: the second alkaline solution with a volume of 500 μL-1000 μL is used for treatment for every 5 mg of the prefabricated zinc oxide film.

In some embodiments, a temperature for the drying treatment ranges from 10° C. to 100° C., and a drying time is between 10 minutes and 2 hours.

In some embodiments, the zinc oxide film with the surface hydroxyl content being greater than or equal to 0.6 is a metal doped zinc oxide film.

In some embodiments, the doped metal in the metal doped zinc oxide film is selected from at least one of Mg²⁺ and Mn²⁺; or alternatively, the doped metal in the metal doped zinc oxide film is selected from at least one of Al³⁺, Y³⁺, La³⁺, Li⁺, Gd³⁺, Zr⁴⁺, and Ce⁴⁺.

In some embodiments, a doping content of the doped metal is as follows:
when the doped metal is Mg²⁺, a doping molar concentration of Mg²⁺ in the metal doped zinc oxide film is between 0.1% and 35%;
when the doped metal is Mn²⁺, a doping molar concentration of Mn²⁺ in the metal doped zinc oxide film is between 0.1% and 30%;
when the doped metal is Al³⁺, a doping molar concentration of Al³⁺ in the metal doped zinc oxide film is between 0.1% and 15%;
when the doped metal is Y³⁺, a doping molar concentration of Y³⁺ in the metal doped zinc oxide film is between 0.1% and 10%;
when the doped metal is La³⁺, a doping molar concentration of La³⁺ in the metal doped zinc oxide film is between 0.1% and 7%;
when the doped metal is Li⁺, a doping molar concentration of Li⁺ in the metal doped zinc oxide film is between 0.1% and 45%;
when the doped metal is Gd³⁺, a doping molar concentration of Gd³⁺ in the metal doped zinc oxide film is between 0.01% and 8%;
when the doped metal is Zr⁴⁺, a doping molar concentration of Zr⁴⁺ in the metal doped zinc oxide film is between 0.1% and 45%;
when the doped metal is Ce⁴⁺, the doping molar concentration of Ce⁴⁺ in the metal doped zinc oxide film is between 0.1% and 10%.

### Beneficial Effects

According to the QLED provided in the present application, the zinc oxide film with a surface hydroxyl content being greater than or equal to 0.6 as the first ETL to suppress the transmission of electrons in the ETL and reduce the transmission of the electrons in the QLED. Thus, the number of injected electrons in the quantum dot luminescent layer is reduced, and the injection balance of carriers in the QLED is realized, and the QLED with much higher external quantum efficiency is obtained finally. However, when the ETL contains zinc oxide and at least part of the surface of the zinc oxide contains amino ligands and/or carboxyl ligands with carbon atom number of 8-18, the distance between zinc oxide nanoparticles in the film is increased under the action of steric effects, due to the long chain length of the coordinated amino ligands and/or the coordinated carboxyl ligands having the carbon atom number ranging from 8-18. Thus, the electron mobility of the ETL is reduced, the transmission of the electrons in the ETL is suppressed, the transmission of the electrons in the QLED is reduced, and the electrons injected into the quantum dot luminescent layer are reduced accordingly. The injection balance of carriers in the QLED is realized, and the QLED with much higher external quantum efficiency is obtained finally.

According to the preparation method of the QLED provided in the present application, electron mobility in the ETL is reduced, the transmission of the electrons in the ETL is suppressed, the transmission of the electrons in the QLED is reduced, and thus the injected electrons in the quantum dot luminescent layer are reduced, the injection balance of carriers in the QLED is realized, and the QLED with much higher external quantum efficiency is obtained finally.

### DESCRIPTION OF THE DRAWINGS

In order to describe the embodiments of the present application more clearly, a brief introduction regarding the accompanying drawings that need to be used for describing the embodiments or the existing technology is given below. It is obvious that the accompanying drawings described below are merely some embodiments of the present application, a person of ordinary skill in the art may also acquire other drawings according to the current drawings without paying creative labors.

FIG. 1 illustrates a schematic structural diagram of an ETL in accordance with one embodiment of the present application;

FIG. 2 illustrates a schematic structural diagram of another ETL in accordance with one embodiment of the present application;

FIG. 3 illustrates a schematic structural diagram of a light-emitting diode in accordance with one embodiment of the present application;

FIG. 4 illustrates a schematic structural diagram of a non-inverted light-emitting diode in accordance with one embodiment of the present application;

FIG. 5 illustrates a schematic structural diagram of an inverted light-emitting diode in accordance with one embodiment of the present application;

FIG. 6 illustrates a first preparation process flow diagram of a zinc oxide film with a surface hydroxyl content being greater than or equal to 0.6 in accordance with one embodiment of the present application;

FIG. 7 illustrates a second preparation process flow diagram of the zinc oxide films with the surface hydroxyl content being greater than or equal to 0.6 provided in one embodiment of the present application;

FIG. 8 illustrates a third preparation process flow diagram of the zinc oxide films with the surface hydroxyl content being greater than or equal to 0.6 provided in one embodiment of the present application;

FIG. 9 illustrates a first preparation process flow diagram of a first ETL in accordance with one embodiment of the present application, wherein the first ETL uses the zinc oxide having a surface containing amino ligands and/or carboxyl ligands with 8-18 carbon atoms as electron transfer material;

FIG. 10 illustrates a second preparation process flow diagram of the first ETL in accordance with one embodiment of the present application, wherein the first ETL uses the zinc oxide having a surface containing amino ligands and/or carboxyl ligands with 8-18 carbon atoms as electron transfer material;

FIG. 11 illustrates a schematic diagram of using X-ray photoelectron spectroscopy (XPS) to test hydroxyl oxygen peak area and lattice oxygen peak area, and calculates a ratio of the hydroxyl oxygen peak area to the lattice oxygen peak area to obtain hydroxyl content, in accordance with one embodiment of the present application;

FIG. 12 illustrates an EQE luminescence curve in accordance with one embodiment of the present application;

FIG. 13 illustrates a schematic diagram that represents a lifetime of the device in accordance with one embodiment of the present application;

FIG. 14 illustrates a device EQE test result of the QLED in accordance with the first embodiment and the first comparison example of the present application;

FIG. 15 illustrates a device EQE test result of the QLED in accordance with the second embodiment and the first comparison example of the present application;

FIG. 16 illustrates a test result of a lifetime of the QLED in accordance with the second embodiment and the first comparison example of the present application;

FIG. 17 illustrates a device EQE test result of the QLED in accordance with the third embodiment and the first comparison example of the present application;

FIG. 18 illustrates a test result of the lifetime of the QLED in accordance with the third embodiment and the first comparison example of the present application;

FIG. 19 illustrates a device EQE test result of the QLED in accordance with the fourth embodiment and the second comparison example of the present application;

FIG. 20 illustrates a device EQE test result of the QLED in accordance with the fifth embodiment and the second comparison example of the present application;

FIG. 21 illustrates a device EQE test result of the QLED provided by the sixth embodiment and the second comparison example of the present application; and

FIG. 22 illustrates a device EQE test result of the QLED in accordance with the seventh embodiment and the second comparison example of the present application.

### DETAILED DESCRIPTION OF EMBODIMENTS

In order to make the technical problems, the technical solutions and the beneficial effects of the present application be clearer and more understandable, the present application will be further described in detail below with reference to the embodiments. It should be understood that the embodiments described herein are only intended to illustrate but not to limit the present application.

In the descriptions of the present application, it should be understood that, terms such as “the first” and “the second” are only for the purpose of illustration, rather than being interpreted as indicating or implying any relative importance, or implicitly indicating the number of indicated technical features. Thus, technical feature(s) restricted by “the first” or “the second” may explicitly or implicitly include one or more such technical feature(s). In the description of the present application, the term “a plurality of” indicates a number of at least two, unless otherwise the term “a plurality of” is explicitly and In particular defined.

In a quantum dot light-emitting diode (QLED) device, an electron mobility of a zinc oxide layer is usually higher than that of a hole transport layer. In order to achieve a better injection balance of carriers in the QLED device, according to the traditional solution, the electron mobility of the zinc oxide layer is reduced by inserting an electron barrier layer between a quantum dot luminescent layer and the zinc oxide layer, such that injected electrons and holes in the quantum dot luminescent layer can reach a balance. However, the use of the method of, for example, inserting the electron barrier layer to change the device structure to improve injection balance of carriers has certain constraints. In one aspect, it is difficult to implement this method in actual device preparation, this is because that the electron barrier layer has a strict requirement on thickness. If the thickness of the electron barrier layer is too thick or too thin, it is difficult to implement an effective function, device performance of the QLED may even be reduced. Thus, it is difficult to control the thickness of the electron barrier layer in practical operation. In another aspect, the method of changing a device structure (i.e., adding the electron barrier layer) may also increase a fabrication cost of the device, cost burden of mass production of the QLED device will be increased in the future.

In view of this, in one aspect, in the present application, the regulation of electron injection rate is realized by regulating the surface hydroxyl content of the zinc oxide film. Thus, electrons injected into the quantum dot luminescent layer are reduced, an injection balance of carriers in the QLED is achieved, and a QLED device with much higher external quantum efficiency (EQE) is obtained finally. In particular, the QLED provided in the present application utilizes the zinc oxide film with more surface hydroxyl content as an electron transport layer (ETL). In this condition, the injection of holes and the injection of electrons are more balanced due to the decrease of the rate of electron injection into the quantum dot luminescent layer, and thus the EQE of the QLED device is improved.

It should be noted that in this embodiment of the present application, the determination of the surface hydroxyl content of the zinc oxide film is obtained by detecting the zinc oxide film using X-ray photoelectron spectroscopy (XPS). In particular, in the detection result of the X-ray photoelectron spectroscopy, O1s spectrum can be divided into three sub peaks which are OM peak representing a molar concentration of oxygen atoms in zinc oxide crystals (peak position is between 529ev and 531ev), OV peak representing a molar concentration of oxygen vacancies in the zinc oxide crystals (peak position is between 531ev and 532ev), and OH peak representing a molar concentration of hydroxyl ligands on the surfaces of the zinc oxide crystals (peak position is between 532ev and 534ev), respectively. Area ratios among these sub peaks represent molar concentration ratios of different types of oxygen atoms in the zinc oxide films. Thus, the surface hydroxyl content of the zinc oxide film is defined as a ratio of OH peak area to OM peak area. That is, the surface hydroxyl content of the zinc oxide film is the ratio of the molar concentration of hydroxyl ligands on the surface of the zinc oxide film to the molar concentration of oxygen atoms in zinc oxide crystals.

The QLED provided in one embodiment of the present application includes an anode and a cathode being oppositely arranged, a quantum dot luminescent layer arranged between the anode and the cathode, and an ETL (ETL) arranged between the quantum dot luminescent layer and the cathode.

Where, the ETL includes a first ETL, and the first ETL is a zinc oxide film having a surface hydroxyl content greater than or equal to 0.6.

In one possible embodiment, the ETL only includes one thin film, this thin film is the zinc oxide film having the surface hydroxyl content greater than or equal to 0.6. That is. the ETL is the first ETL. In this condition, due to the adsorption of a large number of negatively charged hydroxyl groups on the surface of zinc oxide, it can inhibit and hinder the transmission of electrons in the zinc oxide film may be suppressed and blocked, the electrons injected into the quantum dot luminescent layer are reduced, the QLED device has a lower electron injection efficiency in the initial operation of the device, and injection balance of carriers in the QLED device is achieved. The device is in a state of equal carrier equilibrium, and thus has much higher external quantum efficiency.

When the ETL is the first ETL, the zinc oxide in the first ETL is either metal doped zinc oxide or zinc oxide without doped metal.

In some embodiments, the first ETL is the zinc oxide film without doped metals, that is, the ETL is made of zinc oxide, and the zinc oxide does not contain doped metals. In some embodiments, the surface hydroxyl content of the undoped zinc oxide film is greater than or equal to 0.8. In some embodiments, the surface hydroxyl content of the undoped zinc oxide film is greater than or equal to 1.0. It should be noted that the undoped zinc oxide film mentioned in the embodiments of the present application refers to the zinc oxide film which is formed by the zinc oxide without doping with other metal ions, as compared to the metal doped zinc oxide film. That is, the undoped zinc oxide film is a pure zinc oxide film.

In some embodiments, the first ETL is the zinc oxide film containing doped metals, that is, the zinc oxide in the ETL is zinc oxide containing doped metals. It should be understood that, the doped metal in the present application refers to other metal ions doped into the zinc oxide in the form of ions and are different from zinc ions. When doped zinc oxide obtained by doping metallic elements in the zinc oxide is used as an ETL material for the QLED, the doped zinc oxide facilitates the acquisition of higher device efficiency in the QLED device. However, the lifetime of the QLED device is not ideal and is even worse than the lifetime of the QLED device having undoped pure zinc oxide ETL. This is because that, when energy level/oxygen vacancy (electron mobility) of the doped zinc oxide ETL changes, the doped ions will be preferentially filled to the surface defects after entering the surfaces of the zinc oxide particles to achieve an purpose of passivating defects to some extent, while the newly filled doped ion sites will coordinate with new surface hydroxyl content. Thus, the total surface hydroxyl content will increase.

In some embodiments, the surface hydroxyl content of the zinc oxide film containing doped metals is greater than or equal to 0.8. In some embodiments, the surface hydroxyl content of the zinc oxide films containing doped metals is greater than or equal to 1.0.

In some embodiments, the doped metal in the zinc oxide film containing the doped metal is selected from at least one of Mg²⁺ and Mn²⁺. In this condition, doped metal ions and zinc ions have the same valence state, however, their oxides have metal ions of different conduction band energy levels. In this condition, the conduction band energy level of the zinc oxide ETL can be adjusted by doping this metal ion, energy level matching between the quantum dot luminescent layer and the ETL in the QLED device is further optimized, and the EQE of the QLED device is improved.

In some embodiments, the doped metals in the zinc oxide film containing the doped metals are selected from at least one of Al³⁺, Y³⁺, La³⁺, Li⁺, Gd³⁺, Zr⁴⁺, and Ce⁴⁺. In this condition, doped metal ions and zinc ions have different valence states of metal ions. By doping the metal ions, the oxygen vacancies (electron mobility) in the zinc oxide ETL can be adjusted, the injection balance of carriers of the QLED device is further optimized, and the EQE of the QLED device is improved.

There are some differences between an ionic radius of the doped metal ion and an ionic radius of the zinc ion, and the crystal structures of the oxides of the doped metal and the zinc ion are different (e.g., MgO and MnO are NaCl type cubic crystal system, ZrO2 is monoclinic crystal system, and ZnO is Wurtzite type hexagonal crystal system). Thus, the doped metal ions have doping limits in zinc oxide material. When a doping amount exceeds the doping limit, the doped metal ions will precipitate from the surface of the zinc oxide material in the form of a second phase, thereby having an adverse impact on the performance of the zinc oxide material. The comparison of ionic radius of the doped metal ions and the zinc ion provided in the embodiments of the present application is shown in Table 1 below.

TABLE 1

| | Zn²⁺ | Mg²⁺ | Mn²⁺ | Al³⁺ | Y³⁺ |
|---|---|---|---|---|---|
| Ionic radius (A) | 0.60 | 0.57 | 0.66 | 0.39 | 0.90 |
| $\vert \frac{{r}_{{M}^{n +}} - {r}_{{Zn}^{2 +}}}{{r}_{{Zn}^{2 +}}} \vert ( \% )$ | | 5.0 | 10.0 | 35 | 50 |
| | La³⁺ | Li⁺ | Gd³⁺ | Ce⁴⁺ | Zr⁴⁺ |
| Ionic radius (A) | 1.03 | 0.59 | 0.94 | 0.87 | 0.59 |
| $\vert \frac{{r}_{{M}^{n +}} - {r}_{{Zn}^{2 +}}}{{r}_{{Zn}^{2 +}}} \vert ( \% )$ | 72 | 1.7 | 56 | 45 | 1.7 |

According to the embodiments of the present application, the doping amount of doped metal ions is regulated according to the difference of ionic radiuses between the selected doped metal ions and Zn²⁺, and the closer the ionic radiuses between the selected doped metal ion and the zinc ion, and the more similar the crystal structures of the oxides of the selected doped metal ion and zinc ion, and the higher the doping limit of doped metal ion in the zinc oxide material. For example, when the doping metal is Mg²⁺, a doping molar concentration of Mg²⁺ in the zinc oxide film containing the doped metal is between 0.1% and 35%. When the doped metal is Mn²⁺, the doping molar concentration of Mn²⁺ in the zinc oxide film containing the doping metal is between 0.1% and 30%. When the doped metal is Al³⁺, the doping molar concentration of Al³⁺ in the zinc oxide film containing the doping metal is between 0.1% and 15%. When the doped metal is Y³⁺, the doping molar concentration of Y³⁺ in the zinc oxide film containing the doping metal is between 0.1% and 10%. When the doping metal is La³⁺, the doping molar concentration of La³⁺ in the zinc oxide film containing the doping metal is between 0.1% and 7%. When the doping metal is Li⁺, the doping molar concentration of Li⁺ in the zinc oxide film containing the doping metal is between 0.1% and 45%. When the doping metal is Gd³⁺, the doping molar concentration of Gd³⁺ in the zinc oxide film containing the doping metal is between 0.01% and 8%. When the doped metal is Zr⁴⁺, the doping molar concentration of Zr4⁺ in the zinc oxide film containing the doped metal is between 0.1% and 45%. When the doped metal is Ce⁴⁺, the doping molar concentration of Ce⁴⁺ in the zinc oxide film containing the doped metal is between 0.1% and 10%.

In some embodiments, when the ETL is the first ETL, the thickness of the first ETL (i.e. the ETL) is between 10 nm and 100 nm.

In one possible embodiment, the ETL further includes a second ETL. The second ETL is a zinc oxide film with a surface hydroxyl content less than or equal to 0.4. The ETL includes a zinc oxide film with a surface hydroxyl content less than or equal to 0.4 and a zinc oxide film with a surface hydroxyl content greater than or equal to 0.6. The two zinc oxide films are arranged to be laminated in a direction perpendicular to the quantum dot luminescent layer or the cathode. In this condition, when a double-layer zinc oxide electron transport layer is used, the zinc oxide film having the surface with high hydroxyl content can reduce the number of electrons injected into the quantum dot luminescent layer. Thus, there is a lower electron injection efficiency in the initial operation of the QLED device, injection balance of carriers in the QLED device is realized, and the QLED device is in the carrier equilibrium state, and thus has a higher external quantum efficiency. When the QLED device continues to be operated and enters a stable state, due to the existence of the zinc oxide film with low surface hydroxyl amount, a condition that the quantum dot luminescent layer is in a negative electricity state still occurs, and dynamic equilibrium is achieved. Thus, the final electron injection efficiency is at a low level, the electron injection efficiency and the hole injection efficiency form an injection balance of carriers, so that the lifetime of the obtained QLED device will also be improved.

The first ETL and the second ETL are arranged to be laminated, and a relative position of the first ETL and the second ETL can be flexibly arranged. In some embodiments, the second ETL is arranged on the surface of the first ETL adjacent to the quantum dot luminescent layer. In this condition, the deposition of the zinc oxide colloidal solution with less surface hydroxyl content on the quantum dot luminescent layer is beneficial for obtaining a smoother zinc oxide film. In some embodiments, the second ETL is arranged on the surface of the first ETL adjacent to the quantum dot luminescent layer.

In some embodiments, the zinc oxides in the first ETL and the second ETL are undoped zinc oxides. The first ETL and the second ETL are made of zinc oxides which do not contain doped metals. In some embodiments, the ETL is composed of the zinc oxide film (i.e., the first ETL) with the surface hydroxyl content greater than or equal to 0.6 and the zinc oxide film (i.e., the second ETL) with the surface hydroxyl content less than or equal to 0.4. In some embodiments, the surface hydroxyl content of the first ETL is greater than or equal to 0.8, and the surface hydroxyl content of the second ETL is less than or equal to 0.25, or even less than or equal to 0.15. In some embodiments, the surface hydroxyl content of the first ETL is greater than or equal to 1.0, and the surface hydroxyl content of the second ETL is less than or equal to 0.25, or even less than or equal to 0.15.

In some embodiments, the zinc oxide in at least one of the first ETL and the second ETL is metal doped zinc oxide.

In some embodiments, the zinc oxide in the zinc oxide film with the surface hydroxyl content greater than or equal to 0.6 is the metal doped zinc oxide, while the zinc oxide film (i.e. the second ETL) with the surface hydroxyl content less than or equal to 0.4 is an undoped zinc oxide film. In this condition, as mentioned above, in one aspect, the low hydroxyl content enables the QLED device to achieve injection balance of carriers even when the QLED is continuously operated and enter a stable state, thereby achieving long lifetime of the device. In another aspect, the electrons injected into the quantum dot luminescent layer can be reduced due to high hydroxyl content, injection balance of carriers in the QLED device is achieved, and the QLED device with high EQE (EQE) is finally obtained. In addition, metal ions are doped in the zinc oxide with the surface hydroxyl content greater than or equal to 0.6 to achieve effective carrier injection control. In the initial operation of the device of the QLED device, the QLED device can achieve a much higher EQE as compared to the QLED device which uses the undoped zinc oxide film as the ETL, and the surface hydroxyl content of the first ETL is greater than or equal to 0.6. Due to these reasons, the EQE of QLED device can be more efficiently improved. According to this embodiment, injection balance of carriers of the QLED device can be achieved by regulating the surface hydroxyl content of the zinc oxide film, without the need of changing the structure (i.e., inserting an electronic barrier layer) of the QLED device and changing the features of the zinc oxide film through doping or other methods. The entire process is simple to be operated, is cost-effective, and has a good repeatability.

As an example, the ETL is consisted of the first ETL and the undoped zinc oxide film (i.e., the second ETL) with a surface hydroxyl content less than or equal to 0.4, and the zinc oxide in the first ETL is metal doped zinc oxide. In some embodiments, the surface hydroxyl content of the first ETL is greater than or equal to 0.8, and the surface hydroxyl content of the second ETL is less than or equal to 0.25, or even less than or equal to 0.15. In some embodiments, the surface hydroxyl content of the first ETL is greater than or equal to 1.0, and the surface hydroxyl content of the second ETL is less than or equal to 0.25, or even less than or equal to 0.15.

In some embodiments, the zinc oxide film with the surface hydroxyl content greater than or equal to 0.6, that is, the first ETL, is undoped zinc oxide film, while the zinc oxide film with the surface hydroxyl content less than or equal to 0.4, that is, the zinc oxide in the second ETL is metal doped zinc oxide film. In this condition, in one aspect, the low hydroxyl content enables the QLED device to achieve injection balance of carriers when the QLED device is continuously operated to enter a stable state, thereby achieving long lifetime of the device. In another aspect, the electrons injected into the quantum dot luminescent layer can be reduced due to high hydroxyl content, injection balance of carriers in the QLED device is achieved, and the QLED device with high EQE is finally obtained. In addition, metal ions are doped in the zinc oxide with the surface hydroxyl content greater than or equal to 0.6 to achieve effective carrier injection control. In the initial operation of the device of the QLED device, the QLED device can achieve a much higher EQE as compared to the QLED device which uses the undoped zinc oxide film as the ETL, and the surface hydroxyl content of the first ETL is greater than or equal to 0.6. Due to these reasons, the EQE of QLED device can be more efficiently improved.

As an example, the ETL is composed of the undoped zinc oxide film (i.e., the first ETL) with the surface hydroxyl content greater than or equal to 0.6 and the zinc oxide film (i.e., the second ETL) with the surface hydroxyl content less than or equal to 0.4, and the zinc oxide in the second ETL is metal doped zinc oxide. In some embodiments, the surface hydroxyl content of the first ETL is greater than or equal to 0.8, and the surface hydroxyl content of the second ETL is less than or equal to 0.25, or even less than or equal to 0.15. In some embodiments, the surface hydroxyl content of the first ETL is greater than or equal to 1.0, and the surface hydroxyl content of the second ETL is less than or equal to 0.25, or even less than or equal to 0.15.

In some embodiments, the zinc oxide film with the surface hydroxyl content greater than or equal to 0.6, that is, the zinc oxide in the first ETL, is metal doped zinc oxide, while the zinc oxide film with the surface hydroxyl content less than or equal to 0.4, that is, the zinc oxide in the second ETL, is metal doped zinc oxide. In this condition, in one aspect, the low hydroxyl content enables the QLED device to achieve injection balance of carriers when the QLED device is continuously operated to enter the stable state, thereby achieving long lifetime of the device. In another aspect, the electrons injected into the quantum dot luminescent layer can be reduced due to high hydroxyl content, injection balance of carriers in the QLED device is achieved, and the QLED device with high EQE is finally obtained. In addition, metal ions are doped in the zinc oxide with the surface hydroxyl content greater than or equal to 0.6 and the zinc oxide with the surface hydroxyl content less than or equal to 0.4 to achieve effective carrier injection control. In the initial operation of the QLED device, the QLED device can obtain higher EQE than the QLED device which uses the undoped zinc oxide film as the ETL. Furthermore, the surface hydroxyl content of the first ETL is greater than or equal to 0.6. Due to these reasons, the EQE of the QLED device can be significantly improved.

As an example, the ETL is composed of the zinc oxide film (i.e., the first ETL) with the surface hydroxyl content greater than or equal to 0.6 and the zinc oxide film (i.e., the second ETL) with the surface hydroxyl content less than or equal to 0.4, and both the zinc oxide in the first ETL and the zinc oxide in the second ETL are metal doped zinc oxides. In some embodiments, the surface hydroxyl content of the first ETL is greater than or equal to 0.8, and the surface hydroxyl content of the second ETL is less than or equal to 0.25, or even less than or equal to 0.15. In some embodiments, the surface hydroxyl content of the first ETL is greater than or equal to 1.0, and the surface hydroxyl content of the second ETL is less than or equal to 0.25, or even less than or equal to 0.15.

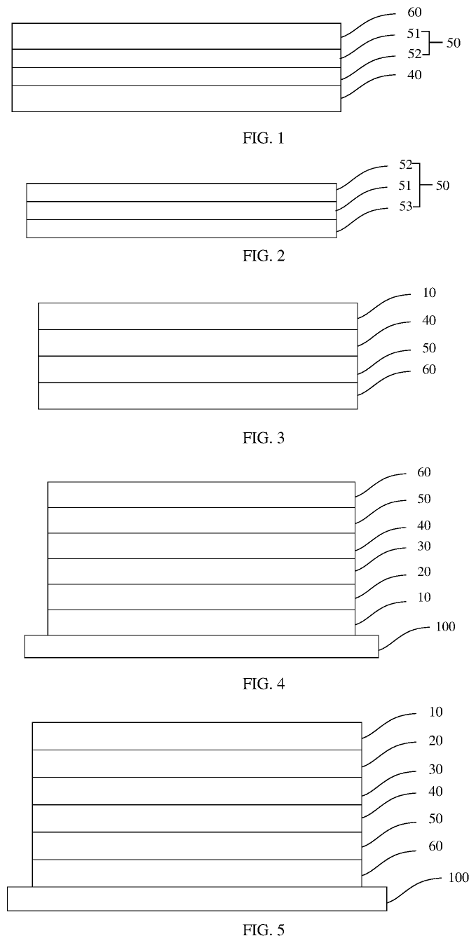

In one implementation mode of the aforesaid embodiment, as shown in FIG. 1, the ETL 50 is composed of a first ETL 51 and a second ETL 52, and the second ETL 52 is more adjacent to the quantum dot luminescent layer 40 than the first ETL 51. That is, the first ETL 51 is more adjacent to a cathode 60. In this condition, the deposition of the zinc oxide colloidal solution with less surface hydroxyl content on the quantum dot luminescent layer is beneficial for obtaining a smoother zinc oxide film.

In some embodiments, the ETL includes the first ETL and the second ETL. The second ETL is arranged on the surface of one side of the first ETL adjacent to the cathode or the quantum dot luminescent layer, and the second ETL is a metal doped zinc oxide film. In this condition, the external quantum efficiency (EQE) of the QLED is optimized by optimizing the energy level matching or the electron mobility of the doped zinc oxide, the surface hydroxyl content of zinc oxide is simultaneously increased to optimize the EQE of the QLED.

As an example, as shown in FIG. 1, the ETL 50 includes a first ETL 51 and a second ETL 52. The second ETL 52 is a metal doped zinc oxide film, and the second ETL 52 is arranged on a surface of one side of the first ETL 51 adjacent to the quantum dot luminescent layer 40. That is, the first ETL 51 is adjacent to the cathode 60. In this condition, the deposition of the doped metal zinc oxide colloidal solution on the quantum dot luminescent layer is beneficial for obtaining a smoother zinc oxide film. In the aforesaid embodiment, when the ETL is a double-layer zinc oxide film, the thickness of each layer of zinc oxide film is between 10 nm and 100 nm. In this condition, the thickness of the zinc oxide film is appropriate and is not prone to be punctured by electrons, which is conducive to maintaining an injection performance, a film quality, and a surface smoothness of the ETL. Considering that the thickness of the zinc oxide film or the metal doped zinc oxide film with surface hydroxyl amount greater than or equal to 0.6 should not be too thick due to their respective low electron mobility. For example, the thickness of the zinc oxide film or the metal doped zinc oxide film with the surface hydroxyl content greater than or equal to 0.6 is between 10 nm and 30 nm. The thickness of the zinc oxide film with surface hydroxyl less than or equal to 0.4 can be arranged to be appropriately thicker due to high electron mobility of this zinc oxide film. For example, the thickness of the zinc oxide film or the metal doped zinc oxide film with the surface hydroxyl content less than or equal to 0.4 is between 20 nm and 60 nm.

In some implementation methods of the aforesaid embodiments, the ETL includes n thin film lamination units, each of the thin film lamination units is composed of the first ETL and the second ETL. Where n is greater than or equal to 2. The ETL uses a laminated structure, such that the energy level matching may be much better, and a lifetime of the QLED device can be prolonged greatly. In some embodiments, n is an integer greater than or equal to 2 and less than or equal to 9.

In one possible implementation mode, the ETL further includes a third ETL. That is, the ETL includes a zinc oxide film with the surface hydroxyl content greater than or equal to 0.6, that is, the first ETL, the second ETL, and the third ETL. Where the second ETL is the zinc oxide film with the surface hydroxyl content less than or equal to 0.4, or the zinc oxide film with the surface hydroxyl content greater than or equal to 0.6, or a metal doped zinc oxide film.

In one embodiment, the third ETL is the zinc oxide film with the surface hydroxyl content greater than or equal to 0.6.

In some embodiments, the ETL includes the zinc oxide film (i.e. the first ETL) with the surface hydroxyl content greater than or equal to 0.6, the zinc oxide film (i.e. the second ETL) with a surface hydroxyl content less than or equal to 0.4, and the zinc oxide film (i.e. the third ETL) with the surface hydroxyl content greater than or equal to 0.6. Where, the third ETL is arranged on one side of the surface of the second ETL away from the first ETL. In this condition, a layer of zinc oxide film with low hydroxyl content enables the QLED device to achieve injection balance of carriers even when the QLED device is continuously operated to enter the stable state, thereby achieving long lifetime of the QLED device. Two layers of zinc oxide films with high hydroxyl content can reduce the number of the electrons injected into the quantum dot luminescent layer to achieve injection balance of carriers in the QLED device. Finally, the QLED device with high EQE is obtained.

In one embodiment, the third ETL is a zinc oxide film with a surface hydroxyl content less than or equal to 0.4.

In some embodiments, as shown in FIG. 2, the ETL 50 includes the zinc oxide film (i.e. the first ETL 51) with the surface hydroxyl content greater than or equal to 0.6, the zinc oxide film (i.e. the second ETL 52) with the surface hydroxyl content less than or equal to 0.4, and the zinc oxide film (i.e. the third ETL 53) with the surface hydroxyl content less than or equal to 0.4, and the third ETL 53 is arranged on one side of the surface of the first ETL 51 away from the second ETL 52. In this condition, the double-layer zinc oxide films with low hydroxyl content enables the QLED device to achieve injection balance of carriers even when the QLED device is continuously operated to enter the stable state, thereby achieving long lifetime of the QLED device, while the zinc oxide film with high hydroxyl content can reduce the number of the electrons injected into the quantum dot luminescent layer to achieve injection balance of carriers in the QLED device. Thus, the QLED device with high EQE is obtained. In addition, the deposition of zinc oxide or doped zinc oxide colloidal solutions with fewer surface hydroxyl content on the quantum dot luminescent layer is beneficial to the acquisition of a smoother zinc oxide film. Thus, the obtained QLED device has both good EQE and lifetime of the QLED device.

In some embodiments, the ETL includes the zinc oxide film (i.e. the first ETL) with the surface hydroxyl content greater than or equal to 0.6, the metal doped zinc oxide film (i.e. the second ETL), and the zinc oxide film (i.e. the third ETL) with the surface hydroxyl content less than or equal to 0.4, and the third ETL is arranged between the second ETL and the first ETL. In this condition, in one aspect, the low hydroxyl content enables the QLED device to achieve injection balance of carriers when the QLED device is continuously operated to enter the stable state, thereby achieving long lifetime of the QLED device. In another aspect, high hydroxyl content can reduce the number of the electrons injected into the quantum dot luminescent layer to achieve injection balance of carriers in the QLED device, and finally, the QLED device with high EQE is obtained. In addition, the zinc oxide in the second ETL is doped with metal ions to achieve effective carrier injection control. In the early stage of operation of the device, the QLED device with higher EQE can be obtained as compared to a QLED device which uses the undoped zinc oxide films as the ETL, the EQE of the QLED device can be more significantly improved.

In some embodiments, the third ETL is a metal doped zinc oxide film.

In some embodiments, the ETL includes the zinc oxide film (i.e. the first ETL) with the surface hydroxyl content greater than or equal to 0.6, the zinc oxide film (i.e. the second ETL) with the surface hydroxyl content less than or equal to 0.4, and the metal doped zinc oxide film (i.e. the third ETL), and the third ETL is arranged on the surface on the side of the second ETL away from the first ETL. In this condition, the zinc oxide film with the low hydroxyl content further strengthens the electron mobility, such that the QLED device can enter the state of injection balance of carriers when it is continuously operated to enter the stable state, thereby obtaining a good lifetime of the device. The high hydroxyl content of the zinc oxide film can reduce the number of the electrons injected into the quantum dot luminescent layer to achieve the injection balance of carriers during the initial operation of the QLED device, and the QLED device with high EQE is obtained finally. Moreover, the QLED device has been in a state of better injection balance of carriers through optimization of the energy level matching or the electron mobility of the doped zinc oxide, and higher external quantum efficiency (EQE) can be obtained during the initial operation of the device as compared to the QLED device that uses the undoped zinc oxide film as the ETL. Due to the low surface hydroxyl content of doped zinc oxide films, the QLED device can also achieve injection balance of carriers when it is continuously operated to enter the stable state. Thus, a better lifetime of the QLEDs can be achieved, and a higher EQE in the initial operation of the device can be maintained. In some embodiments, the third ETL is arranged to be adjacent to the quantum dot luminescent layer. The deposition of doped zinc oxide colloidal solution on the quantum dot luminescent layer is beneficial to acquisition of a smoother zinc oxide film.

It should be understood that, in the embodiments where the ETL contains the third ETL, the zinc oxide in the zinc oxide film with the surface hydroxyl content less than or equal to 0.4 can either be the undoped zinc oxide or be metal doped zinc oxide. Similarly, zinc oxide in zinc oxide film with the surface hydroxyl content greater than or equal to 0.6 can either be undoped zinc oxide or be metal doped zinc oxide.

In the embodiments where the ETL contains the third ETL, in some embodiments, the thickness of the ETL is between 10 nm and 100 nm. In some embodiments, the thickness of the zinc oxide film with the surface hydroxyl content less than or equal to 0.4 is between 20 nm and 60 nm. In some embodiments, the thickness of the zinc oxide film with the surface hydroxyl content greater than or equal to 0.6 is between 10 nm and 30 nm. In some embodiments, the thickness of the metal doped zinc oxide film is between 10 nm and 30 nm. The thickness of each layer of the zinc oxide film is within the aforesaid range. Thus, in this condition, the zinc oxide film has an appropriate thickness and is not prone to be punctured by electrons, which is conducive to maintaining the injection performance, the film quality, and the surface smoothness of the ETL. In particular, the thickness of the zinc oxide film or the metal doped zinc oxide film with the surface hydroxyl amount greater than or equal to 0.6 is relatively thin due to its low electron mobility. The thickness of the zinc oxide film with the surface hydroxyl less than or equal to 0.4 is relatively thicker due to its high electron mobility.

In the embodiment in which the ETL includes the second ETL, and the second ETL is the metal doped zinc oxide film, and the embodiment in which the ETL includes the second ETL and the third ETL, and the second ETL and/or the third ETL is/are the metal doped zinc oxide film(s), the types of the doped metals in the metal doped zinc oxide films, the impact of the doping metals and the doping content of the doped metals have been described above (in the condition where the ETL is the first ETL). In order to save space, they will not be repeatedly described herein.

In some embodiments, the doped metal in the metal doped zinc oxide film is selected from at least one of Mg²⁺ and Mn²⁺. In some embodiments, the doped metal in the metal doped zinc oxide film is selected from at least one of Al³⁺, Y³⁺, La³⁺, Li⁺, Gd³⁺, Zr⁴⁺, and Ce⁴⁺.

In some embodiments, when the doping metal is Mg²⁺, the doping molar concentration of Mg²⁺ in the metal doped zinc oxide film ranges from 0.1% to 35%; When the doping metal is Mn²⁺, the doping molar concentration of Mn²⁺ in the metal doped zinc oxide film ranges from 0.1% to 30%. When the doping metal is Al³⁺, the doping molar concentration of Al³⁺ in the metal doped zinc oxide film ranges from 0.1% to 15%. When the doping metal is Y³⁺, the doping molar concentration of Y³ in the metal doped zinc oxide film ranges from 0.1% to 10%. When the doping metal is La³⁺, the doping molar concentration of La³⁺ in the metal doped zinc oxide film ranges from 0.1% to 7%. When the doping metal is Li⁺, the doping molar concentration of Li⁺ in the metal doped zinc oxide film ranges from 0.1% to 45%. When the doping metal is Gd³⁺, the doping molar concentration of Gd³⁺ in the metal doped zinc oxide film ranges from 0.01% to 8%. When the doping metal is Zr⁴⁺, the doping molar concentration of Zr⁴⁺ in the metal doped zinc oxide film ranges from 0.1% to 45%. When the doping metal is Ce⁴⁺, the doping molar concentration of Ce⁴⁺ in the metal doped zinc oxide film ranges from 0.1% to 10%.

According to the QLED provided in the embodiments of the present application, the zinc oxide film with the surface hydroxyl content greater than or equal to 0.6 is used as the first ETL to suppress the transmission of electrons in the ETL and reduce the transmission of electrons in the QLED, thereby reducing the number of electrons injected in the quantum dot luminescent layer and achieving the injection balance of carriers in the QLED. The QLED with high EQE is obtained finally. The QLED provided in the present application can achieve injection balance of carriers of the QLED device by only adjusting the surface hydroxyl content of the zinc oxide film, without the need of changing the structure (inserting an electron barrier layer) of the QLED device and changing the features of the zinc oxide film through doping or other methods. The entire process is simple to be operated, is low in cost, and has good repeatability.

In another aspect, the embodiments of the present application provide a quantum dot light-emitting diode (QLED), including an anode and a cathode being oppositely arranged, a quantum dot luminescent layer arranged between the anode and cathode, and an electron transport layer (ETL) arranged between the quantum dot luminescent layer and the cathode.

Where, the ETL contains zinc oxide, and at least some of the surface of the zinc oxide contains amino ligands and/or carboxyl ligands with 8-18 carbon atoms.

In the ETL, due to the long chain length of the amino ligands and/or the carboxyl ligands with 8-18 carbon atoms coordinated with the zinc oxide, under the space steric effect, the distances among the zinc oxide nanoparticles in the film is increased, and the electron mobility of the ETL is reduced, the transmission of electrons in the ETL is suppressed, and the transmission of electrons in the QLED is reduced. Thus, the number of electrons injected into the quantum dot luminescent layer is reduced, and the injection balance of carriers in the QLED is achieved, and the QLED with high EQE is obtained finally.

In the embodiments of the present application, the chain length, that is, the number of carbon atoms of the amino ligands and/or the carboxyl ligands needs to be strictly controlled. When the chain length is too short, the distances among the zinc oxide nanoparticles are not prone to be increased. Thus, the electron mobility of the ETL is not prone to be reduced. When the chain length is too long, due to the weak polarity of the ligands, it is difficult to effectively disperse the ligands in the zinc oxide colloidal solution with high polarity, and bind the ligands to the surfaces of the zinc oxide nanoparticles through ligand exchange. For example, the amino ligands and/or the carboxyl ligands with 8-18 carbon atoms are selected from at least one of octanoic acid, octylame, dodecanoic acid, lauryl amine, oleic acid, and oleylamine. In some embodiments, the number of carbon atoms of the amino ligands and/or the carboxyl ligands is between 8 and 12. Thus, the electron mobility of the ETL is reduced, and a better film quality is realized.

In some embodiments, the ETL includes the first ETL containing zinc oxide, and the surface of the zinc oxide that forms the first ETL contains amino ligands and/or the carboxyl ligands with 8-18 carbon atoms. The introduction of the amino ligands and/or the carboxyl ligands can increase the distances among the zinc oxide nanoparticles after film formation, and thereby reducing the electron mobility of the first ETL after film formation.

In some embodiments, in the zinc oxide film having the surface containing amino ligands and/or carboxyl ligands with 8-18 carbon atoms, a molar ratio of the amino ligands and/or the carboxyl ligands with 8-18 carbon atoms to zinc oxide is 1:4-10:1. In this condition, the appropriate amount of amino ligands and/or carboxyl ligands on the surfaces of the zinc oxide nanoparticles can reduce the electron mobility of the ETL containing zinc oxide, and make the electrons and holes in the quantum dot luminescent layer tend to be balanced, and thus improves the EQE of the QLED. When the chain length of the ligands is longer (e.g., 13-18 carbon atoms), the electron mobility of the sample after ligand exchange will be decreased. Thus, the electron mobility can be reduced and EQE can be improved when there are not too many additive amount of ligands with longer chain length. In addition, when there are too many additive amount of ligands with longer chain length, the solubility of zinc oxide nanoparticles in polar solvent will be reduced, film formation of zinc oxide layer in the final device is affected, and the device performance of the finally formed QLED device is reduced. However, when the chain length of ligands is short (e.g., 8-12 carbon atoms), the electron mobility decreases slightly after the ligand exchange. Thus, the additive amount of ligands with more chain length needs to be higher to achieve the purpose of improving EQE. In some embodiments, the number of carbon atoms of the amino ligands and/or the carboxyl ligands is between 8 and 12, and the molar ratio of the amino ligands and/or the carboxyl ligands to the zinc oxide nanoparticles is selected from 1:1 to 10:1. In some embodiments, the number of carbon atoms of the amino ligands and/or the carboxyl ligands is between 13 and 18, and the molar ratio of the amino ligands and/or the carboxyl ligands to the zinc oxide nanoparticles is selected from a range of 1:4-5:1.

In one possible embodiment, the ETL only includes one thin film, and this thin film is the first ETL. That is, the material forming the ETL is the zinc oxide, and the surface of the zinc oxide contains the amino ligands and/or the carboxyl ligands with 8-18 carbon atoms. In this condition, the transmission resistance of electrons in the ETL to the quantum dot luminescent layer is great, and the injection rate of electrons into the quantum dot luminescent layer is reduced. The lower electron injection rate and the lower hole injection rate are conducive to the injection balance of carriers, such that the EQE of the QLED device can be improved.

In some embodiments, the zinc oxide in the first ETL is undoped zinc oxide, which means that, the ETL is made of zinc oxide having the surface containing amino ligands and/or carboxyl ligands with 8-18 carbon atoms, and the zinc oxide does not contain doped metals. It should be noted that the undoped zinc oxide film mentioned in the embodiments of the present application refers to the zinc oxide film which is formed by zinc oxide without doping with other metal ions, as compared to the zinc oxide film with doped metals. The undoped zinc oxide film is a pure zinc oxide film.

In some embodiments, the zinc oxide in the first ETL is metal doped zinc oxide, that is, the zinc oxide in the ETL is the zinc oxide containing doped metals. It should be understood that the doped metal mentioned in the present application refers to other metal ions which are doped into zinc oxide in the form of ions and are different from zinc ions. The doped zinc oxide obtained by doping metal elements in zinc oxide can be used as ETL material for the QLED, which is conducive to obtaining higher device efficiency of the QLED device. However, the lifetime of the device is not ideal, and is even worse than that of QLED using the undoped pure zinc oxide ETL. In particular, as compared to the adjustment of the surface hydroxyl amount of the undoped zinc oxide film, when adjusting the surface hydroxyl amount of the doped zinc oxide film, the QLED device has been in a better injection balance of carriers by optimizing the energy level matching or electron mobility of doped zinc oxide. In the initial operation of the device, higher EQE can be achieved as compared to the QLED that uses undoped zinc oxide films as ETL.

The types of doped metals, the effects of doping metals, and the doping content of doped metals in metal doped zinc oxide film have been described above (in the condition where the ETL is the first ETL), and are not repeatedly described herein in order to save space.

In some embodiments, the doped metal in the metal doped zinc oxide film is selected from at least one of Mg²⁺ and Mn²⁺. In some embodiments, the doped metal in the metal doped zinc oxide film is selected from at least one of Al³⁺, Y³⁺, La³, Li⁺, Gd³⁺, Zr⁴⁺, and Ce⁴⁺. The doping amount of doped metal ions can refer to the aforesaid descriptions, and is not repeatedly described herein.

In some embodiments, when the ETL is the first ETL, the thickness of the first ETL (i.e., the ETL) is between 10 nm and 100 nm.

In one possible embodiment, the ETL further includes a second ETL, and the second ETL is the zinc oxide film with surface hydroxyl content less than or equal to 0.4. That is, the ETL simultaneously includes a zinc oxide film having surface containing amino ligands and/or carboxyl ligands with 8-18 carbon atoms and a zinc oxide film with a surface hydroxyl content less than or equal to 0.4. The two zinc oxide films are arranged to be laminated in a direction perpendicular to the direction of the quantum dot luminescent layer or the cathode. That is, the second ETL is arranged on the surface of the first ETL adjacent to the cathode or the quantum dot luminescent layer. In this condition, when double-layer zinc oxide is used for electron transport, the zinc oxide film having surface containing the amino ligands and/or the carboxyl ligands with 8-18 carbon atoms can reduce the number of the electrons injected into the quantum dot luminescent layer through the ETL, a lower electron injection efficiency in the initial operation of the QLED device is resulted, and injection balance of carriers in the QLED device is achieved. The device is in a state of equal carrier equilibrium, and thus possesses a high EQE. When the QLED device continues to be operated to enter a stable state, due to the existence of the zinc oxide film with low surface hydroxyl amount, the state of negative electricity of the quantum dot luminescent layer will still occur and dynamic equilibrium is reached. Thus, the final electron injection efficiency is at a low level, the electron injection efficiency and the hole injection efficiency form an injection balance of carriers. Thus, the lifetime of the obtained QLED device can also be improved.

The first ETL and the second ETL are arranged to be laminated, and the relative position of the first ETL and the second ETL can be flexibly arranged. In some embodiments, the second ETL is arranged on the surface of the first ETL adjacent to the quantum dot luminescent layer. In this condition, the deposition of the zinc oxide solution with fewer surface hydroxyl content on the quantum dot luminescent layer is conducive to obtaining a smoother zinc oxide film. In some embodiments, the second ETL can also be arranged on the surface of the first ETL adjacent to the quantum dot luminescent layer.

In some embodiments, both the first ETL and the second ETL are undoped zinc oxide films. The first ETL and the second ETL are made of zinc oxide which does not contain doped metals. However, the surface of the zinc oxide in the first ETL contains the amino ligands and/or carboxyl ligands with 8-18 carbon atoms. In some embodiments, the ETL is composed of the first ETL having the surface bonded with the amino ligands and/or the carboxyl ligands with 8-18 carbon atoms, and the second ETL having the surface containing hydroxyl amount less than or equal to 0.4. For example, the ETL further includes a second ETL, which is a zinc oxide film with the surface hydroxyl content less than or equal to 0.4. Both the first ETL and the second ETL are undoped zinc oxide films, and the second ETL is arranged on one side of the surface adjacent to the quantum dot luminescent layer.

In some embodiments, the zinc oxide in at least one of the first ETL and the second ETL is metal doped zinc oxide.

In some embodiments, the zinc oxide film having the surface bonded with the amino ligands and/or the carboxyl ligands with 8-18 carbon atoms, that is, the zinc oxide in the first ETL, is metal doped zinc oxide. The zinc oxide film having the surface hydroxyl content less than or equal to 0.4, that is, the second ETL, is undoped zinc oxide film. In this condition, as mentioned above, in one aspect, the zinc oxide film having the surface bonded with the amino ligands and/or the carboxyl ligands with 8-18 carbon atoms, that is, the first ETL, can reduce the number of electrons injected into the quantum dot luminescent layer to achieve injection balance of carriers in the QLED device, and the QLED device with high EQE is obtained finally. In another aspect, the zinc oxide film with low surface hydroxyl content, also known as the second ETL, enables the QLED device to achieve injection balance of carriers when the QLED device is continuously operated to enter a stable state, thereby achieving long lifetime of the QLED device. In addition, doping metal ions in the zinc oxide with amino ligands and/or carboxyl ligands with 8-18 carbon atoms can achieve effective carrier injection control. In the initial operation of the device, higher EQE can be obtained than the QLED device that uses the undoped zinc oxide film as ETL. Moreover, under the effect of the amino ligands and/or the carboxyl ligands with 8-18 carbon atoms in the first ETL, the EQE of QLED device can be effectively improved. In this embodiment, injection balance of carriers of the QLED device can be achieved by regulating the surface hydroxyl content of the zinc oxide film, without changing the structure (inserting an electronic barrier layer) of the QLED device or changing the features of the zinc oxide film through doping or other methods. The entire process is simple to be operated, is cost-effective, and has good repeatability.

As an example, the ETL is composed of the zinc oxide film (i.e., the first ETL) having the surface bonded with the amino ligands and/or the carboxyl ligands with 8-18 carbon atoms, and an undoped zinc oxide film (i.e., the second ETL) with the surface hydroxyl content less than or equal to 0.4, and the zinc oxide in the first ETL is metal doped zinc oxide. In some embodiments, the ETL is composed of the metal doped zinc oxide film (i.e., the first ETL) having the surface bonded with the amino ligands and/or the carboxyl ligands with 8-18 carbon atoms, and an undoped zinc oxide film (i.e., the second ETL) with the surface hydroxyl content less than or equal to 0.4, and the second ETL is arranged on one side of the surface adjacent to the quantum dot luminescent layer.

In some embodiments, the first ETL having the surface bonded with the amino ligands and/or the carboxyl ligands with 8-18 carbon atoms is an undoped zinc oxide film, and the zinc oxide of the zinc oxide film with the surface hydroxyl content less than or equal to 0.4, that is, the second ETL, is metal doped zinc oxide film. In this condition, in one aspect, the first ETL having the surface bonded with the amino ligands and/or the carboxyl ligands with 8-18 carbon atoms can reduce the number of the electrons injected into the quantum dot luminescent layer to achieve injection balance of carriers in the QLED device, and the QLED device with high EQE is obtained finally. In another aspect, the second ETL with low surface hydroxyl content enables the QLED device to achieve injection balance of carriers even when the QLED device is continuously operated to enter the stable state, thereby achieving long lifetime of the device. In addition, metal ions are doped in the zinc oxide of the second ETL to achieve effective carrier injection regulation. In the initial operation of the device, higher EQE can be obtained than the QLED that uses undoped zinc oxide films as ETL. In addition, under the synergistic effect of the functions of the amino ligands and/or the carboxyl ligands with 8-18 carbon atoms in the first ETL, the EQE of the QLED device can be more effectively improved. In this embodiment, injection balance of carriers of the QLED device can be achieved by regulating the surface hydroxyl content of the zinc oxide film, without changing the structure (inserting the electronic barrier layer) of the device or changing the features of the zinc oxide film through doping or other methods. The entire process is simple to be operated, is cost-effective, and has good repeatability.

For example, the ETL is composed of the undoped zinc oxide film (i.e., the first ETL) with amino ligands and/or carboxyl ligands with 8-18 carbon atoms, and the zinc oxide film (i.e., the second ETL) with the surface hydroxyl content less than or equal to 0.4, and the zinc oxide in the second ETL is metal doped zinc oxide. In some embodiments, the ETL is composed of an undoped zinc oxide film (i.e., the first ETL) with amino ligands and/or carboxyl ligands with 8-18 carbon atoms and a zinc oxide film (i.e., the second ETL) with the surface hydroxyl content less than or equal to 0.4. The zinc oxide in the second ETL is metal doped zinc oxide, and the second ETL is arranged on one side of the surface adjacent to the quantum dot luminescent layer.

In some embodiments, the zinc oxide of the zinc oxide film (i.e., the first ETL) having the surface bonded with the amino ligands and/or the carboxyl ligands with 8-18 carbon atoms is metal doped zinc oxide, and the zinc oxide of the zinc oxide film (i.e., the second ETL) with the surface hydroxyl content less than or equal to 0.4 is metal doped zinc oxide. In this condition, in one aspect, the first ETL having the surface bonded with the amino ligands and/or the carboxyl ligands with 8-18 carbon atoms can reduce the number of the electrons injected into the quantum dot luminescent layer to achieve injection balance of carriers in the QLED device, and the QLED device with high EQE is obtained finally. In another aspect, the second ETL with low surface hydroxyl content enables the QLED device to achieve injection balance of carriers even when the QLED device is continuously operated to enter the stable state, thereby achieving long lifetime of the QLED device. In addition, metal ions are doped in the zinc oxides of the first ETL and the second ETL to achieve effective carrier injection regulation. In the initial operation of the device, higher EQE can be obtained than the QLED that uses undoped zinc oxide films as ETL. In addition, under the synergistic effect of the amino ligands and/or the carboxyl ligands with 8-18 carbon atoms in the first ETL, the EQE of the QLED device can be significantly improved. In this embodiment, injection balance of carriers of QLED device can be achieved by regulating the surface hydroxyl content of the zinc oxide film, without changing the structure (inserting the electronic barrier layer) of the QLED device or changing the features of the zinc oxide film through doping or other methods. The entire process is simple to be operated, is cost-effective, and has good repeatability.

As an example, the ETL is composed of the zinc oxide film (i.e., the first ETL) containing amino ligands and/or carboxyl ligands with 8-18 carbon atoms and a zinc oxide film (i.e., the second ETL) with the surface hydroxyl amount greater than or equal to 0.6, and the zinc oxides in the first ETL and the second ETL is metal doped zinc oxides. In some embodiments, the ETL is composed of the metal doped zinc oxide film (i.e., the first ETL) having the surface bonded with the amino ligands and/or the carboxyl ligands with 8-18 carbon atoms, and the metal doped zinc oxide film (i.e., the second ETL) with the surface hydroxyl content greater than or equal to 0.6, and the second ETL is arranged on one side of the surface adjacent to the quantum dot luminescent layer.

In one implementation mode of the aforesaid embodiment, as shown in FIG. 1, an ETL 50 is composed of a first ETL 51 and a second ETL 52, and the second ETL 52 is more adjacent to the quantum dot luminescent layer 40 than the first ETL 51. That is, the first ETL 51 is adjacent to the cathode 60. The deposition of a zinc oxide colloidal solution with low surface hydroxyl content on the quantum dot luminescent layer is conducive to obtaining a smoother zinc oxide film.

In some embodiments, the ETL includes a second ETL arranged on one side of the surface of the first ETL adjacent to the cathode or the quantum dot luminescent layer, and the second ETL is a metal doped zinc oxide film. In this condition, the first ETL having the surface bonded with the amino ligands and/or the carboxyl ligands with 8-18 carbon atoms can reduce the number of the electrons injected into the quantum dot luminescent layer to achieve injection balance of carriers in the QLED device, and the QLED device with high EQE is obtained finally. Moreover, the EQE of the QLED is further optimized by optimizing the energy level matching or the electron mobility of the metal doped zinc oxide.

In the aforesaid embodiment, when the ETL is a double-layer zinc oxide film, the thickness of each layer of zinc oxide films is between 10 nm and 100 nm. In this condition, the thickness of the zinc oxide film is appropriate and is not prone to be punctured by electrons, which is conducive to maintaining the injection performance, the film quality, and the surface smoothness of the ETL. Due to the low electron mobility of the metal doped zinc oxide film, the thickness of the film should not be too thick. For example, the thickness of metal doped zinc oxide film is between 10 nm and 30 nm. The thickness of the zinc oxide film having the surface bonded with the amino ligands and/or the carboxyl ligands with 8-18 carbon atoms is between 10 nm and 80 nm. Due to the high electron mobility of the zinc oxide film with the surface hydroxyl less than or equal to 0.4, the thickness of this zinc oxide film can be appropriately thicker. For example, the thickness of the zinc oxide film with the surface hydroxyl content less than or equal to 0.4 ranges from 20 nm to 60 nm.

In some implementation methods of the aforesaid embodiment, the ETL includes n thin film lamination units, each of the thin film lamination units is composed of the first ETL and the second ETL, where n is greater than or equal to 2. The ETL adopts a laminated structure that enables a better energy level matching and a greater increase in the lifetime of the QLED device. In some embodiments, n is an integer greater than or equal to 2 and less than or equal to 9.

In one possible implementation method, the ETL includes a second ETL and a third ETL.

In some embodiments, the second ETL is a zinc oxide film with a surface hydroxyl content less than or equal to 0.4, the third ETL is selected from a zinc oxide film with a surface hydroxyl content greater than or equal to 0.6, and the second ETL is bonded to one side of the surface of the first ETL, and the third ETL is bonded to the surface of one side of the second ETL away from the first ETL. In this condition, the zinc oxide film having the surface bonded with the amino ligands and/or the carboxyl ligands with 8-18 carbon atoms and the zinc oxide film with the high surface hydroxyl content can reduce the number of the electrons injected into the quantum dot luminescent layer to achieve injection balance of carriers in the QLED device, and ultimately achieve high EQE in the initial operation of the device of the QLED. One layer of zinc oxide film with low hydroxyl content enables the QLED device to achieve injection balance of carriers even when the QLED device is continuously operated to enter a stable state, thereby achieving a long lifetime of the QLED device.

In some embodiments, the second ETL is the zinc oxide film with the surface hydroxyl content less than or equal to 0.4, the third ETL is selected from the zinc oxide films having the surface bonded with the amino ligands and/or the carboxyl ligands with 8-18 carbon atoms on the surface, and the second ETL is bonded to one side of the surface of the first ETL, and the third ETL is bonded to the surface of one side of the second ETL away from the first ETL. In this condition, two layers of the zinc oxide films having the surface containing amino ligands and/or carboxyl ligands with 8-18 carbon atoms can reduce the number of the electrons injected into the quantum dot luminescent layer to achieve injection balance of carriers in the QLED device, and ultimately achieve high EQE in the initial operation of the device of the QLED. Moreover, one layer of zinc oxide film with low hydroxyl content enables the QLED device to achieve injection balance of carriers even when the QLED is continuously operated to enter the stable state, thereby achieving a long lifetime of the QLED device.

In some embodiments, the second ETL is the zinc oxide film with the surface hydroxyl content less than or equal to 0.4, the third ETL is selected from metal doped zinc oxide films, and the second ETL is bonded to one side of the surface of the first ETL, and the third ETL is bonded to the surface of the side of the second ETL away from the first ETL. In this condition, the zinc oxide film having the surface bonded with the amino ligands and/or the carboxyl ligands with 8-18 carbon atoms and the metal doped zinc oxide film can reduce the number of the electrons injected into the quantum dot luminescent layer to achieve injection balance of carriers in the QLED device, and ultimately achieve high EQE in the initial operation of the QLED device. Moreover, one layer of the zinc oxide film with low hydroxyl content enables the QLED device to achieve injection balance of carriers even when the QLED device is continuously operated to enter the stable state, thereby achieving a long lifetime of the QLED device. Thus, the obtained QLED device has excellent EQE and long lifetime.

In some embodiments, the second ETL is the zinc oxide film with the surface hydroxyl content less than or equal to 0.4, the third ETL is the zinc oxide film with the surface hydroxyl content less than or equal to 0.4, and the first ETL is arranged on one side of the surface of the second ETL and the third ETL. In this condition, the zinc oxide film having the surface bonded with the amino ligands and/or the carboxyl ligands with 8-18 carbon atoms can reduce the number of the electrons injected into the quantum dot luminescent layer to achieve injection balance of carriers in the QLED device, and ultimately achieve high EQE in the initial operation of the device of the QLED. The two layers of zinc oxide films with low hydroxyl content enables the QLED device to achieve injection balance of carriers even when the QLED device is continuously operated to enter the stable state, thereby achieving a long lifetime of the device. In addition, the deposition of the zinc oxide solution with fewer surface hydroxyl content on the quantum dot luminescent layer is conducive to obtaining a smoother zinc oxide film. Thus, the obtained QLED device has excellent EQE and long lifetime.

As an example, as shown in FIG. 2, an ETL 50 includes a first ETL 51, a second ETL 52, and a third ETL 53. Where the first ETL 51 is a zinc oxide film having the surface containing amino ligands and/or carboxyl ligands with 8-18 carbon atoms, and the second ETL 52 is the zinc oxide film with surface hydroxyl amount less than or equal to 0.4. The third ETL 53 is the zinc oxide film with the surface hydroxyl content less than or equal to 0.4, and the third ETL 53 is arranged on the surface of one side of the first ETL 51 away from the second ETL 52.

It should be understood that in the embodiments where the ETL contains the second ETL and the third ETL, the zinc oxide in the zinc oxide film with the surface hydroxyl content less than or equal to 0.4 is either undoped zinc oxide or metal doped zinc oxide. Similarly, the zinc oxide in the zinc oxide film with the surface hydroxyl content greater than or equal to 0.6 can either be undoped zinc oxide or metal doped zinc oxide.

In the embodiments where the ETL contains the third ETL, the thickness of the ETL is between 10 nm and 100 nm. The zinc oxide film containing the amino ligands and/or the carboxyl ligands with 8-18 carbon atoms, or the zinc oxide film with the surface hydroxyl amount of 0.6 or more than 0.6, or the metal doped zinc oxide film has a relatively thin thickness due to its low electron mobility. The zinc oxide film with the surface hydroxyl less than or equal to 0.4 has a relatively thick thickness due to its high electron mobility. In some embodiments, the thickness of the zinc oxide film having the surface bonded with the amino ligands and/or the carboxyl ligands with 8-18 carbon atoms is between 10 nm and 80 nm. In some embodiments, the thickness of the zinc oxide film with the surface hydroxyl content greater than or equal to 0.6 is between 10 nm and 30 nm. In some embodiments, the thickness of the metal doped zinc oxide film is between 10 nm and 30 nm. The thickness of each layer is within the aforesaid range. In this condition, the zinc oxide film has an appropriate thickness and is not prone to be punctured by electrons, which is conducive to maintaining the injection performance, the film quality, and the surface smoothness of the ETL.

The ETL includes a second ETL, in the embodiment where the second ETL is the metal doped zinc oxide film and the embodiments where the ETL includes the second ETL and the third ETL, and the second ETL and/or the third ETL is the metal doped zinc oxide films, the types of doped metals in the metal doped zinc oxide film, the impact of the doping metals and the doping content of the doped metals have been described above (in the condition where the ETL is the first ETL), and are not repeatedly described herein in order to save space.

In some embodiments, the doped metal in the metal doped zinc oxide film is selected from at least one of Mg²⁺ and Mn²⁺. In some embodiments, the doped metal in the metal doped zinc oxide film is selected from at least one of Al³⁺, Y³⁺, La³⁺, Li⁺, Gd³⁺, Zr⁴⁺, and Ce⁴⁺. The doping amount of doped metal ions has been described above, and will not be repeatedly described herein.

In one possible embodiment, the two QLED (one QLED includes an ETL, including a first ETL, and the first ETL is a zinc oxide film with a surface hydroxyl content greater than or equal to 0.6; the second QLED includes an ETL containing zinc oxide, and at least some surfaces of the zinc oxide contain amino ligands and/or carboxyl ligands with 8-18 carbon atoms) provided in the embodiments of the present application. As shown in FIG. 3, The QLED includes an anode 10 and a cathode 60 being oppositely arranged, and a quantum dot luminescent layer 40 arranged between the cathode 60 and anode 10, and an ETL 50 arranged between the cathode 60 and the quantum dot luminescent layer 40.

In some embodiments, the QLED further includes a hole functional layer arranged between the anode 10 and the quantum dot luminescent layer 40. Where the hole functional layer includes at least one of a hole transport layer, hole injection layer, and electron barrier layer. In some embodiments, the QLED further includes an electron injection layer arranged between the cathode 60 and the ETL 50.

In the aforesaid embodiments, the QLED may also include a substrate, and the anode 10 or the cathode 60 is arranged on the substrate.

The QLED provided in the embodiment of the present application are divided into a non-inverted LED and an inverted LED.

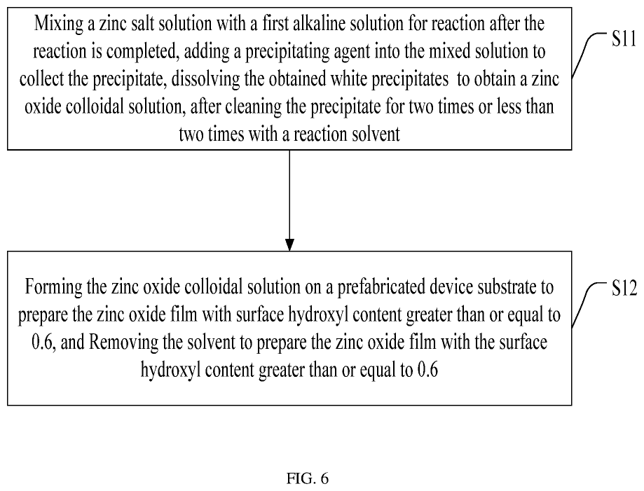

In one embodiment, the non-inverted QLED includes the anode 10 and the cathode 60 being oppositely arranged, a quantum dot luminescent layer 40 arranged between the anode 10 and cathode 60, and the ETL 50 arranged between the cathode 60 and the quantum dot luminescent layer 40, and the anode 10 is arranged on the substrate. In some embodiments, a hole transport layer 30 is arranged between the anode 10 and the quantum dot luminescent layer 40. Furthermore, a hole injection layer 20 is arranged between the anode 10 and the hole transport layer, and/or, an electron injection layer is arranged between the cathode 60 and the ETL 50. In some embodiments of the non-inverted QLED, as shown in FIG. 4, the QLED includes a substrate 100, an anode 10 arranged on the surface of the substrate 100, a hole injection layer 20 arranged on the surface of the anode 10, a hole transport layer 20 arranged on the surface of the hole injection layer 20, and a quantum dot luminescent layer 40 arranged on the surface of the hole transport layer, an ETL 50 arranged on the surface of the quantum dot luminescent layer 40, and a cathode 60 arranged on a surface of the ETL 50.

In one embodiment, the inverted QLED includes a laminated structure, the laminated structure includes the anode 10 and a cathode 60 being oppositely arranged, a quantum dot luminescent layer 40 arranged between the anode 10 and the cathode 60, and an ETL 50 arranged between the cathode 60 and the quantum dot luminescent layer 40, and the cathode 60 is arranged on the substrate. In some embodiments, a hole transport layer 30 is arranged between the anode 10 and the quantum dot luminescent layer 40. Furthermore, a hole injection layer 20 is arranged between the anode 10 and the hole transport layer; and/or, an electron injection layer is arranged between the cathode 60 and the ETL 50. In some embodiments of the inverted QLED, as shown in FIG. 5, the QLED includes a substrate 100, a cathode 60 disposed on the surface of the substrate 100, an ETL 50 disposed on the surface of the cathode 60, a luminescent layer 40 disposed on the surface of the ETL 50, a hole transfer layer 40 disposed on the surface of the quantum dot luminescent layer 40, a hole injection layer 20 disposed on the surface of the hole injection layer 20, and an anode 10 disposed on the surface of the hole injection layer 20.

In the aforesaid embodiment, the substrate 100 can be a rigid substrate or a flexible substrate. In particular, glass, silicon wafer, polycarbonate, polymethyl methacrylate, poalkaline liquorthylene terephthalate, poalkaline liquorthylene naphthalate, polyamide, poalkaline liquorthersulfone, or a composition of at least two of the above materials, or a laminated structure formed by at least two of the materials can be selected.

In some embodiments, the material of the hole injection layer 20 can be selected from at least one of poly (ethylenedioxythiophene):polystyrene sulfonate (PEDOT:PSS), HTL-1, HTL-2. Certainly, other hole injection materials with high injection performance can also be used.

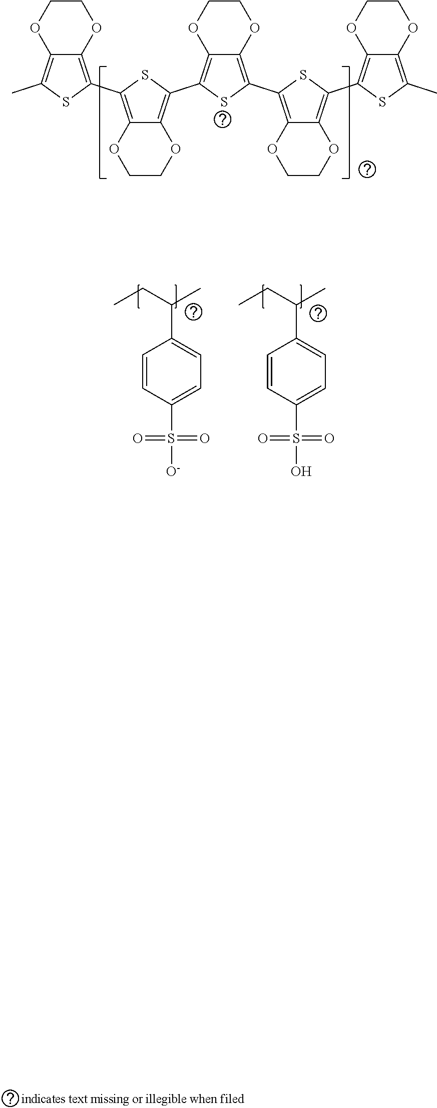

A structure of PEDOT:PSS is as follows:

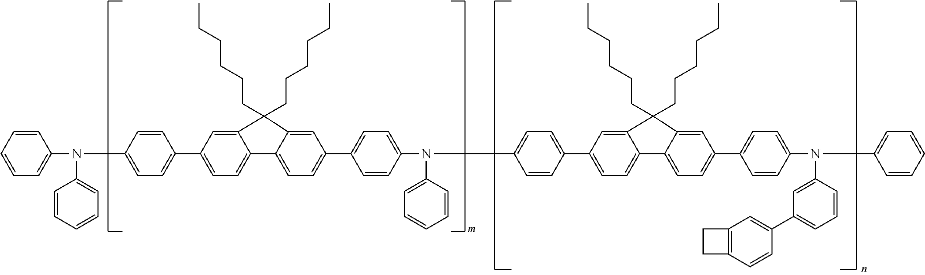

A structure of HTL-1 is as follows:

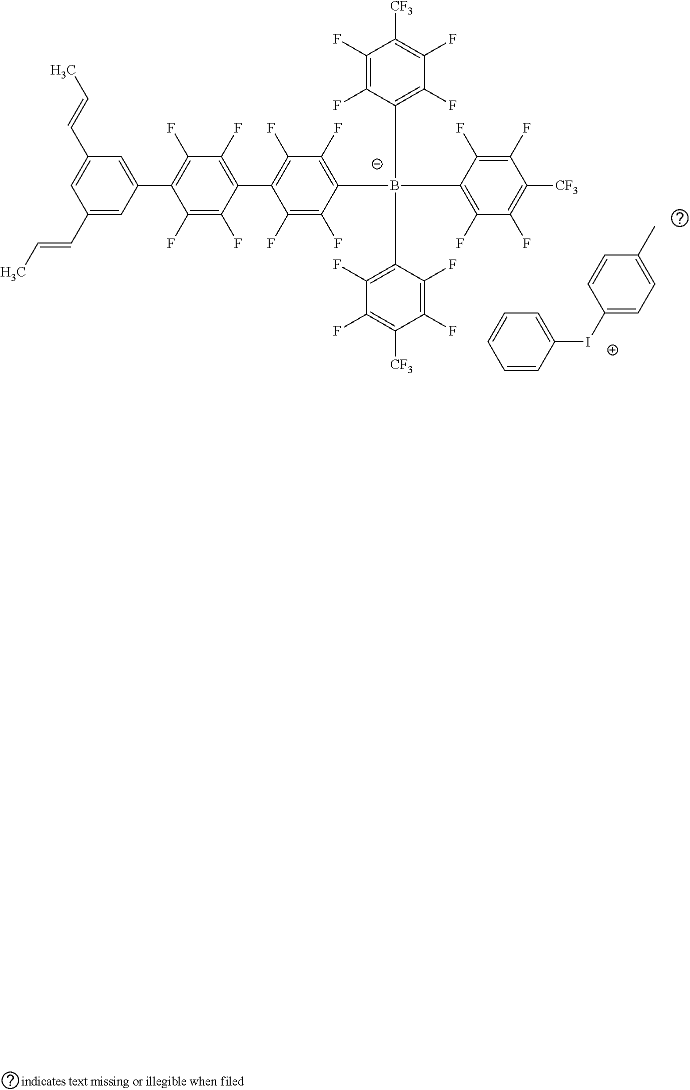

A structure of HTL-2 is as follows:

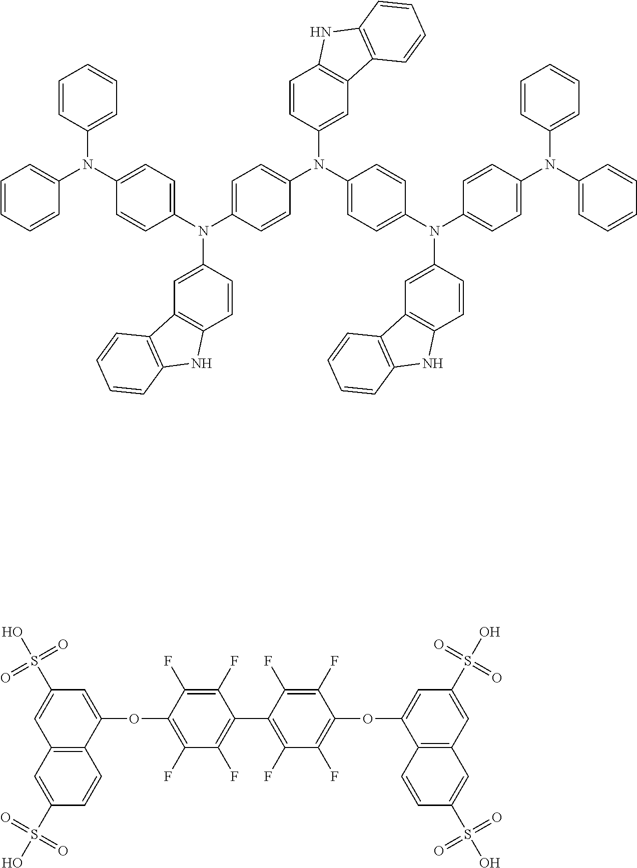 [SMILES: c1ccc(N(c2ccccc2)c2ccc(N(c3ccc(N(c4ccc(N(c5ccc(N(c6ccccc6)c6ccccc6)cc5)c5ccc6[nH]c7ccccc7c6c5)cc4)c4ccc5[nH]c6ccccc6c5c4)cc3)c3ccc4[nH]c5ccccc5c4c3)cc2)cc1 ; O=S(=O)(O)c1ccc2c(Oc3c(F)c(F)c(-c4c(F)c(F)c(Oc5cc(S(=O)(=O)O)cc6cc(S(=O)(=O)O)ccc56)c(F)c4F)c(F)c3F)cc(S(=O)(=O)O)cc2c1]

In some embodiments, the material of the hole transport layer 30 can be selected from conventional hole transport materials. For example, the material of the hole transport layer 30 is selected from at least one of 4,4′-N,N′-dicarbazolyl biphenyl, poly [(9,9′-dioctylfluoren-2,7-diyl)-co-(4,4′-(N-(4-sec-butylphenyl)diphenylamine)], poly (4-butylphenyl diphenylamine), 4,4′,4′-tri (N-carbazolyl)-triphenylamine, poly (N-vinylcarbazole) and derivatives thereof. Certainly, the material of the hole transport layer 30 can also be other hole transport materials with high injection performance.

The quantum dot in the luminescent layer 40 is one of red, green, and blue. The quantum dot can also be a yellow light quantum dot. Where, the quantum dot can be cadmium containing or cadmium free. In some embodiments, the quantum dot in the quantum dot luminescent layer 40 can be single core quantum dot or core-shell structured quantum dot, and the core-shell compounds of the quantum dot can be independently selected from CdS, CdSe, CdTe, ZnO, ZnS, ZnSe, ZnTe, GaAs, GaP, GaSb, HgS, HgSe, HgTe, InAs, InP, InSb, AlAs, AlP, CuInS, CuInSe, and at least one of various core-shell structured quantum dots or alloy structured quantum dots. The formed quantum dot luminescent layer has the characteristics of wide excitation spectrum and continuous distribution, high stability of emission spectrum.

In the embodiments of the present application, the material and the thickness of the electronic transmission layer 50 can refer to the above descriptions, and are not repeatedly described herein. In this embodiment of the present application, the thickness of the ETL is between 10 nm and 100 nm. When the thickness of the ETL is less than 10 nm, the film layer is prone to be punctured by electrons, thus, it is difficult to ensure the injection performance of charge carriers. When the thickness of the ETL is greater than 100 nm, the injection of electrons is blocked and a charge injection balance of the device is affected.

A bottom electrode (i.e., the anode 10 bonded to the substrate 100 or the cathode 60 bonded to the substrate) can use common bottom electrode materials. In some embodiments, the bottom electrode materials include at least one of zinc oxide, indium oxide, tin oxide, indium tin oxide (ITO), indium zinc oxide (IZO), and fluorine doped tin oxide.

In some embodiments, the top electrode (i.e., the anode 10 or the cathode 60 away from substrate 100) is a transparent oxide, a thin metal, or a combination of the transparent oxide and the thin metal. In some embodiments, the transparent oxide can be ITO, IZO, AZO. In some embodiments, the thin metal can be Ag, Al, Au, Mg, Ca, Yb, Ba or alloys thereof. In some embodiments, the top electrode can also be O/M/O, where M is Ag, Al, Au, Mg, Ca, Yb, Ba or alloys thereof, O is oxide which includes but not limited to ITO, IZO, AZO.

The ETL of the QLED provided in the embodiments of the present application contains zinc oxide, and at least a part of the surface of the zinc oxide contains amino ligands and/or carboxyl ligands with 8-18 carbon atoms. Due to the long chain length of the coordinated amino ligands and/or coordinated carboxyl ligands with 8-18 carbon atoms, under the space steric effect, distances among the zinc oxide nanoparticles in the film are increased, the electron mobility of the ETL is reduced, the transmission of electrons in the ETL is suppressed, the transmission of electrons in the QLED is reduced, and thus the electrons injected in the quantum dot luminescent layer is reduced, the injection balance of carriers in QLED is achieved, and the QLED with high EQE is obtained finally.

The QLED provided in the embodiment of the present application can be prepared by various methods. Hereinafter, three embodiments of methods for preparing the aforesaid QLED are provided in the present application.

In the first embodiment, the present application provides a preparation method for QLED. The QLED includes an anode and a cathode being oppositely arranged, a quantum dot luminescent layer arranged between the anode and cathode, and an ETL arranged between the quantum dot luminescent layer and the cathode. The ETL includes a first ETL, and the first ETL is a zinc oxide film with surface hydroxyl content greater than or equal to 0.6.

As shown in FIG. 6, a preparation method for a zinc oxide film with surface hydroxyl content greater than or equal to 0.6 includes:

at step S11, a zinc salt solution is mixed with a first alkaline solution for reaction after the reaction is completed, a precipitating agent is added into the mixed solution to collect the precipitates; the obtained white precipitates are dissolved to obtain a zinc oxide colloidal solution after cleaning the precipitate for two times or less than two times with a reaction solvent;

at step S12, the zinc oxide colloidal solution is formed on a prefabricated device substrate to prepare the zinc oxide film with surface hydroxyl content greater than or equal to 0.6, and the solvent is removed to prepare the zinc oxide film with the surface hydroxyl content greater than or equal to 0.6.

According to the preparation method of the QLED provided in this embodiment of the present application, a solution method is used to prepare a zinc oxide colloidal solution which is taken as a film-forming solution for forming the zinc oxide film with the surface hydroxyl content greater than or equal to 0.6. During the preparation process of the zinc oxide colloidal solution using the solution method, the obtained precipitate is cleaned for two times or less than two times with the reaction solvent to obtain the zinc oxide with the surface hydroxyl content greater than or equal to 0.6. The zinc oxide film with the surface hydroxyl content greater than or equal to 0.6 is used as the first ETL, the transmission of electrons to the quantum dot luminescent layer is suppressed, and the number of electrons injected into the quantum dot luminescent layer is reduced, such that the electrons and holes in the QLED can be more balanced, and the external quantum efficiency (EQE) of the QLED device is improved.

In this embodiment of the present application, regarding the composition of the QLED, and especially the description of the ETL, reference can be made to the first aspect described above. These contents are not repeatedly described herein in order to save space.

In the step S11, the zinc oxide colloidal solution is prepared through the solution method which can be one of alcoholysis method, hydrolysis method, etc. The basic process of preparation of the zinc oxide through the solution method is as follows: the zinc salt solution is mixed and reacted with the first alkaline solution to generate an intermediate of hydroxide, such as a zinc hydroxide, a condensation reaction is acted on the intermediate of hydroxide and zinc oxide nanoparticles are gradually generated.

In this embodiment of the present application, the zinc salt solution is a salt solution formed by dissolving the zinc salt in the solvent. Where, the zinc salt is selected from the salts that can react with the first alkaline liquor to generate zinc hydroxide. Said salts include but not limited to one of zinc acetate, zinc nitrate, zinc sulfate and zinc chloride. The solvent is selected from solvents which have good solubility for zinc salts and the generated zinc oxide nanoparticles, which includes but is not limited to water, organic alcohols, organic ethers and sulfones with high polarity. In some embodiments, the solvent is selected from at least one of water, organic alcohols, organic ethers and sulfones. This type of solvent not only has good solubility for zinc salts, but also is relatively stable as a reaction medium in alkaline environment and is not prone to introduce side reactions. Furthermore, this solvent has solubility for the end product (i.e., the zinc oxide nanoparticles) with polarity. In addition, the aforesaid solvent can ionize the alkali, and serve as the solvent for dissolving zinc salts, and serve as a diluting or dissolving solvent for the alkali, and promote the reaction between the alkali and zinc salts. As an example, the solvent can be selected from at least one of water, methanol, ethanol, propanol, butanol, ethylene glycol, 2-methoxyethanol, and dimethyl sulfoxide (DMSO).

In the embodiment of the present application, the first alkaline liquor is a solution formed by the alkali that can react with the zinc salt to generate zinc hydroxide. In particular, the first alkaline liquor provides Hydroxide ions that react with zinc ions in a reaction system. It should be understood that when the zinc salt contains doped metal ions, the first alkaline liquor reacts with the zinc ions and the doped metal ions simultaneously to generate hydroxide ions. In this embodiment of the present application, the first alkaline solution is obtained by dissolving the solvent or diluting the alkali. In one aspect, solid alkali, such as sodium hydroxide, can be dissolved by the solvent to form the first liquid alkali, the first liquid alkali is then added to the reaction system, which is conducive to the uniformity of dispersion of the first alkali in the reaction system. In another aspect, the concentration of alkali in the first alkaline solution can be adjusted to be between 0.1 mol/L and 2 mol/L by dissolving or diluting, in order to avoid the added concentration of alkali from being too high, thereby causing a reaction rate to be too fast and ultimately resulting in uneven sizes of the zinc oxide nanoparticles. Moreover, agglomeration of the zinc oxide particles occurs when the sizes of the zinc oxide particles are too large.

Where, the alkali in the first alkaline solution can be selected to be either inorganic alkali or organic alkali. A strong base or a weak alkali can be selected. In one possible embodiment, the alkali in the first alkaline liquor is selected from the alkali with K^{b}>10⁻¹. For example, the alkali with K^{b}>10⁻¹ is selected from at least one of potassium hydroxide, sodium hydroxide and lithium hydroxide. In one possible embodiment, the alkali in the first alkaline liquor is selected from the alkali with K^{b}<10⁻¹. For example, the alkali with K^{b}<10⁻¹ is selected from at least one of TMAH, ammonium hydroxide, ethanolamine and ethylenediamine. The solvent used for dissolving or diluting alkali to form the first alkaline solution is capable of dissolving alkali or mixing with alkali. In addition, the solvent and the zinc oxide nanoparticles have the same polarity. In some embodiments, the solvent used to dissolve or dilute the alkali to form the first alkaline solution may be the same as or different from the solvent in the zinc salt solution. In some embodiments, the solvent used to dissolve or dilute the alkali to form the first alkaline solution is selected to be the same as the solvent in the zinc salt solution, which is more conducive to obtaining a stable reaction system. Where, the same solvents include but are not limited to the solvents with higher polarity such as water, organic alcohol, organic ether, sulfone, etc. In some embodiments, the solvent is selected from at least one of water, organic alcohol, organic ether, and sulfone. As an example, the solvent can be selected to be at least one of water, methanol, ethanol, propanol, butanol, ethylene glycol, 2-methoxyethanol, and dimethyl sulfoxide (DMSO).

In some embodiments, the zinc salt solution is mixed with the first alkaline solution at a temperature range of 0-70° C., and the reaction lasts for 30 minutes to 4 hours to prepare the zinc oxide nanoparticles. In some embodiments, the method of mixing the zinc salt solution with the first alkaline solution includes: dissolving the zinc salt at room temperature (5° C.-40° C.) to obtain the zinc salt solution, and dissolving or diluting the alkali at the room temperature to obtain the first alkaline solution; adjusting the temperature of the zinc salt solution to the temperature range of 0-70° C. and adding the first alkaline solution. In this condition, the added alkali reacts with the zinc salt in the zinc salt solution to generate the zinc oxide nanoparticles and achieve good particle dispersion. When the reaction temperature is below 0° C., the generation of zinc oxide nanoparticles will be significantly decelerated, and special equipment needs to be used to achieve the reaction, the difficulty of the reaction is increased, and even under some conditions, the zinc oxide nanoparticles are not prone to be generated, and hydroxide intermediates can only be obtained. However, when the reaction temperature is higher than 70° C., the reaction activity is too high, and the generated zinc oxide nanoparticles are agglomerated seriously, which makes it difficult to obtain a well dispersed colloidal solution, later film formation of the zinc oxide colloidal solution is affected. In some embodiments, the reaction temperature between the zinc salt solution and the first alkaline solution is between room temperature and 50° C. In this condition, not only the formation of zinc oxide nanoparticles is facilitated, but also the obtained zinc oxide ions have good particle dispersion, which is conducive to the film formation of the zinc oxide colloidal solution. In some embodiments, the zinc salt solution is mixed with the first alkaline solution at the temperature ranging from 0 to 30° C., a qualified zinc oxide colloidal solution can be easily generated. In some embodiments, the zinc oxide colloidal solution can also be generated at the temperature ranging from 30° C. to 70° C., however, the quality of the obtained zinc oxide colloidal solution is not as good as that of the zinc oxide colloidal solution generated at the temperature ranging from 0 to 30° C., and the reaction time is be shortened. In some embodiments, in the step of mixing the zinc salt solution with the first alkaline solution, the zinc salt solution is mixed with the first alkaline solution according to a molar ratio of hydroxide ions to zinc ions of 1.5:1-2.5:1 to ensure the formation of the zinc oxide nanoparticles and reduce the generation of by-products due to reaction. When the molar ratio of the hydroxide ions to the zinc ions is less than 1.5:1, zinc salts are significantly excessive, such that a large number of zinc salts are not prone to generate zinc oxide nanoparticles. When the molar ratio of hydroxide ions to zinc ions is greater than 2.5:1, the first alkaline liquor is significantly excessive, and the excessive hydroxide ions and the intermediate of the zinc hydroxide form stable complex compound, which is not prone to be condensed to produce the zinc oxide nanoparticles. In some embodiments, in the step of mixing the zinc salt solution with the first alkaline liquor, the additive amount of the zinc salt solution and the first alkaline liquor meet the following requirements: a ratio of the molar amount of hydroxide ions provided by the first alkaline liquor to the molar amount of zinc ions provided by the zinc salts is in the range of 1.7:1-1.9:1.

In some embodiments, the zinc salt solution is mixed with the first alkaline solution and reacted at a reaction temperature of 0-70° C. for 30 minutes to 4 hours to ensure the formation of zinc oxide nanoparticles and control the particle sizes of the zinc oxide nanoparticles. When the reaction time is less than 30 minutes, the cluster seeds of zinc oxide are obtained through the reaction with too low reaction time. In this condition, the crystal state of the sample is incomplete and the crystal structure is poor. If the sample is used as the ETL material, the conductivity of the ETL will be poor. When the reaction time exceeds 4 hours, excessive particle growth time leads to excessively large and uneven particle sizes of the generated nanoparticles, a higher surface roughness of the zinc oxide colloidal solution is caused after film formation, the electron transport performance is affected. In some embodiments, the zinc salt solution is mixed with the first alkaline solution, the zinc salt solution and the first alkaline solution are reacted at a reaction temperature for 1-2 hours.

In some embodiments, the zinc salt solution is mixed with the first alkaline solution at a temperature of 0-70° C., and the reaction lasts for 30 minutes to 4 hours under stirring conditions to promote the uniformity of the reaction and the uniformity of the particles of the obtained zinc oxide nanoparticles, and uniformly sized zinc oxide nanoparticles are obtained.

In this embodiment of the present application, after the reaction is completed, a precipitating agent is added to the mixed solution after the reaction is completed, and precipitates are collected. The precipitating agent is selected to be a solvent which has a polarity being opposite to the polarity of the end product (i.e., zinc oxide nanoparticles). Thus, the precipitating agent is precipitated by reducing the solubility of the zinc oxide nanoparticles. In some embodiments, the precipitating agent is selected as the solvent having weaker polarity. This precipitating agent has a polarity being opposite to the polarity of the zinc oxide nanoparticles and thus is conducive to the precipitation of the zinc oxide nanoparticles. As an example, the precipitating agents include but are not limited to ethyl acetate, acetone, n-hexane, n-heptane, and other long chain alkanes with low polarity.

In some embodiments, 2-6 times of the volume of the precipitating agent are added to the mixed solution after the reaction, that is, the volume ratio of the precipitating agent to the mixed solution is in a range of 2:1-6:1, white precipitates are generated in the mixed solution. In this condition, it is ensured that the solubility of zinc oxide nanoparticles is not disrupted due to excessive precipitation of the precipitating agent, at the premise that the zinc oxide nanoparticles are fully precipitated. In some embodiments, the volume ratio of the precipitating agents to the mixed solution is in a range of 3:1-5:1.

In this embodiment of the present application, centrifugation processing is performed on the mixed solution after precipitation treatment to collect precipitates. According to this embodiment of the present application, the reaction solvent is used to clean the collected precipitates to remove reactants that are not involved in the reaction. By cleaning the obtained zinc oxide nanoparticles using the reaction solvent, excess zinc salts, alkalis, and other raw materials used for preparing the zinc oxide nanoparticles can be removed, the purity of the zinc oxide nanoparticles can be improved. It should be noted that the reaction solvent has been described above. In some embodiments, the reaction solvent is selected from at least one of water, organic alcohols, organic ethers, and sulfones. As an example, the reaction solvent is selected from at least one of water, methanol, ethanol, propanol, butanol, ethylene glycol, 2-methoxyethanol and DMSO.

In this embodiment of the present application, since the zinc salts are used to react with alkali to form the zinc oxide nanoparticles. In the polar zinc oxide solution, due to the inherent characteristics of the zinc oxide colloid, a large number of ionized hydroxyl groups are adsorbed on the surface of the zinc oxide colloid. These hydroxyl groups are negatively charged and are heavily adsorbed on the surfaces of the zinc oxide nanoparticles, thus, the surfaces of the zinc oxide nanoparticles have negative charges. Under the action of electrostatic coulomb repulsion between the zinc oxide nanoparticles, the zinc oxide nanoparticles can be dispersed in the polar solution and have good solution stability and dispersity. When this zinc oxide colloidal solution is deposited into the zinc oxide film, a large number of hydroxyl groups can still be coated on the surfaces of the solidified zinc oxide particles. When this type of zinc oxide film is used as the ETL in the QLED structure, due to the large number of negatively charged hydroxyl groups absorbed on the surface of zinc oxide, the transmission of electrons in the zinc oxide layer may be suppressed and blocked. Thus, the surface hydroxyl content of the zinc oxide film directly affects the injection of electrons into the QLED device. When the surface hydroxyl content is high, the transmission of electrons in the QLED device will be suppressed, and the number of electrons injected into the quantum dot luminescent layer will be decreased. When the surface hydroxyl content is low, the transmission of electrons in the QLED device will be smooth, and the number of electrons injected into the quantum dot luminescent layer will be increased. Therefore, according to the embodiment of the present application, the surface hydroxyl content of the obtained zinc oxide nanoparticles is adjusted by controlling the frequency of cleaning.

In particular, when the zinc oxide nanoparticles are cleaned more frequently, the residual hydroxyl content on the surfaces of the zinc oxide nanoparticles is fewer accordingly. In this embodiment of the present application, the reactive solvent is used to clean the precipitates for two times or less than two times. Thus, the surface hydroxyl content is greater than or equal to 0.6.

In one possible implementation method, if the alkali in the first alkaline solution is the alkali with K^{b}>10⁻¹, the number of cleaning operations is less than or equal to 2. In this condition, due to the high ionization coefficient of the alkali with K^{b}>10⁻¹, the surface of the finally synthesized zinc oxide colloid has a higher hydroxyl content. After the cleaning operations are performed for two times or less than two times, a state of high surface hydroxyl content of the zinc oxide can be maintained.

In one possible implementation method, if the alkali in the first alkaline solution is an alkali with K^{b}<10⁻¹, the number of cleaning operations is less than or equal to 1. When the alkali is the alkali with K^{b}<10⁻¹, due to the small ionization coefficient of the alkali, the finally synthesized zinc oxide colloid has less surface hydroxyl content. Thus, when the cleaning times is less than or equal to 1, more surface hydroxyl content can be achieved.

Where, the selection of different alkalis K_{b} can refer to the above descriptions. As an example, bases with K^{b}>10⁻¹ include but are not limited to potassium hydroxide, sodium hydroxide, lithium hydroxide and other inorganic strong alkalis. Alkalis with K^{b}<10⁻¹ include but are not limited to TMAH, ammonium hydroxide, ethanolamine, ethylenediamine and other weak organic alkalis.

In some embodiments, the alkali in the first alkaline liquor is selected from at least one of potassium hydroxide, sodium hydroxide, and lithium hydroxide. The collected precipitates are cleaned with the reaction solvent for one time, and the zinc oxide nanoparticles with the surface hydroxyl amount greater than or equal to 0.6 can be obtained. In some embodiments, the alkali in the first alkaline liquor is selected from at least one of TMAH, ammonium hydroxide, ethanolamine, and ethylenediamine. The collected precipitates are cleaned with reaction solvent for one time, and the zinc oxide nanoparticles with the surface hydroxyl amount greater than or equal to 0.6 can be obtained.

White precipitates are obtained after cleaning, the white precipitates are dissolved to obtain the zinc oxide colloidal solution.

In one possible implementation, the zinc oxide film with the surface hydroxyl content greater than or equal to 0.6 is metal doped zinc oxide film. Correspondingly, the zinc oxide film with the surface hydroxyl content greater than or equal to 0.6 is metal doped zinc oxide. In this condition, the zinc salt solution contains doped metal ions, too.

The types of the doped metals, the effects of the doping metals, and the doping content of the doped metals in metal doped zinc oxide film have been described above (in the condition where the ETL is the first ETL), and are not repeatedly described herein in order to save space.

In some embodiments, the doped metal in the metal doped zinc oxide film is selected from at least one of Mg²⁺ and Mn²⁺. In some embodiments, the doped metal in the metal doped zinc oxide film is selected from at least one of Al³⁺, Y³⁺, La³⁺, Li⁺, Gd³⁺, Zr⁴⁺, and Ce⁴⁺. The doping amount of the doped metal ions can refer to the above descriptions, and are not repeatedly described herein.

In some embodiments, the zinc salt solution contains zinc ions and doped metal ions, and in the step of mixing the zinc salt solution with the first alkaline liquor, the additive amount of the zinc salt solution and the first alkaline liquor meets the requirements that the ratio of the product of the molar amount of metal ions and the valence number to the molar amount of hydroxide ions is in the range of 0.75:1-1.25:1. In some embodiments, in the step of mixing the zinc salt solution with the first alkaline solution, the additive amount of the zinc salt solution and the first alkaline solution meets the requirement that the ratio of the product of the molar amount and the valence number of metal ions to the molar amount of hydroxide ions is 0.85:1-0.95:1.

In the aforesaid step S12, the zinc oxide colloidal solution can be formed on the prefabricated device substrate for preparing the zinc oxide film with the surface hydroxyl content greater than or equal to 0.6, according to the type of the QLED device to be prepared, and the solvent is removed to prepare the zinc oxide film with the surface hydroxyl content greater than or equal to 0.6.

In some embodiments, the formation of the aforesaid zinc oxide colloidal solution on the prefabricated device substrate can be achieved by one of the methods including but not limited to spin coating, scraping coating, printing, spraying, roller coating, electrodeposition, etc. After forming the aforesaid zinc oxide colloidal solution on the prefabricated device substrate, the solvent is removed through an annealing treatment, and the zinc oxide film with the surface hydroxyl content greater than or equal to 0.6 is obtained.

In one possible implementation method, the QLED is a non-inverted QLED, and the prefabricated device substrate includes an anode substrate and a quantum dot luminescent layer bonded to the anode substrate. In some embodiments, the prefabricated device substrate further includes a hole functional layer arranged between the anode substrate and the quantum dot luminescent layer. Where, the hole functional layer includes at least one of a hole transport layer, a hole injection layer, and an electron barrier layer.

In one possible implementation method, the QLED is an inverted QLED, and the prefabricated device substrate is a cathode substrate. In some embodiments, the prefabricated device substrate further includes an electron injection layer bonded to the cathode surface of the cathode substrate.

In some embodiments, the zinc oxide film with the surface hydroxyl content greater than or equal to 0.6 can be served as the ETL separately.

In some embodiments, the ETL includes two layers of zinc oxide films or n thin film lamination units each of which is composed of two layers of zinc oxide films. The two layers of zinc oxide films are referred to as the first ETL and the second ETL, respectively, n is greater than or equal to 2. In some embodiments, n is an integer greater than or equal to 2 and less than or equal to 9. Where, at least the first ETL is the zinc oxide film with the surface hydroxyl content greater than or equal to 0.6, which is prepared by the aforesaid method. Regarding the detail of the second ETL, reference can be made to the second ETL of the QLED device described above.

In some embodiments, the second ETL is a zinc oxide film with a surface hydroxyl content less than or equal to 0.4. Alternatively, the second ETL is a metal doped zinc oxide film. Where, the first ETL can be arranged on one side adjacent to the quantum dot luminescent layer or be arranged on one side adjacent to the cathode. Preferably, the second ETL is arranged on one side adjacent to the quantum dot luminescent layer or the metal doped zinc oxide film is arranged on one side adjacent to the quantum dot luminescent layer, and a smoother zinc oxide film can be obtained.

In some embodiments, the ETL includes a three layer zinc oxide film which is referred to as the first ETL, the second ETL, and the third ETL, respectively. Where, at least the first ETL is the zinc oxide film with the surface hydroxyl content greater than or equal to 0.6 which is prepared by the aforesaid method. Regarding the details of the second ETL and the third ETL, reference can be made to the embodiments where the ETL in the QLED device includes the third ETL as mentioned above.

In the aforesaid embodiment, the zinc oxide film with the surface hydroxyl content less than or equal to 0.4 can be formed by the zinc oxide colloidal solution with the surface hydroxyl content less than or equal to 0.4.

In the aforesaid embodiment, the metal doped zinc oxide film can be prepared by the method described below:

Mixing a zinc salt solution containing doped metal ions with the first alkaline solution at a temperature of 0-70° C. for reaction for 30 minutes to 4 hours; adding a precipitating agent to the mixed solution after the reaction and collecting the precipitate; after cleaning the precipitate with the reaction solvent, the white precipitate obtained is dissolved to obtain the doped zinc oxide colloidal solution; forming the metal doped zinc oxide colloidal solution on the substrate of the metal doped zinc oxide film to be prepared, and preparing the metal doped zinc oxide film. In this embodiment, the types of the zinc salt and the solvent of the zinc salt solution, and the content of the zinc salt solution, the type and the doping content of the doped ions, the type and the additive amount of the first alkaline solution, the reaction temperature and time, the selection and the additive amount of the precipitating agent are all in accordance with the step S11 of the embodiment of the present application. In this method, the zinc salt solution containing doped metal ions can be obtained by dissolving the zinc salt and the selected metal salt in a certain proportion in the solvent at room temperature. In the step of mixing the zinc salt solution containing doped metal ions with the first alkaline solution, the additive amount of alkali meets the following requirement: the ratio of the product of the molar amount and the valence number of metal ions to the molar amount of hydroxide ions is in the range of 0.75:1-1.25:1.

In the second implementation method, a preparation method for a quantum dot light-emitting diode (QLED) is provided in the present application. The QLED includes an anode and a cathode being oppositely arranged, a quantum dot luminescent layer arranged between the anode and cathode, and an electron transport layer (ETL) arranged between the quantum dot luminescent layer and the cathode. The ETL includes a first ETL, and the first ETL is a zinc oxide film with a surface hydroxyl content greater than or equal to 0.6.

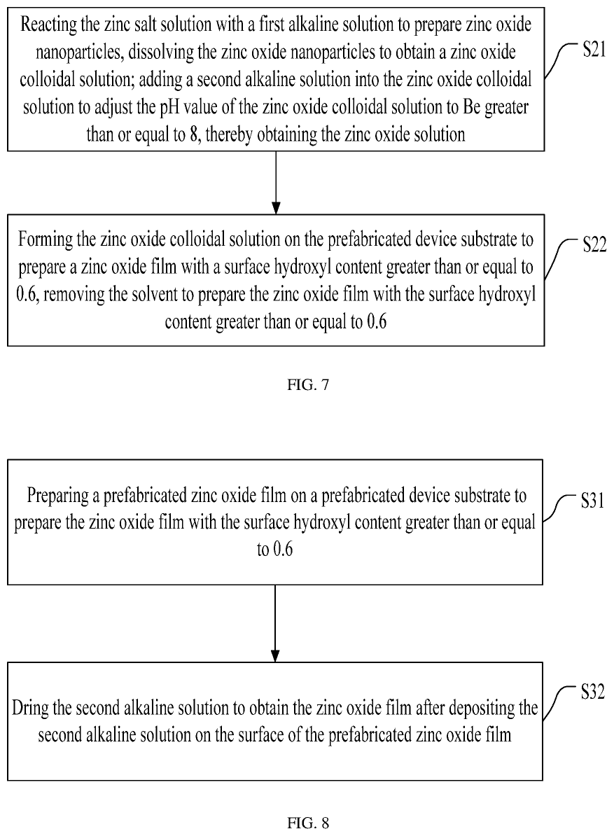

As shown in FIG. 7, a preparation method for the zinc oxide film with the surface hydroxyl content greater than or equal to 0.6, includes:

At step S21, a zinc salt solution is reacted with a first alkaline solution to prepare zinc oxide nanoparticles; the zinc oxide nanoparticles are dissolved to obtain a zinc oxide colloidal solution; a second alkaline solution is added into the zinc oxide colloidal solution, the pH value of the zinc oxide colloidal solution is adjusted to be greater than or equal to 8, and the zinc oxide solution is obtained;

At step S22, the zinc oxide colloidal solution is formed on the prefabricated device substrate to prepare a zinc oxide film with a surface hydroxyl content greater than or equal to 0.6, the solvent is removed, and the zinc oxide film with the surface hydroxyl content greater than or equal to 0.6 is prepared.

According to the preparation method of the QLED provided in this embodiment of the present application, a solution method is used to prepare the zinc oxide colloidal solution, then, a second alkaline solution is added to the zinc oxide colloidal solution, the pH value of the zinc oxide colloidal solution is adjusted to be greater than or equal to 8 to obtain the zinc oxide solution. The zinc oxide with the surface hydroxyl content greater than or equal to 0.6 is obtained. The zinc oxide film with the surface hydroxyl content greater than or equal to 0.6 is used as the first ETL, the transmission of electrons towards the quantum dot luminescent layer is suppressed, and the number of electrons injected into the quantum dot luminescent layer is reduced, such that the hole injection and electron injection in the QLED can be more balanced, and the lifetime of the QLED device is prolonged finally.

In this embodiment of the present application, the composition of the QLED, especially the detail of the ETL, can refer to the first aspect described above, and is not repeatedly described herein in order to save space.

The method of preparing the zinc oxide colloidal solution through the solution method in the step S21, the selection and the type of the zinc salt solution, the zinc salt and the solvent in zinc salt solution and the method for forming the zinc salt solution, the selection and the type of alkali and the solvent in the first alkaline solution, and the method for forming the first alkaline solution can refer to the descriptions in the step S11 of the first implementation method, and are not repeatedly described herein in order to save space. The reaction conditions and the reaction time for mixing the zinc salt solution with the first alkaline solution, the ratio of the zinc salt solution to the first alkaline solution, and the preferable situation can refer to the descriptions in the step S11 of the first implementation method, and are not repeatedly described herein in order to save space.

In some embodiments, after the reaction is completed, the precipitating agent is added to the mixed solution after the reaction to collect the precipitate. The selection of the precipitating agent can refer to the first embodiment as mentioned above.

In this embodiment of the present application, centrifugation treatment is performed on the mixed system and precipitates are collected. The method and the condition of the centrifugation treatment can refer to the first implementation method as mentioned above.

the precipitate after cleaning is dissolved to obtain the zinc oxide colloidal solution.

In this embodiment of the present application, the second alkaline solution is added to the zinc oxide colloidal solution, the pH value of the zinc oxide colloidal solution is adjusted to be greater than or equal to 8. The hydroxyl ligands on the surface of the zinc oxide and the ionized hydroxyl groups in the zinc oxide colloidal solution form a dynamic equilibrium. However, the addition of the second alkaline solution mentioned above will break this equilibrium. In particular, after the addition of the second alkaline solution, since the ionized hydroxyl content in the zinc oxide colloidal solution increases, the hydroxyl ligand content on the surface of zinc oxide increases correspondingly. However, at the same time, the additive amount of alkali in the second alkaline solution should not be too much (the pH value should not be too high), otherwise, the zinc oxide particles will react into zinc hydroxide, thereby reducing the concentration of the zinc oxide colloidal solution. Thus, in some embodiments, the pH value of the zinc oxide colloidal solution is adjusted between 9 and 12 by adding the second alkaline solution. Thus, a high yield (concentration) of zinc oxide nanoparticles can be obtained while ensuring that the surface hydroxyl content of the obtained zinc oxide is greater than or equal to 0.6. In some embodiments, the pH value of the zinc oxide colloidal solution is adjusted between 9 and 10 by adding the second alkaline solution.

In this embodiment of the present application, the alkali in the second alkaline liquor can be selected to be either inorganic alkali or organic base. Strong alkali or weak alkali can also be selected. In some embodiments, the second alkaline liquor is selected from the second alkaline liquor formed by at least one of potassium hydroxide, sodium hydroxide, Lithium hydroxide, TMAH, ammonium hydroxide, ethanolamine, and ethylenediamine. In this embodiment of the present application, the second alkaline solution is the solution formed by dissolving inorganic alkali or by dissolving or diluting organic alkali. By dissolving or diluting the alkali and adjusting the concentration of the second alkaline solution, the reaction rate can be controlled to fully adjust the surface hydroxyl content of zinc oxide nanoparticles. Where, the solvent used for dissolving or diluting acid to form the second alkaline solution can dissolve or be mixed with alkali, and the solvent has the same polarity as the zinc oxide nanoparticles. In some embodiments, the solvent used to dissolve or dilute the alkali to form the second alkaline solution can be the same as or different from the solvent in the zinc salt solution. In some embodiments, the solvent used for dissolving or diluting alkali to form the second alkaline solution includes but is not limited to the solvent with higher polarity, such as water, organic alcohols, organic ethers, sulfones, etc. In some embodiments, the solvent is selected from at least one of water, organic alcohols, organic ethers, and sulfones. As an example, the solvent can be at least one of water, methanol, ethanol, propanol, butanol, ethylene glycol, 2-methoxyethanol, and dimethyl sulfoxide (DMSO).

In one possible implementation, the zinc oxide film with the surface hydroxyl content greater than or equal to 0.6 is a metal doped zinc oxide film. Correspondingly, the zinc oxide with the surface hydroxyl content greater than or equal to 0.6 is the metal doped zinc oxide. In this condition, the zinc salt solution further contains doped metal ions. In this embodiment, the selection of the doped metal ions can refer to the selection of doped metals in the metal doped zinc oxide films as mentioned above.

In some embodiments, the zinc salt solution contains zinc ions and doped metal ions, and in the step of mixing the zinc salt solution with the first alkaline liquor, the additive amount of the zinc salt solution and the first alkaline liquor meets the requirement that the ratio of the product of the molar amount and the valence number of metal ions to the molar amount of hydroxide ions is in the range of 0.75:1-1.25:1. In some embodiments, in the step of mixing the zinc salt solution with the first alkaline solution, the additive amount of the zinc salt solution and the first alkaline solution meets the requirement that the ratio of the product of the molar amount and the valence number of metal ions to the molar amount of hydroxide ions is 0.85:1-0.95:1.

In the aforesaid step S22, the zinc oxide solution can be formed on the prefabricated device substrate to prepare the zinc oxide film with the surface hydroxyl content greater than or equal to 0.6 according to the type of the QLED device to be prepared, and the solvent can be removed to prepare the zinc oxide film with the surface hydroxyl content greater than or equal to 0.6.

The implementation method of the step S22 refers to the first implementation method as mentioned above.

A preparation method for a quantum dot light-emitting diode (QLED) is provided in the third embodiment of the present application. The QLED includes an anode and a cathode being oppositely arranged, a quantum dot luminescent layer arranged between the anode and cathode, and an electron transport layer (ETL) arranged between the quantum dot luminescent layer and the cathode. The ETL includes a first ETL, and the first ETL is a zinc oxide film with a surface hydroxyl content greater than or equal to 0.6.

As shown in FIG. 8, a preparation method for the zinc oxide film with the surface hydroxyl content greater than or equal to 0.6 includes:

At step S31, prefabricated zinc oxide film is prepared on a prefabricated device substrate to prepare the zinc oxide film with the surface hydroxyl content greater than or equal to 0.6;

At step S32, after depositing the second alkaline solution on the surface of the prefabricated zinc oxide film, the second alkaline solution is dried to obtain the zinc oxide film.

According to the preparation method of the QLED provided in this embodiment of the present application, alkali treatment is performed on the prefabricated zinc oxide film, and a liquid film is formed on the surface of the zinc oxide film. Thus, the hydroxyl content on the surface of the prefabricated zinc oxide film and the alkali content in the liquid film will form a dynamic equilibrium, then, the hydroxyl content on the surface of the prefabricated zinc oxide film is increased, and the zinc oxide which has the surface containing the hydroxyl content greater than or equal to 0.6 is obtained. In this condition, the zinc oxide film which has the surface containing hydroxyl content greater than or equal to 0.6 is used as the first ETL, the transmission of electron towards the quantum dot luminescent layer is suppressed, and the number of electrons injected into the quantum dot luminescent layer is reduced, such that the hole injection and electron injection in the QLED can be more balanced, and the lifetime of the QLED device is prolonged finally.

In this embodiment of the present application, the composition of the QLED, especially the detail of the ETL, refers to the first aspect and is not repeatedly described herein in order to save space.

In the step S31, prefabricated zinc oxide film can be prepared through various methods. For example, the prefabricated zinc oxide film can be prepared by a solution method or a sol gel method.

In some embodiments, the prefabricated zinc oxide film is prepared by the solution method. The solution method includes: mixing the zinc salt solution with the first alkaline solution to prepare zinc oxide nanoparticles; dissolving the zinc oxide nanoparticles to obtain the zinc oxide colloidal solution; forming the zinc oxide colloidal solution on the prefabricated device substrate to prepare the zinc oxide film with the surface hydroxyl content greater than or equal to 0.6, and removing the solvent to prepare the prefabricated zinc oxide film.

Where, the step of preparing the zinc oxide nanoparticles by mixing the zinc salt solution with the first alkaline solution refer to the step S11 of the aforesaid first implementation method and is not repeatedly described herein in order to save space.

In one possible implementation, the zinc oxide in the zinc oxide film with the surface hydroxyl content less than or equal to 0.4 is metal doped zinc oxide, and correspondingly, the zinc oxide in the zinc oxide film with the surface hydroxyl content less than or equal to 0.4 is metal doped zinc oxide. In this condition, the zinc salt solution further contains doped metal ions. In this embodiment, the selection of the doped metal ions and the doping content refer to the selection of the doped metals in metal doped zinc oxide film as mentioned above.

In this embodiment of the present application, the zinc oxide colloidal solution can be formed on the prefabricated device substrate to prepare the zinc oxide film with the surface hydroxyl content greater than or equal to 0.6, according to the type of the QLED device to be prepared, and the solvent is removed to prepare the zinc oxide film with the surface hydroxyl content greater than or equal to 0.6.

In some embodiments, the above zinc oxide colloidal solution is formed on the prefabricated device substrate, referring to the step S12 of “forming the zinc oxide colloidal solution on the prefabricated device substrate to be prepared with a surface hydroxyl content greater than or equal to 0.6, removing the solvent, and preparing the zinc oxide film with a surface hydroxyl content greater than or equal to 0.6”.

In the aforesaid step S32, the surface hydroxyl content of the prefabricated zinc oxide film is changed by depositing the second alkaline solution on the prefabricated zinc oxide film. In particular, when the second alkaline solution is deposited, a liquid film will be formed on the surface of the prefabricated zinc oxide film, thus, the hydroxyl groups on the surface of the prefabricated zinc oxide film and the alkali content in the liquid film will form a dynamic equilibrium. Thus, the hydroxyl groups on the surface of the prefabricated zinc oxide film are further increased.

In this embodiment of the present application, the alkali in the second alkaline liquor can be selected to be either inorganic alkali or organic base. Strong alkali or weak alkali can also be selected. In some embodiments, the second alkaline liquor is selected from the second alkaline liquor formed by at least one of potassium hydroxide, sodium hydroxide, lithium hydroxide, TMAH, ammonium hydroxide, ethanolamine, and ethylenediamine. In this embodiment of the present application, the second alkaline solution is the solution formed by dissolving inorganic alkali or by dissolving or diluting organic alkali. By dissolving or diluting the alkali and adjusting the concentration of the second alkaline solution, the reaction rate can be controlled to fully adjust the surface hydroxyl content of zinc oxide nanoparticles. Where, the solvent used for dissolving or diluting acid to form the second alkaline solution can dissolve or be mixed with alkali, and the solvent has the same polarity as the zinc oxide nanoparticles. In some embodiments, the solvent used to dissolve or dilute the alkali to form the second alkaline solution can be the same as or different from the solvent in the zinc salt solution. In some embodiments, the solvent used for dissolving or diluting alkali to form the second alkaline solution includes but is not limited to the solvent with higher polarity, such as water, organic alcohols, organic ethers, sulfones, etc. In some embodiments, the solvent is selected from at least one of water, organic alcohols, organic ethers, and sulfones. As an example, the solvent can be at least one of water, methanol, ethanol, propanol, butanol, ethylene glycol, 2-methoxyethanol, and dimethyl sulfoxide (DMSO).

In this embodiment of the present application, the concentration and the additive amount of the alkaline solution need to be controlled, this is because that when the concentration and the additive amount of alkali are too large, a large number of zinc hydroxide impurities will be produced on the surface of the prefabricated zinc oxide film, thereby affecting the quality of the zinc oxide film. However, when the concentration and the additive amount of alkali are too small, the surface hydroxyl content of zinc oxide is not prone to be increased. In some embodiments, the concentration of the second alkaline solution is between 0.05 mmol/L and 0.5 mmol/L. Thus, an appropriate concentration is obtained to regulate the surface hydroxyl content of the prefabricated zinc oxide film. In some embodiments, a deposition amount of the second alkaline solution and the weight of the lower layer of prefabricated zinc oxide film meet the following requirement: for every 5 mg of prefabricated zinc oxide film, a volume of 50 μL-1000 μL of the second alkaline solution is used for treatment. If the concentration of the second alkaline solution and the added amount of alkali are too large, a large number of zinc hydroxide impurities will be produced on the surface of the prefabricated zinc oxide film, thereby affecting the quality of the zinc oxide film. However, if the concentration of the second alkaline solution and the additive amount of alkali are too small, the surface hydroxyl content of zinc oxide is not prone to be increased. It should be understood that the concentration of the second alkaline solution can be flexibly adjusted according to different types of selected alkalis.

Inorganic alkali is generally strong alkali, and a hydroxide ion has strong ionization ability. Thus, the amount of hydroxyl on the surface of zinc oxide can be adjusted through only a small amount of inorganic alkali with low concentration. However, organic alkali is generally weak alkali, and the ionization capacity of the hydroxide ion is weak. Therefore, a relatively high concentration of organic alkali is required to effectively adjust the surface hydroxyl content of zinc oxide.

In some embodiments, the alkali in the second alkaline solution is the inorganic alkali, and the concentration of the second alkaline solution is in a range of 0.05-0.1 mmol/L. As an example, the inorganic alkali is selected from at least one of potassium hydroxide, sodium hydroxide and lithium hydroxide. In this condition, the deposition amount of the second alkaline solution and the weight of the lower layer of prefabricated zinc oxide film meet the following requirement: for every 5 mg of prefabricated zinc oxide film, a volume of 50 μL-400 μL of the second alkaline solution is used for treatment.

In some embodiments, the alkali in the second alkaline liquor is organic base, and the concentration of the correspondingly formed second alkaline liquor is in a range of 0.2-0.4 mmol/L. As an example, the organic carboxylic acid is selected from at least one of TMAH, ammonium hydroxide, ethanolamine and ethylenediamine. In this condition, the deposition amount of the second alkaline solution and the weight of the lower layer of prefabricated zinc oxide film meet the following requirement: for every 5 mg of prefabricated zinc oxide film, a volume of 500 μL-1000 μL of the second alkaline solution is used for treatment.

In this embodiment of the present application, the method of depositing the second alkaline solution on the surface of the prefabricated zinc oxide film can adopt a solution processing method which includes but is not limited to one of spin coating method, scratch coating method, printing method, spray coating method, roller coating method, electrodeposition method, etc.

After depositing the second alkaline solution on the surface of the prefabricated zinc oxide film, drying treatment is performed to enable the ionized hydrogen ions in the second alkaline solution to fully react with the hydroxyl groups on the surface of zinc oxide. In some embodiments, the drying temperature is between 10° C. and 100° C., and the drying time is between 10 minutes and 2 hours. In this condition, the ionized hydrogen ions in the second alkaline solution fully react with the hydroxyl groups on the surface of zinc oxide to increase the surface hydroxyl content of zinc oxide. If the drying temperature is too high or the time for drying treatment is too long, fast dry of the second alkaline solution is caused, and the prefabricated zinc oxide film will become a solid film quickly, which makes it difficult for the ionized hydrogen ions in the second alkaline solution to fully react with the hydroxyl groups on the surface of zinc oxide, and the surface hydroxyl content of zinc oxide is not prone to be effectively reduced. When the drying temperature is too low or the time for drying treatment is too short, it is difficult to fully dry the prefabricated zinc oxide film, the preparation of the next layer is affected, and especially, the quality of electrode evaporation is affected. In some embodiments, the drying temperature is between 10° C. and 50° C., and the drying time is between 30 minutes and 2 hours. By changing the surface hydroxyl content of zinc oxide through this method, an auxiliary layer formed by a small amount of alkali is maintained on the surface of the finally obtained thin film surface.

In one possible implementation method, the QLED is a non-inverted QLED, and the prefabricated device substrate includes an anode substrate and a quantum dot luminescent layer bonded to the anode substrate. In some embodiments, the prefabricated device substrate further includes a hole functional layer arranged between the anode substrate and the quantum dot luminescent layer. Where, the hole functional layer includes at least one of a hole transport layer, a hole injection layer, and an electron barrier layer.

In one possible implementation method, the QLED is an inverted QLED, and the prefabricated device substrate is a cathode substrate. In some embodiments, the prefabricated device substrate further includes an electron injection layer bonded to a cathode surface of the cathode substrate.

In some embodiments, the zinc oxide film with the surface hydroxyl content greater than or equal to 0.6 can be served as the ETL separately.

In some embodiments, the ETL includes two layers of zinc oxide films or n thin film lamination units, each of the n thin film lamination units is composed of two layers of zinc oxide films, and the two layers of zinc oxide films are referred to as the first ETL and the second ETL respectively, n is greater than or equal to 2. In some embodiments, n is an integer greater than or equal to 2 and less than or equal to 9. Where, at least the first ETL is the zinc oxide film with the surface hydroxyl content greater than or equal to 0.6, which is prepared by the aforesaid method. The detail of the second ETL can refer to descriptions of the second ETL of the QLED device mentioned above.

In some embodiments, the second ETL is the zinc oxide film with the surface hydroxyl content less than or equal to 0.4. Alternatively, the second ETL is a metal doped zinc oxide film. Where, the first ETL can be arranged on one side adjacent to the quantum dot luminescent layer or arranged on one side adjacent to the cathode. Preferably, the zinc oxide film with the surface hydroxyl content less than or equal to 0.4 or the metal doped zinc oxide film can be arranged on one side adjacent to the quantum dot luminescent layer, and a smoother zinc oxide film can be obtained.

In some embodiments, the ETL includes a three-layer zinc oxide film which is referred to as the first ETL, the second ETL, and the third ETL, respectively. Where, at least the first ETL is the zinc oxide film with the surface hydroxyl content greater than or equal to 0.6, which is prepared by the aforesaid method. The details of the second ETL and the third ETL can refer to the embodiments where the ETL in the QLED device includes the third ETL, as mentioned above.

In the aforesaid embodiment, the zinc oxide film with the surface hydroxyl content less than or equal to 0.4 can be formed by the zinc oxide colloidal solution with the surface hydroxyl content less than or equal to 0.4.

In the aforesaid embodiment, the metal doped zinc oxide film can be prepared through the preparation method for the metal doped zinc oxide film provided in the first implementation method. In some embodiments, the preparation of the metal doped zinc oxide film, includes:

Mixing a zinc salt solution containing doped metal ions with the first alkaline solution at a temperature of 0-70° C. for reaction for 30 minutes to 4 hours; adding a precipitating agent to the mixed solution after the reaction and collecting the precipitate; after cleaning the precipitate with the reaction solvent, the white precipitate obtained is dissolved to obtain the doped zinc oxide colloidal solution; forming the metal doped zinc oxide colloidal solution on the substrate of the metal doped zinc oxide film to be prepared, and preparing the metal doped zinc oxide film. In this embodiment, the types of the zinc salt and the solvent of the zinc salt solution, and the content of the zinc salt solution, the type and the doping content of the doped ions, the type and the additive amount of the first alkaline solution, the reaction temperature and time, the selection and the additive amount of the precipitating agent are all in accordance with the step S11 of the embodiment of the present application. In this method, the zinc salt solution containing doped metal ions can be obtained by dissolving the zinc salt and the selected metal salt in a certain proportion in the solvent at room temperature. In the step of mixing the zinc salt solution containing doped metal ions with the first alkaline solution, the additive amount of alkali meets the following requirement: the ratio of the product of the molar amount and the valence number of metal ions to the molar amount of hydroxide ions is in the range of 0.75:1-1.25:1.

The types of doped metals, the effects of doping metals, and the doping content of doped metals in metal doped zinc oxide film refer to the above descriptions (in the embodiments where the ETL is the first ETL), and are not repeatedly described herein in order to save space.

In some embodiments, the doped metal in the metal doped zinc oxide film is selected from at least one of Mg²⁺ and Mn²⁺. In some embodiments, the doped metal in the metal doped zinc oxide film is selected from at least one of Al³⁺, Y³⁺, La³⁺, Li⁺, Gd³⁺, Zr⁴⁺, and Ce⁴⁺. The doping amount of doped metal ions can refer to the above descriptions, and are not repeatedly described herein.

It should be understood that, in the three embodiments of the present application, when the device is a non-inverted QLED, after preparing the ETL, the method further includes evaporating a cathode on the ETL to obtain the QLED. In some embodiments, the method further includes preparing the electron injection layer on the ETL before evaporating the cathode on the ETL. When the device is an inverted QLED, after preparing the ETL, the method further includes preparing a two point luminescent layer on the ETL, and evaporating an anode on the quantum dot luminescent layer to obtain the QLED. In some embodiments, the preparation of the hole functional layer on the quantum dot luminescent layer is further included before the anode is evaporated.

In this embodiment of the present application, a solution processing method is preferably used in the method of forming the hole functional layer (which includes at least one layer of the hole injection layer, the hole transport layer, and the electron barrier layer) and the quantum dot luminescent layer. This method includes but is not limited to one of the spin coating method, the scratch coating method, the printing method, the spray coating method, the roller coating method, the electrodeposition method, etc.

A preparation method for a quantum dot light-emitting diode (QLED) is provided in the fourth implementation method of the present application. The method includes an anode and a cathode being oppositely arranged, a quantum dot luminescent layer arranged between the anode and cathode, and an ETL arranged between the quantum dot luminescent layer and the cathode. The ETL includes a first ETL containing zinc oxide, and the surface of the zinc oxide that forms the first ETL contains amino ligands and/or carboxyl ligands with 8-18 carbon atoms.

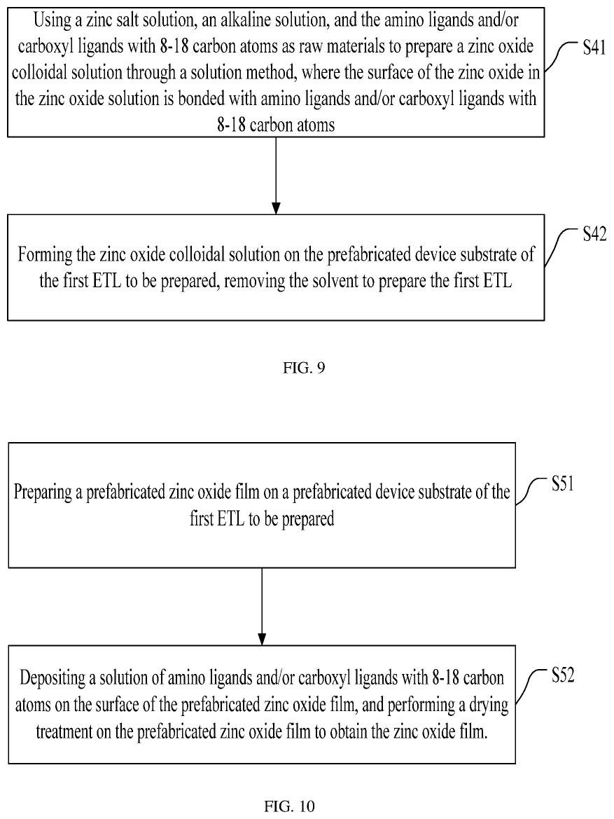

As shown in FIG. 9, the preparation method of the first ETL is described below:

At step S41, a zinc salt solution, an alkaline solution, and the amino ligands and/or carboxyl ligands with 8-18 carbon atoms are used as raw materials to prepare a zinc oxide colloidal solution through a solution method. Where the surface of the zinc oxide in the zinc oxide solution is bonded with amino ligands and/or carboxyl ligands with 8-18 carbon atoms.

At step S42, the zinc oxide colloidal solution is formed on the prefabricated device substrate of the first ETL to be prepared, the solvent is removed, and the first ETL is prepared.

According to the preparation method of the QLED provided in this embodiment of the present application, the amino ligands and/or the carboxyl ligands with 8-18 carbon atoms are added during the synthetic process of the zinc oxide colloidal solution, ligand exchange between the amino ligands and/or the carboxyl ligands and the hydroxyl ligands on the surface of the zinc oxide colloid is promoted, then, the amino ligands and/or the carboxyl ligands with 8-18 carbon atoms are coordinated on the surface of the zinc oxide colloid. Due to the long chain length of the coordinated amino ligands and/or the carboxyl ligands with 8-18 carbon atoms, under the space steric effect, the distance between the zinc oxide nanoparticles in the solution after film formation is increased, the electron mobility of the ETL is reduced, the transmission of electrons in the ETL is suppressed, the transmission of electrons in the QLED is reduced, and the electrons injected in the quantum dot luminescent layer is reduced accordingly. The injection balance of carriers in the QLED is realized, and the QLED with high EQE is obtained finally.

In this embodiment of the present application, the composition of the QLED, especially the detail of the ETL, the selection of the amino ligands and/or the carboxyl ligands with 8-18 carbon atoms, and the thickness of the zinc oxide film containing the amino ligands and/or the carboxyl ligands with 8-18 carbon atoms refer to the first aspect, and are not repeatedly described herein in order to save space.

In the step S41, the basic process of preparing the zinc oxide through the solution method is as follows: the zinc salt solution is mixed and reacted with the alkaline solution to generate an intermediate of hydroxide, such as zinc hydroxide. A condensation reaction is performed on the intermediate of hydroxide and the zinc oxide nanoparticles are gradually generated. On this basis, in the embodiment of the present application, the amino ligands and/or the carboxyl ligands with the chain length of 8-18 carbon atoms are added during the synthetic process of the zinc oxide colloidal solution, the ligand exchange between the amino ligands and/or the carboxyl ligands and the hydroxyl ligands on the surface of the zinc oxide colloid is enabled. Thus, the amino ligands and/or the carboxyl ligands of 8-18 carbon atoms are coordinated on the surface of the zinc oxide colloid. Due to the long chain length of the coordinated amino ligands and the carboxyl ligands, under the space steric effect, the distance between the zinc oxide nanoparticles in the zinc oxide colloidal solution after film formation is increased, the electron mobility of the zinc oxide ETL after film formation is further reduced, which actually plays the same role as the zinc oxide film with the surface hydroxyl content greater than or equal to 0.6.

In the method of preparing the zinc oxide colloidal solution through the solution method by using the zinc salt solution, the alkaline solution, and the amino ligands and/or the carboxyl ligands with 8-18 carbon atoms as raw materials, multiple time nodes for adding the amino ligands and/or the carboxyl ligands with 8-18 carbon atoms are provided. Several corresponding methods for preparing the zinc oxide colloidal solution through the solution method are provided.

In the first implementation method, the amino ligands and/or the carboxyl ligands with 8-18 carbon atoms are added into the zinc salt solution during the initial synthetic process of the zinc oxide colloidal solution, that is, the amino ligands and/or the carboxyl ligands with 8-18 carbon atoms and the alkaline solution are added into the zinc salt solution together.

In this condition, the step of preparing the zinc oxide colloidal solution through the solution method, includes:
the zinc salt solution, the alkaline solution, and the amino ligands and/or the carboxyl ligands with 8-18 carbon atoms are mixed and reacted to prepare the zinc oxide nanoparticles having the surfaces bonded with the amino ligands and/or the carboxyl ligands with 8-18 carbon atoms;
the zinc oxide nanoparticles are dissolved to obtain the zinc oxide colloidal solution.

In the aforesaid step, the zinc salt solution is the salt solution formed by dissolving the zinc salt in the solvent. Where, the zinc salt can react with the alkaline liquor to form zinc hydroxide salts, which includes but is not limited to one of zinc acetate, zinc nitrate, zinc sulfate and zinc chloride. The selected solvent has solubility for zinc salts, which include but are not limited to solvents with higher polarity, such as water, organic alcohols, organic ethers, sulfones, etc. In some embodiments, the solvent is selected from at least one of water, organic alcohols, organic ethers, and sulfones. This type of solvent has good solubility in zinc salts and is relatively stable as a reaction medium in alkaline environments, introduction of side reactions is not prone to occur. As an example, the solvent can be at least one of water, methanol, ethanol, propanol, butanol, ethylene glycol, 2-methoxyethanol, and dimethyl sulfoxide (DMSO).

In this embodiment of the present application, the alkaline solution is the solution which is formed by alkali and can react with the zinc salt to generate the zinc hydroxide. Alkaline solution is obtained by dissolution or dilution of the solvent. Where, inorganic alkali or organic alkali can be selected as the alkali in alkaline liquor. In one possible embodiment, the alkali in the alkaline liquor is the inorganic alkali. For example, the inorganic alkali is selected from at least one of potassium hydroxide, sodium hydroxide and lithium hydroxide. In one possible embodiment, the alkali in the alkaline liquor is the organic alkali. For example, the weak alkali is selected from at least one of TMAH, ammonium hydroxide, ethanolamine and ethylenediamine. In some embodiments, the solvent used to dissolve or dilute alkali to form the alkaline solution can be the same as or different from the solvent in the zinc salt solution. In some embodiments, the selection of the solvent for dissolving or diluting alkali to form the alkaline solution, which is the same as the solvent in the zinc salt solution, is more conducive to obtaining a stable reaction system. Where, the aforesaid same solvent includes but is not limited to the solvent with higher polarity, such as water, organic alcohols, organic ethers, sulfones, etc. In some embodiments, the solvent is selected from at least one of water, organic alcohols, organic ethers, and sulfones. As an example, the solvent can be at least one of water, methanol, ethanol, propanol, butanol, ethylene glycol, 2-methoxyethanol, and dimethyl sulfoxide (DMSO).

In some embodiments, the amino ligands and/or the carboxyl ligands with 8-18 carbon atoms include but are not limited to octanoic acid, octylamine, dodecanoic acid, lauryl amine, oleic acid, and oleylamine. In some embodiments, after the amino ligands and/or the carboxyl ligands with 8-18 carbon atoms are configured as the ligand solution, which is mixed and reacted with the zinc salt solution and the alkaline solution. The solvent in the ligand solution is selected to be the solvent with higher polarity, since the solubility of the reaction raw materials for reaction and products are mainly considered. As an example, the solvent in the ligand solution is selected from at least one of methanol, ethanol, propanol, butanol, ethylene glycol, 2-methoxyethanol and DMSO. In some embodiments, the amino ligands and/or the carboxyl ligands with 8-18 carbon atoms are the ligand solution, and the concentration of the ligand solution is in a range of 0.2-0.4 mmol/L. When the concentration is too low, the additive amount of the amino ligands and/or the carboxyl ligands with 8-18 carbon atoms is too small to achieve a function of effective ligand exchange. When the concentration is too high, the additive amount of the amino ligands and/or the carboxyl ligands with 8-18 carbon atoms will affect the polarity of the zinc oxide colloidal solution, and thereby affects the effectiveness of the next cleaning.

In some embodiments, the additive amount of the alkaline liquor meets the following requirement: the molar ratio of hydroxide ions provided by the alkaline liquor to the zinc ions provided by zinc salts is 1.5:1-2.5:1, so as to ensure the formation of the zinc oxide nanoparticles and reduce the generation of reaction by-products. When the molar ratio of the hydroxide ions to the zinc ions is less than 1.5:1, the zinc salts are significantly excessive, a large number of zinc salts are not prone to generate zinc oxide nanoparticles. When the molar ratio of the hydroxide ions to the zinc ions is greater than 2.5:1, the alkaline liquor is significantly excessive, and the excessive hydroxide ion and the intermediate of the zinc hydroxide form a stable complex compound, condensation polymerization is not prone to be performed to produce zinc oxide nanoparticles. In some embodiments, in the step of mixing the zinc salt solution with the alkaline solution, the additive amount of the zinc salt solution and the alkaline solution meets the following requirement: the ratio of the molar amount of the hydroxide ions provided by the alkaline solution to the molar amount of the zinc ions provided by the zinc salt is 1.7:1 to 1.9:1.

In some embodiments, the additive amount of the amino ligands and/or the carboxyl ligands with 8-18 carbon atoms meets the following requirement: the molar ratio of the amino ligands and/or the carboxyl ligands with 8-18 carbon atoms to the zinc salt in the zinc salt solution is in the range of 1:1-10:1. In this condition, the amino ligands and/or the carboxyl ligands with 8-18 carbon atoms are added to be bonded with the surfaces of the generated zinc oxide nanoparticles, thereby reducing the electron transfer efficiency of the zinc oxide film through the amino ligands and/or the carboxyl ligands with 8-18 carbon atoms, thereby realizing the injection balance of carriers in the QLED, which is conducive to improving the external quantum efficiency (EQE) of the QLED device. However, when the additive amount of the amino ligands and/or the carboxyl ligands with 8-18 carbon atoms is too small, the long chain ligands connected to the surface of the zinc oxide are less, which is not conducive to reducing the electron transfer efficiency and improving the EQE. When the additive amount of ligands is too high, there will be too many long chain ligand connections on the surface of the zinc oxide, and the hydrophilicity and the hydrophobicity of zinc oxide nanoparticles will transition from hydrophilicity to hydrophobicity, thereby resulting in poor solubility in polar solvents and affecting the film formation and device performance in the finally obtained QLED device.

When the chain length (13-18 carbon atoms) of ligands is longer, the electron mobility of the sample after ligand exchange will decrease. Thus, the electron mobility can be reduced and the EQE can be improved when the additive amount of ligands with longer chain length is not too much. In addition, when the additive amount of ligands with longer chain length is too much, the solubility of the zinc oxide nanoparticles in polar solvents will be reduced, the film formation of the zinc oxide layer in the final device is affected, and the device performance of the finally obtained QLED device is reduced. However, when the chain length (8-12 carbon atoms) of ligands is short, the electron mobility decreases slightly after the ligand exchange. Thus, the additive amount of the ligands with longer chain length needs to be higher to achieve the purpose of improving EQE. In some embodiments, the number of carbon atoms of the amino ligands and/or the carboxyl ligands is between 8-12, and the additive amount of the amino ligands and/or carboxyl ligands meets the following requirement: the molar ratio of the amino ligands and/or the carboxyl ligands to the zinc salts in the zinc salt solution is in the range of 4:1-10:1. In some embodiments, the number of carbon atoms of the amino ligands and/or carboxyl ligand is 13-18, and the additive amount of the amino ligands and/or the carboxyl ligands meets the following requirement: the molar ratio of the amino ligands and/or the carboxyl ligands to the zinc salts in the zinc salt solution is in the range of 1:1-5:1.

In some embodiments, the zinc salt solution, the alkaline solution, and the amino ligands and/or the carboxyl ligands with 8-18 carbon atoms are reacted for 30 minutes to 4 hours at the temperature ranging from 0 to 70° C. to prepare the zinc oxide nanoparticles with surfaces bonded with the amino ligands and/or the carboxyl ligands with 8-18 carbon atoms. In some embodiments, the method of mixing the zinc salt solution with the alkaline solution is as follows: the zinc salt is dissolved at room temperature (5° C.-40° C.) to obtain the zinc salt solution, the alkaline solution is obtained by dissolving or diluting alkali at room temperature, and the amino ligands and/or the carboxyl ligands with 8-18 carbon atoms are dissolved at room temperature to obtain the ligand solution; the temperature of the zinc salt solution is adjusted to 0-70° C., and the alkaline solution and the ligand solution are added. In this condition, the added alkali reacts with the zinc salt in the zinc salt solution to generate the zinc oxide nanoparticles. The added ligands exchange with the hydroxyl ligands on the surface of the zinc oxide nanoparticles to prepare the zinc oxide nanoparticles with surfaces containing the amino ligands and/or the carboxyl ligands with 8-18 carbon atoms, and good particle dispersion can be achieved. When the reaction temperature is lower than 0° C., the generation of zinc oxide nanoparticles will be significantly decreased, and even the generation of the zinc oxide nanoparticles is difficult, the intermediate of hydroxide can only be obtained. When the reaction temperature is above 70° C., the aggregation of the obtained zinc oxide nanoparticles is serious, and dispersity is poor, and the later film formation of the zinc oxide colloidal solution is affected. In some embodiments, the reaction temperature between the zinc salt solution and the alkaline solution is between room temperature and 50° C. In this condition, not only the formation of the zinc oxide nanoparticles is facilitated, the obtained zinc oxide ions have good particle dispersity, which is conducive to the film formation of the zinc oxide colloidal solution.

In some embodiments, in the step of mixing the zinc salt solution with the alkaline solution according to the molar ratio of hydroxide ions to the zinc ions of 1.5:1-2.5:1, the zinc salt solution is mixed with alkaline solution to ensure the formation of the zinc oxide nanoparticles and reduce the generation of reaction by-products. When the molar ratio of hydroxide ions to zinc ions is less than 1.5:1, the zinc salts are significantly excessive, thus, it is difficult for a large number of zinc salts to generate zinc oxide nanoparticles. When the molar ratio of hydroxide ions to zinc ions is greater than 2.5:1, the alkaline liquor is significantly excessive, and the excessive hydroxide ion and the intermediate of the zinc hydroxide form a stable complex compound, which is not prone to produce zinc oxide nanoparticles through polycondensation. In some embodiments, in the step of mixing the zinc salt solution with the alkaline solution, the additive amount of the zinc salt solution and the alkaline solution meets the following requirement: the ratio of the molar amount of hydroxide ions provided by the alkaline solution to the molar amount of the zinc ions provided by the zinc salts is 1.7:1 to 1.9:1.

In some embodiments, the zinc salt solution is mixed with the alkaline solution for reaction at the reaction temperature for 30 minutes to 4 hours to ensure the formation of the zinc oxide nanoparticles and control the particle sizes of the nanoparticles. When the reaction time is less than 30 minutes, the reaction time is too short, the formation of the zinc oxide nanoparticles is insufficient, and the crystallinity of the formed nanoparticles is poor. When the reaction time exceeds 4 hours, the too long particle growth time causes the generated nanoparticles to be too large and have uneven particle sizes, which affects the later film-forming properties of the zinc oxide colloidal solution. In some embodiments, after adding the amino ligands and/or the carboxyl ligands with 8-18 carbon atoms, the reaction lasts 10 minutes to 2 hours. In some embodiments, the zinc salt solution is mixed with the alkaline solution and the two solutions are reacted at the reaction temperature for 1-2 hours.

In some embodiments, the zinc salt solution, the alkaline solution, and the amino ligands and/or the carboxyl ligands with 8-18 carbon atoms are mixed under the temperature ranging from 0 to 70° C., and a stirring reaction is performed to promote the uniformity of the reaction and the particle uniformity of the obtained zinc oxide nanoparticles.

In this embodiment of the present application, after the reaction is completed, a precipitating agent is added to the mixed solution after the reaction is completed, and precipitates are collected. The precipitating agent is selected to be a solvent which has a polarity being opposite to the polarity of the end product (i.e., zinc oxide nanoparticles). Thus, the precipitating agent is precipitated by reducing the solubility of the zinc oxide nanoparticles. In some embodiments, the precipitating agent is selected as the solvent having weaker polarity. This precipitating agent has a polarity being opposite to the polarity of the zinc oxide nanoparticles and thus is conducive to the precipitation of the zinc oxide nanoparticles. As an example, the precipitating agents include but are not limited to ethyl acetate, acetone, n-hexane, n-heptane, and other long chain alkanes with low polarity.

In some embodiments, 2-6 times of the volume of the precipitating agent (i.e., the volume ratio of the precipitating agent to the mixed solution is in a range of 2:1-6:1) is added to the mixed solution after the reaction, white precipitates are generated in the mixed solution. In this condition, it is ensured that the solubility of zinc oxide nanoparticles is not disrupted due to excessive precipitation of the precipitating agent while the zinc oxide nanoparticles are fully precipitated. In some embodiments, the volume ratio of the precipitating agent to the mixed solution is in a range of 3:1-5:1.

In this embodiment of the present application, the centrifugation processing is performed on the mixed system after precipitation treatment and precipitates are collected. In some embodiments, the reaction solvent is used to clean the collected precipitates so as to remove the reactants that are not involved in the reaction. The obtained zinc oxide nanoparticles are cleaned using the reaction solvent, excessive zinc salts, alkalis, and other raw materials used for preparing zinc oxide nanoparticles can be removed, and the purity of zinc oxide nanoparticles can be improved accordingly. It should be noted that the reaction solvent refers to the above descriptions. In some embodiments, the reaction solvent is selected from at least one of water, organic alcohols, organic ethers, and sulfones. This type of reaction solvent has a high polarity and can effectively remove residual impurities such as zinc salts, alkalis, and intermediate impurities in the zinc oxide nanoparticles. As an example, the reaction solvent is selected from at least one of water, methanol, ethanol, propanol, butanol, ethylene glycol, 2-methoxyethanol and DMSO.

The precipitates after cleaning processing are dissolved to obtain the zinc oxide colloidal solution.

In the second implementation method, the amino ligands and/or the carboxyl ligands with 8-18 carbon atoms are added during the synthetic process of the zinc oxide colloidal solution. That is, the amino ligands and/or the carboxyl ligands with 8-18 carbon atoms are added to the zinc oxide precursor solution that has already added alkaline solution.

In this condition, the step of preparing the zinc oxide colloidal solution through the solution method, includes:
mixing the zinc salt solution with the alkaline solution for reaction, and adding the amino ligands and/or the carboxyl ligands with 8-18 carbon atoms during the reaction process to prepare the zinc oxide nanoparticles having surfaces bonded with the amino ligands and/or the carboxyl ligands with 8-18 carbon atoms. Where, the reaction time after adding the amino ligands and/or the carboxyl ligands with 8-18 carbon atoms is greater than or equal to 10 minutes;
dissolving the zinc oxide nanoparticles to obtain the zinc oxide colloidal solution.

In the above step, the zinc salt solution is the salt solution formed by dissolving the zinc salt in the solvent, and the alkaline solution is the solution formed by the alkali that can react with the zinc salt to generate the zinc hydroxide. Where, regarding the selection of the zinc salt and the solvent in the zinc salt solution, the alkali in the alkaline solution and the formation method thereof, the selection of the solvent, and the addition ratio of the zinc salt and the alkaline solution in the reaction system, reference can be made to the descriptions in the first implementation method mentioned above.

In some embodiments, the amino ligands and/or the carboxyl ligands with 8-18 carbon atoms include but are not limited to octanoic acid, octylamine, dodecanoic acid, lauryl amine, oleic acid, and oleylamine. In some embodiments, after the amino ligands and/or the carboxyl ligands with 8-18 carbon atoms are configured as ligand solution, and the ligand solution is mixed with the zinc salt solution and the alkaline solution for reaction. The solvent in the ligand solution should be selected as the solvent with higher polarity, under the consideration of the solubility of the reaction raw materials and products mainly. As an example, the solvent in the ligand solution is selected from at least one of methanol, ethanol, propanol, butanol, ethylene glycol, 2-methoxyethanol and DMSO. In some embodiments, the amino ligands and/or the carboxyl ligands with 8-18 carbon atoms are ligand solution, and the concentration of the ligand solution is in a range of 0.2-0.4 mmol/L. When the concentration is too low, the additive amount of the amino ligands and/or the carboxyl ligands with 8-18 carbon atoms is too small to have an effective ligand exchange function. When the concentration is too high, the additive amount of the amino ligands and/or the carboxyl ligands with 8-18 carbon atoms will affect the polarity of the zinc oxide colloidal solution, and thereby affects the effectiveness of the next cleaning.

In this embodiment of the present application, the reaction temperature and the time for mixing the zinc salt solution with the alkaline solution have been described in the first implementation method mentioned above.

In this embodiment of the present application, the amino ligands and/or the carboxyl ligands with 8-18 carbon atoms are added during the reaction process to prepare the zinc oxide nanoparticles having surfaces bonded with the amino ligands and/or the carboxyl ligands with 8-18 carbon atoms.

In some embodiments, the additive amount of the amino ligands and/or the carboxyl ligands with 8-18 carbon atoms meets the following requirement: the molar ratio of the amino ligands and/or the carboxyl ligands with 8-18 carbon atoms to the zinc salt in the zinc salt solution is in the range of 1:1-10:1. In this condition, the amino ligands and/or the carboxyl ligands with 8-18 carbon atoms are added to be bonded with the surfaces of the generated zinc oxide nanoparticles, thereby reducing the electron transfer efficiency of the zinc oxide film through the amino ligands and/or the carboxyl ligands with 8-18 carbon atoms, thereby realizing the injection balance of carriers in the QLED, which is conducive to improving the external quantum efficiency (EQE) of the QLED device. However, when the additive amount of the amino ligands and/or the carboxyl ligands with 8-18 carbon atoms is too small, the long chain ligands connected to the surface of the zinc oxide are less, which is not conducive to reducing the electron transfer efficiency and improving the EQE. When the additive amount of ligands is too high, there will be too many long chain ligand connections on the surface of the zinc oxide, and the hydrophilicity and the hydrophobicity of zinc oxide nanoparticles will transition from hydrophilicity to hydrophobicity, thereby resulting in poor solubility in polar solvents and affecting the film formation and device performance in the finally obtained QLED device.

When the chain length (13-18 carbon atoms) of ligands is longer, the electron mobility of the sample after ligand exchange will decrease. Thus, the electron mobility can be reduced and the EQE can be improved when the additive amount of ligands with longer chain length is not too much. In addition, when the additive amount of ligands with longer chain length is too much, the solubility of the zinc oxide nanoparticles in polar solvents will be reduced, the film formation of the zinc oxide layer in the final device is affected, and the device performance of the finally obtained QLED device is reduced. However, when the chain length (8-12 carbon atoms) of ligands is short, the electron mobility decreases slightly after the ligand exchange. Thus, the additive amount of the ligands with longer chain length needs to be higher to achieve the purpose of improving EQE. In some embodiments, the number of carbon atoms of the amino ligands and/or the carboxyl ligands is between 8-12, and the additive amount of the amino ligands and/or carboxyl ligands meets the following requirement: the molar ratio of the amino ligands and/or the carboxyl ligands to the zinc salts in the zinc salt solution is in the range of 4:1-10:1. In some embodiments, the number of carbon atoms of the amino ligands and/or carboxyl ligand is 13-18, and the additive amount of the amino ligands and/or the carboxyl ligands meets the following requirement: the molar ratio of the amino ligands and/or the carboxyl ligands to the zinc salts in the zinc salt solution is in the range of 1:1-5:1.

It should be noted that the reaction time after adding amino ligands and/or carboxyl ligands with 8-18 carbon atoms is greater than or equal to 10 minutes, allowing the ligands to fully exchange with the hydroxyl groups on the surface of the generated zinc oxide nanoparticles. In some embodiments, amino ligands and/or carboxyl ligands with 8-18 carbon atoms are added during the reaction process and stirred for a time of 10 minutes to 2 hours to fully carry out the exchange reaction. In some embodiments, the stirring time is between 30 minutes and 1 hour.

In some embodiments, after the reaction is completed, the precipitating agent is added to the mixed solution after the reaction to collect the precipitates. The selection and the additive amount of the precipitating agent have been described in the first implementation method mentioned above.

In this embodiment of the present application, centrifugation processing is performed on the mixed solution after precipitation treatment to collect precipitates. According to this embodiment of the present application, a reaction solvent is used to clean the collected precipitates to remove reactants that are not involved in the reaction. By cleaning the obtained zinc oxide nanoparticles using the reaction solvent, excess zinc salts, alkalis, and other raw materials used for preparing the zinc oxide nanoparticles can be removed, the purity of the zinc oxide nanoparticles can be improved. It should be noted that the reaction solvent has been described above. In some embodiments, the reaction solvent is selected from at least one of water, organic alcohols, organic ethers, and sulfones. As an example, the reaction solvent is selected from at least one of water, methanol, ethanol, propanol, butanol, ethylene glycol, 2-methoxyethanol and DMSO.

The precipitate after cleaning is dissolved to obtain the zinc oxide colloidal solution.

In the third implementation method, the amino ligands and/or the carboxyl ligands with 8-18 carbon atoms are added after the zinc oxide colloidal solution is prepared.

In this condition, the step of preparing the zinc oxide colloidal solution through the solution method include:

After mixing the zinc salt solution with the alkaline solution for reaction to prepare the zinc oxide nanoparticles, the amino ligands and/or the carboxyl ligands with 8-18 carbon atoms are added, and the reaction is continued to be performed to prepare the zinc oxide nanoparticles with 8-18 carbon atoms having surfaces bonded with the amino ligands and/or the carboxyl ligands.

The zinc oxide nanoparticles are dissolved to obtain the zinc oxide colloidal solution.

In the above step, the zinc salt solution is the salt solution formed by dissolving the zinc salt in the solvent, and the alkaline solution is the solution formed by the alkali that can react with the zinc salt to generate the zinc hydroxide. Where, regarding the selection of the zinc salt and the solvent in the zinc salt solution, the alkali in the alkaline solution and the formation method thereof, the selection of the solvent, and the addition ratio of the zinc salt and the alkaline solution in the reaction system, reference can be made to the descriptions in the first implementation method mentioned above.

In some embodiments, the amino ligands and/or the carboxyl ligands with 8-18 carbon atoms, the selection of the solvent in the ligand solution, and the concentration of the ligand solution have been described in the first implementation method mentioned above.

In this embodiment of the present application, the reaction temperature and the reaction time for mixing the zinc salt solution with the alkaline solution have been described in the first implementation method mentioned above.

In this embodiment of the present application, the amino ligands and/or the carboxyl ligands with 8-18 carbon atoms are added into the zinc oxide nanoparticles prepared after reaction to prepare the zinc oxide nanoparticles having surfaces bonded with the amino ligands and/or the carboxyl ligands with 8-18 carbon atoms.

In some embodiments, the additive amount of the amino ligands and/or the carboxyl ligands with 8-18 carbon atoms meets the following requirement: the molar ratio of the amino ligands and/or the carboxyl ligands with 8-18 carbon atoms to the zinc salt in the zinc salt solution is in the range of 1:1-10:1. In this condition, the amino ligands and/or the carboxyl ligands with 8-18 carbon atoms are added to be bonded with the surfaces of the generated zinc oxide nanoparticles, thereby reducing the electron transfer efficiency of the zinc oxide film through the amino ligands and/or the carboxyl ligands with 8-18 carbon atoms, thereby realizing the injection balance of carriers in the QLED, which is conducive to improving the external quantum efficiency (EQE) of the device. However, when the additive amount of the amino ligands and/or the carboxyl ligands with 8-18 carbon atoms is too small, the long chain ligands connected to the surface of the zinc oxide are less, which is not conducive to reducing the electron transfer efficiency and improving the EQE. When the additive amount of ligands is too high, there will be too many long chain ligand connections on the surface of the zinc oxide, and the hydrophilicity and the hydrophobicity of zinc oxide nanoparticles will transition from hydrophilicity to hydrophobicity, thereby resulting in poor solubility in polar solvents and affecting the film formation and device performance in the finally obtained device.

When the chain length (13-18 carbon atoms) of ligands is longer, the electron mobility of the sample after ligand exchange will decrease. Thus, the electron mobility can be reduced and the EQE can be improved when the additive amount of ligands with longer chain length is not too much. In addition, when the additive amount of ligands with longer chain length is too much, the solubility of the zinc oxide nanoparticles in polar solvents will be reduced, the film formation of the zinc oxide layer in the final device is affected, and the device performance of the finally obtained QLED device is reduced. However, when the chain length (8-12 carbon atoms) of ligands is short, the electron mobility decreases slightly after the ligand exchange. Thus, the additive amount of the ligands with longer chain length needs to be higher to achieve the purpose of improving EQE. In some embodiments, the number of carbon atoms of the amino ligands and/or the carboxyl ligands is between 8-12, and the additive amount of the amino ligands and/or carboxyl ligands meets the following requirement: the molar ratio of the amino ligands and/or the carboxyl ligands to the zinc salts in the zinc salt solution is in the range of 4:1-10:1. In some embodiments, the number of carbon atoms of the amino ligands and/or carboxyl ligand is 13-18, and the additive amount of the amino ligands and/or the carboxyl ligands meets the following requirement: the molar ratio of the amino ligands and/or the carboxyl ligands to the zinc salts in the zinc salt solution is in the range of 1:1-5:1.

It should be noted that the reaction time after adding amino ligands and/or carboxyl ligands with 8-18 carbon atoms is greater than or equal to 10 minutes, the ligands are allowed to fully exchange with the hydroxyl groups on the surface of the generated zinc oxide nanoparticles. In some embodiments, the amino ligands and/or the carboxyl ligands with 8-18 carbon atoms are added during the reaction process and are stirred for a time of 10 minutes to 2 hours to fully perform the exchange reaction. In some embodiments, the stirring time is between 30 minutes and 1 hour.

In some embodiments, after the reaction is completed, the precipitating agent is added to the mixed solution after the reaction to collect the precipitates. The selection and the additive amount of the precipitating agent have been described in the first implementation method mentioned above.

In this embodiment of the present application, the centrifugation processing is performed on the mixed solution after precipitation treatment to collect precipitates. According to this embodiment of the present application, the reaction solvent is used to clean the collected precipitates to remove reactants that are not involved in the reaction. By cleaning the obtained zinc oxide nanoparticles using the reaction solvent, excess zinc salts, alkalis, and other raw materials used for preparing the zinc oxide nanoparticles can be removed, the purity of the zinc oxide nanoparticles can be improved. It should be noted that the reaction solvent has been described above. In some embodiments, the reaction solvent is selected from at least one of water, organic alcohols, organic ethers, and sulfones. As an example, the reaction solvent is selected from at least one of water, methanol, ethanol, propanol, butanol, ethylene glycol, 2-methoxyethanol and DMSO.

The precipitates after cleaning are dissolved to obtain the zinc oxide colloidal solution.

In the fourth implementation method, after preparing and cleaning the zinc oxide nanoparticles, the amino ligands and/or the carboxyl ligands with 8-18 carbon atoms are added.

In this condition, the step of preparing the zinc oxide colloidal solution through the solution method, includes:
mixing the zinc salt solution with alkaline solution for reaction, collecting and cleaning the product to obtain the zinc oxide nanoparticles;
after dissolving the zinc oxide nanoparticles, adding the amino ligands and/or the carboxyl ligands with 8-18 carbon atoms for reaction, and the amino ligands and/or the carboxyl ligands with 8-18 carbon atoms are bonded with the surface of zinc oxide to obtain the zinc oxide colloidal solution.

In the above step, the zinc salt solution is the salt solution formed by dissolving the zinc salt in the solvent, and the alkaline solution is the solution formed by the alkali that can react with the zinc salt to generate the zinc hydroxide. Where, regarding the selection of the zinc salt and the solvent in the zinc salt solution, the alkali in the alkaline solution and the formation method thereof, the selection of the solvent, and the addition ratio of the zinc salt and the alkaline solution in the reaction system, reference can be made to the descriptions in the first implementation method mentioned above.

In this embodiment, the reaction temperature and the reaction time for reaction of the zinc salt solution have been described in the first implementation method mentioned above.

In some embodiments, after the reaction is completed, the precipitating agent is added to the mixed solution after the reaction and the precipitates are collected. The selection and the additive amount of precipitating agent have been described in the first implementation method mentioned above.

In this embodiment of the present application, the centrifugation processing is performed on the mixed system after precipitation treatment and precipitates are collected. In some embodiments, the reaction solvent is used to clean the collected precipitates so as to remove the reactants that are not involved in the reaction. The obtained zinc oxide nanoparticles are cleaned using the reaction solvent, excessive zinc salts, alkalis, and other raw materials used for preparing zinc oxide nanoparticles can be removed, and the purity of zinc oxide nanoparticles can be improved accordingly. It should be noted that the reaction solvent refers to the above descriptions. In some embodiments, the reaction solvent is selected from at least one of water, organic alcohols, organic ethers, and sulfones. This type of reaction solvent has a high polarity and can effectively remove residual impurities such as zinc salts, alkalis, and intermediate impurities in the zinc oxide nanoparticles. As an example, the reaction solvent is selected from at least one of water, methanol, ethanol, propanol, butanol, ethylene glycol, 2-methoxyethanol and DMSO.

In this embodiment of the present application, after the zinc oxide nanoparticles are dissolved, the amino ligands and/or the carboxyl ligands with 8-18 carbon atoms are added to react with the dissolved zinc oxide nanoparticles. The amino ligands and/or the carboxyl ligands with 8-18 carbon atoms are bounded with the surface of zinc oxide to obtain the zinc oxide colloidal solution.

In some embodiments, the amino ligands and/or the carboxyl ligands with 8-18 carbon atoms include but are not limited to octanoic acid, octylamine, dodecanoic acid, lauryl amine, oleic acid, and oleylamine. In some embodiments, after the amino ligands and/or the carboxyl ligands with 8-18 carbon atoms are configured as the ligand solution, which is mixed and reacted with the zinc salt solution and the alkaline solution. The solvent in the ligand solution is selected to be the solvent with higher polarity, since the solubility of the reaction raw materials for reaction and products are mainly considered. As an example, the solvent in the ligand solution is selected from at least one of methanol, ethanol, propanol, butanol, ethylene glycol, 2-methoxyethanol and DMSO. In some embodiments, the amino ligands and/or the carboxyl ligands with 8-18 carbon atoms are the ligand solution, and the concentration of the ligand solution is in a range of 0.05-0.1 mmol/L. When the concentration is too low, the additive amount of the amino ligands and/or the carboxyl ligands with 8-18 carbon atoms is too small to achieve a function of effective ligand exchange. In this embodiment, the amine/carboxyl ligand solution is added to the finally obtained zinc oxide colloidal solution after cleaning, and further cleaning and purification processes are not existed. Therefore, when the concentration is too high, the additive amount of the amino ligands and/or the carboxyl ligands with 8-18 carbon atoms is too much, and the remaining ligands will be directly remained in the finally obtained zinc oxide ETL film. The excessive ligands have an impact on the film forming quality and the properties of the zinc oxide ETL.

In some embodiments, the additive amount of the amino ligands and/or the carboxyl ligands with 8-18 carbon atoms meets the following requirement: the molar ratio of the amino ligands and/or the carboxyl ligands with 8-18 carbon atoms to the zinc salt in the zinc salt solution is in the range of 1:4-4:1. In this condition, the added amino ligands and/or the carboxyl ligands with 8-18 carbon atoms are bounded with the surfaces of the generated zinc oxide nanoparticles, the electron mobility of the zinc oxide ETL is reduced, and the initial EQE of the QLED device is improved. However, at the same time, when the additive amount of the amino ligands and/or the carboxyl ligands with 8-18 carbon atoms is too small, the number of the long chain ligands connected with the surface of the zinc oxide are less, the electron transfer efficiency is not prone to be reduced, and the EQE is not prone to be improved. When the additive amount of the ligands is too high, there will be too many long chain ligand connections on the surface of the zinc oxide, hydrophilicity and hydrophobicity of zinc oxide nanoparticles will transition from hydrophilicity to hydrophobicity. Thus, polar solvent has a poor solubility, and the film formation and device performance in the final QLED device are affected.

When the chain length (13-18 carbon atoms) of ligands is longer, the electron mobility of the sample after ligand exchange will decrease. Thus, the electron mobility can be reduced and the EQE can be improved when the additive amount of ligands with longer chain length is not too much. In addition, when the additive amount of ligands with longer chain length is too much, the solubility of the zinc oxide nanoparticles in polar solvents will be reduced, the film formation of the zinc oxide layer in the final device is affected, and the device performance of the finally obtained QLED device is reduced. However, when the chain length (8-12 carbon atoms) of ligands is short, the electron mobility decreases slightly after the ligand exchange. Thus, the additive amount of the ligands with longer chain length needs to be higher to achieve the purpose of improving EQE. In some embodiments, the number of carbon atoms of the amino ligands and/or the carboxyl ligands is between 8-12, and the additive amount of the amino ligands and/or carboxyl ligands meets the following requirement: the molar ratio of the amino ligands and/or the carboxyl ligands to the zinc salts in the zinc salt solution is in the range of 1:1-10:1. In some embodiments, the number of carbon atoms of the amino ligands and/or carboxyl ligand is 13-18, and the additive amount of the amino ligands and/or the carboxyl ligands meets the following requirement: the molar ratio of the amino ligands and/or the carboxyl ligands to the zinc salts in the zinc salt solution is in the range of 1:4-5:1.

It should be noted that the reaction time after adding amino ligands and/or carboxyl ligands with 8-18 carbon atoms is greater than or equal to 10 minutes, the ligands are allowed to fully exchange with the hydroxyl groups on the surface of the generated zinc oxide nanoparticles. In some embodiments, the amino ligands and/or the carboxyl ligands with 8-18 carbon atoms are added during the reaction process and are stirred for a time of 10 minutes to 2 hours to fully perform the exchange reaction. In some embodiments, the stirring time is between 30 minutes and 1 hour.

In the aforesaid step S42, the zinc oxide colloidal solution can be formed on the prefabricated device substrate according to the type of the prepared QLED device, and the solvent is removed to prepare the zinc oxide film having the surface bounded with the amino ligands and/or the carboxyl ligands with 8-18 carbon atoms.

In some embodiments, the formation of the aforesaid zinc oxide colloidal solution on the prefabricated device substrate can be achieved by one of the methods including but not limited to spin coating, scraping coating, printing, spraying, roller coating, electrodeposition, etc. After forming the aforesaid zinc oxide colloidal solution on the prefabricated device substrate, the solvent is removed through an annealing treatment to obtain the zinc oxide film having the surface bounded with the amino ligands and/or the carboxyl ligands with 8-18 carbon atoms.

In one possible implementation method, the QLED is a non-inverted QLED, and the prefabricated device substrate includes an anode substrate and a quantum dot luminescent layer bonded on the anode substrate. In some embodiments, the prefabricated device substrate further includes a hole functional layer arranged between the anode substrate and the quantum dot luminescent layer. Where, the hole functional layer includes at least one of the hole transport layer, the hole injection layer, and the electron barrier layer.

In one possible implementation method, the QLED is an inverted QLED, and the prefabricated device substrate is a cathode substrate. In some embodiments, the prefabricated device substrate further includes an electron injection layer bonded with the cathode surface of the cathode substrate.

In some embodiments, the first ETL can be served as an electron transport layer (ETL) separately.

In some embodiments, the ETL includes two layers of zinc oxide films or n thin film lamination units each of which is composed of two layers of zinc oxide films. The two layers of zinc oxide films are referred to as the first ETL and the second ETL, respectively, n is greater than or equal to 2. In some embodiments, n is an integer greater than or equal to 2 and less than or equal to 9. Where, at least the first ETL is the zinc oxide film having the surface bounded with the amino ligands and/or the carboxyl ligands with 8-18 carbon atoms, which is prepared by the aforesaid method. Regarding the detail of the second ETL, reference can be made to the second ETL of the QLED device described above.

In some embodiments, the second ETL is the zinc oxide film with the surface hydroxyl content less than or equal to 0.4. Alternatively, the second ETL is a metal doped zinc oxide film. Where, the first ETL can be arranged on one side adjacent to the quantum dot luminescent layer or on the side adjacent to the cathode. Preferably, the second ETL is arranged on one side adjacent to the quantum dot luminescent layer or the metal doped zinc oxide film is arranged on one side adjacent to the quantum dot luminescent layer, a smoother zinc oxide film can be obtained.

In some embodiments, the ETL includes a three-layer zinc oxide film which is referred to as the first ETL, the second ETL, and the third ETL, respectively. Where, at least the first ETL is the zinc oxide film having the surface bounded with the amino ligands and/or the carboxyl ligands with 8-18 carbon atoms, which is prepared by the aforesaid method. Regarding the details of the second ETL and the third ETL, reference can be made to the embodiments where the ETL in the QLED device includes the third ETL as mentioned above.

In the aforesaid embodiment, the zinc oxide film with the surface hydroxyl content greater than or equal to 0.6 can be formed through the zinc oxide colloidal solution with the surface hydroxyl content greater than or equal to 0.6.

In the aforesaid embodiment, the zinc oxide film with the surface hydroxyl content less than or equal to 0.4 can be formed through the zinc oxide colloidal solution with the surface hydroxyl content less than or equal to 0.4.

In the aforesaid embodiment, the metal doped zinc oxide film can be prepared according to the method described below:

Mixing a zinc salt solution containing doped metal ions with the first alkaline solution at a temperature of 0-70° C. for reaction for 30 minutes to 4 hours; adding a precipitating agent to the mixed solution after the reaction and collecting the precipitate; after cleaning the precipitate with the reaction solvent, the white precipitate obtained is dissolved to obtain the doped zinc oxide colloidal solution; forming the metal doped zinc oxide colloidal solution on the substrate of the metal doped zinc oxide film to be prepared, and preparing the metal doped zinc oxide film. In this embodiment, the types of the zinc salt and the solvent of the zinc salt solution, and the content of the zinc salt solution, the type and the doping content of the doped ions, the type and the additive amount of the first alkaline solution, the reaction temperature and time, the selection and the additive amount of the precipitating agent are all in accordance with the step S11 of the embodiment of the present application. In this method, the zinc salt solution containing doped metal ions can be obtained by dissolving the zinc salt and the selected metal salt in a certain proportion in the solvent at room temperature. In the step of mixing the zinc salt solution containing doped metal ions with the first alkaline solution, the additive amount of alkali meets the following requirement: the ratio of the product of the molar amount and the valence number of metal ions to the molar amount of hydroxide ions is in the range of 0.75:1-1.25:1.

In the fifth embodiment, a quantum dot light-emitting diode (QLED) is provided in the embodiments of the present application. The QLED includes an anode and a cathode being oppositely arranged, a quantum dot luminescent layer arranged between the anode and cathode, and an electron transport layer (ETL) arranged between the quantum dot luminescent layer and the cathode. The ETL includes a first ETL, and at least one side of the surface of the first ETL contains amino ligands and/or carboxyl ligands with 8-18 carbon atoms.

Where, as shown in FIG. 10, a preparation method of the first ETL includes:

At step S51, a prefabricated zinc oxide film is prepared on a prefabricated device substrate of the first ETL to be prepared;

At step S52, a solution of amino ligands and/or carboxyl ligands with 8-18 carbon atoms is deposited on the surface of the prefabricated zinc oxide film, and a drying treatment is performed on the prefabricated zinc oxide film to obtain the zinc oxide film.

According to the preparation method of the QLED provided in this embodiment of the present application, the solution of the amino ligands and/or the carboxyl ligands with 8-18 carbon atoms is deposited on the prefabricated zinc oxide film, ligand exchange between the amino ligands and/or the carboxyl ligands and the hydroxyl ligands on the surface of the zinc oxide colloid is promoted. Then, the amino ligands and/or the carboxyl ligands with 8-18 carbon atoms are coordinated on the surface of the zinc oxide colloid. Due to the long chain length of the coordinated amino ligands and/or the carboxyl ligands with 8-18 carbon atoms, under the space steric effect, the distance between the zinc oxide nanoparticles in the solution after film formation is increased, the electron mobility of the ETL is reduced, the transmission of electrons in the ETL is suppressed, the transmission of electrons in the QLED is reduced, and the electrons injected in the quantum dot luminescent layer is reduced accordingly. The injection balance of carriers in the QLED is realized, and the QLED with high EQE is obtained finally.

In this embodiment of the present application, the composition of the QLED, and especially the detail of the ETL, has been described in the first aspect, and is not repeatedly described herein in order to save space.

In the aforesaid step S51, the prefabricated zinc oxide film can be prepared through various methods. For example, the prefabricated zinc oxide film can be prepared by a solution method or a sol gel method.

In some embodiments, the prefabricated zinc oxide film is prepared by the solution method, which includes: mixing the zinc salt solution with the alkaline solution to prepare the zinc oxide nanoparticles; dissolving the zinc oxide nanoparticles to obtain the zinc oxide colloidal solution; forming a zinc oxide colloidal solution on the prefabricated device substrate of the first ETL to be prepared, and removing the solvent to prepare the prefabricated zinc oxide film.

The zinc oxide colloidal solution is prepared through the solution method, the solution method can be one of alcoholysis method, hydrolysis method, etc. The basic process of preparing the zinc oxide through the solution method is as follows: mixing the zinc salt solution with the alkaline solution for reaction to produce an intermediate of hydroxide, such as zinc hydroxide; a condensation reaction is performed on the intermediate of hydroxide and the zinc oxide nanoparticles are gradually generated.

In this embodiment of the present application, the basis of selection and the types of the zinc salt in the zinc salt solution, and the formation method of the zinc salt solution have been described in the first implementation method.

In some embodiments, the zinc salt solution is mixed with the first alkaline solution at a temperature range of 0-70° C., and the reaction lasts for 30 minutes to 4 hours to prepare the zinc oxide nanoparticles. In some embodiments, the method of mixing the zinc salt solution with the first alkaline solution includes: dissolving the zinc salt at room temperature (5° C.-40° C.) to obtain the zinc salt solution, and dissolving or diluting the alkali at the room temperature to obtain the first alkaline solution; adjusting the temperature of the zinc salt solution to the temperature range of 0-70° C. and adding the first alkaline solution. In this condition, the added alkali reacts with the zinc salt in the zinc salt solution to generate the zinc oxide nanoparticles and achieve good particle dispersion. When the reaction temperature is below 0° C., the generation of zinc oxide nanoparticles will be significantly decelerated, and special equipment needs to be used to achieve the reaction, the difficulty of the reaction is increased, and even under some conditions, the zinc oxide nanoparticles are not prone to be generated, and hydroxide intermediates can only be obtained. However, when the reaction temperature is higher than 70° C., the reaction activity is too high, and the generated zinc oxide nanoparticles are agglomerated seriously, which makes it difficult to obtain a well dispersed colloidal solution, later film formation of the zinc oxide colloidal solution is affected. In some embodiments, the reaction temperature between the zinc salt solution and the first alkaline solution is between room temperature and 50° C. In this condition, not only the formation of zinc oxide nanoparticles is facilitated, but also the obtained zinc oxide ions have good particle dispersion, which is conducive to the film formation of the zinc oxide colloidal solution. In some embodiments, the zinc salt solution is mixed with the first alkaline solution at the temperature ranging from 0 to 30° C., a qualified zinc oxide colloidal solution can be easily generated. In some embodiments, the zinc oxide colloidal solution can also be generated at the temperature ranging from 30° C. to 70° C., however, the quality of the obtained zinc oxide colloidal solution is not as good as that of the zinc oxide colloidal solution generated at the temperature ranging from 0 to 30° C., and the reaction time is be shortened.

In some embodiments, in the step of mixing the zinc salt solution with the first alkaline solution, the zinc salt solution is mixed with the first alkaline solution according to a molar ratio of hydroxide ions to zinc ions of 1.5:1-2.5:1 to ensure the formation of the zinc oxide nanoparticles and reduce the generation of by-products due to reaction. When the molar ratio of the hydroxide ions to the zinc ions is less than 1.5:1, zinc salts are significantly excessive, such that a large number of zinc salts are not prone to generate zinc oxide nanoparticles. When the molar ratio of hydroxide ions to zinc ions is greater than 2.5:1, the first alkaline liquor is significantly excessive, and the excessive hydroxide ions and the intermediate of the zinc hydroxide form stable complex compound, which is not prone to be condensed to produce the zinc oxide nanoparticles. In some embodiments, in the step of mixing the zinc salt solution with the first alkaline liquor, the additive amount of the zinc salt solution and the first alkaline liquor meet the following requirements: a ratio of the molar amount of hydroxide ions provided by the first alkaline liquor to the molar amount of zinc ions provided by the zinc salts is in the range of 1.7:1-1.9:1.

In some embodiments, the zinc salt solution is mixed with the first alkaline solution and reacted at a reaction temperature of 0-70° C. for 30 minutes to 4 hours to ensure the formation of zinc oxide nanoparticles and control the particle sizes of the zinc oxide nanoparticles. When the reaction time is less than 30 minutes, the cluster seeds of zinc oxide are obtained through the reaction with too low reaction time. In this condition, the crystal state of the sample is incomplete and the crystal structure is poor. If the sample is used as the ETL material, the conductivity of the ETL will be poor. When the reaction time exceeds 4 hours, excessive particle growth time leads to excessively large and uneven particle sizes of the generated nanoparticles, a higher surface roughness of the zinc oxide colloidal solution is caused after film formation, the electron transport performance is affected. In some embodiments, the zinc salt solution is mixed with the first alkaline solution, the zinc salt solution and the first alkaline solution are reacted at a reaction temperature for 1-2 hours.

In some embodiments, the zinc salt solution is mixed with alkaline solution at the temperature of 0-70° C., and the reaction is performed for 30 minutes to 4 hours under stirring condition to promote the uniformity of the reaction and the particle uniformity of the obtained zinc oxide nanoparticles, and uniformly sized zinc oxide nanoparticles are prepared.

In this embodiment of the present application, the prepared zinc oxide nanoparticles are dissolved to obtain the zinc oxide colloidal solution.

In this embodiment of the present application, the method of obtaining the zinc oxide nanoparticles further includes: after the reaction is completed, adding a precipitating agent to the mixed solution after the reaction is completed, and collecting precipitates. The precipitating agent is selected to be a solvent which has a polarity being opposite to the polarity of the end product (i.e., zinc oxide nanoparticles). Thus, the precipitating agent is precipitated by reducing the solubility of the zinc oxide nanoparticles. In some embodiments, the precipitating agent is selected as the solvent having weaker polarity. This precipitating agent has a polarity being opposite to the polarity of the zinc oxide nanoparticles and thus is conducive to the precipitation of the zinc oxide nanoparticles. As an example, the precipitating agents include but are not limited to ethyl acetate, acetone, n-hexane, n-heptane, and other long chain alkanes with low polarity.

In some embodiments, 2-6 times of the volume of the precipitating agent are added to the mixed solution after the reaction, that is, the volume ratio of the precipitating agent to the mixed solution is in a range of 2:1-6:1, white precipitates are generated in the mixed solution. In this condition, it is ensured that the solubility of zinc oxide nanoparticles is not disrupted due to excessive precipitation of the precipitating agent, at the premise that the zinc oxide nanoparticles are fully precipitated. In some embodiments, the volume ratio of the precipitating agents to the mixed solution is in a range of 3:1-5:1.

In this embodiment of the present application, centrifugation processing is performed on the mixed solution after precipitation treatment to collect precipitates. According to this embodiment of the present application, the reaction solvent is used to clean the collected precipitates to remove reactants that are not involved in the reaction. By cleaning the obtained zinc oxide nanoparticles using the reaction solvent, excess zinc salts, alkalis, and other raw materials used for preparing the zinc oxide nanoparticles can be removed, the purity of the zinc oxide nanoparticles can be improved. It should be noted that the reaction solvent has been described above. In some embodiments, the reaction solvent is selected from at least one of water, organic alcohols, organic ethers, and sulfones. As an example, the reaction solvent is selected from at least one of water, methanol, ethanol, propanol, butanol, ethylene glycol, 2-methoxyethanol and DMSO.

White precipitates are obtained after cleaning, the obtained white precipitates are dissolved to obtain the zinc oxide colloidal solution.

In one possible implementation, the first ETL is the metal doped zinc oxide film. Correspondingly, the zinc oxide in the first ETL is the metal doped zinc oxide. In this condition, the zinc salt solution contains doped metal ions, too. In this embodiment, the selection of doped metal ions and doping content refer to the selection of the doped metals in the metal doped zinc oxide film mentioned above.

In this embodiment of the present application, the zinc oxide colloidal solution can be formed on the prefabricated device substrate of the first ETL to be prepared according to the type of the QLED device to be prepared, and the solvent is removed to prepare the prefabricated zinc oxide film.

In some embodiments, the formation of the aforesaid zinc oxide colloidal solution on the prefabricated device substrate can be achieved by one of the methods including but not limited to spin coating, scraping coating, printing, spraying, roller coating, electrodeposition, etc. After forming the aforesaid zinc oxide colloidal solution on the prefabricated device substrate, the solvent is removed through an annealing treatment, and the zinc oxide film with the surface hydroxyl content greater than or equal to 0.6 is obtained.

In some embodiments, the zinc oxide prefabrication film is prepared through the sol gel method (i.e., a high-temperature calcination method). In particular, zinc oxide precursor is directly spin-coated on the substrate of the prefabricated zinc oxide film to be prepared, and then a high-temperature heat treatment is performed on the zinc oxide precursor to make the zinc oxide precursor to become zinc oxide.

In the aforesaid step S52, the ligand exchange of the amino ligands and/or the carboxyl ligands and the hydroxyl ligands on the surface of the zinc oxide colloid is promoted by depositing the solution of the amino ligands and/or the carboxyl ligand with 8-18 carbon atoms on the prefabricated zinc oxide film. Thus, the amino ligands and/or the carboxyl ligands with 8-18 carbon atoms are coordinated on the surface of the zinc oxide colloid.

In this embodiment of the present application, coordination solution of the amino ligands and/or the carboxyl ligands with 8-18 carbon atoms refers to the ligand solution obtained by dissolving and coordinating the amino ligands and/or the carboxyl ligands with 8-18 carbon atoms in the solvent. In some embodiments, the amino ligands and/or the carboxyl ligands with 8-18 carbon atoms include but are not limited to octanoic acid, octylamine, dodecanoic acid, lauryl amine, oleic acid, and oleylamine. In some embodiments, the solvent with higher polarity is selected to because that the solubility of reaction raw materials and products are mainly considered. In some embodiments, the solvent used to dissolve the amino ligands and/or the carboxyl ligands with 8-18 carbon atoms includes but is not limited to one of the solvents with high polarity, such as water and alcohol. For example, the solvent used to dissolve the amino ligands and/or carboxyl ligands with 8-18 carbon atoms is selected from at least one of water, methanol, ethanol, propanol, butanol, ethylene glycol, 2-methoxyethanol, DMSO.

In this embodiment of the present application, the concentration and the additive amount of the solution of the amino ligands and/or the carboxyl ligands with 8-18 carbon atoms need to be controlled. This is because that when the concentration is too low, the amount of the amino ligands and/or the carboxyl ligands with 8-18 carbon atoms is too small to have an effective ligand exchange function. When the concentration of ligands is too high, the additive amount of the amino ligands and/or the carboxyl ligands with 8-18 carbon atoms is too high, and the large amount of residual ligands in the solution will be directly remained in the final first ETL, thereby affecting the film forming quality and the properties of the ETL. In some embodiments, the concentration of the ligand solution of the amino ligands and/or the carboxyl ligands with 8-18 carbon atoms is in the range of 0.05-0.1 mmol/L.

In some embodiments, the concentration of amino ligand and/or carboxyl ligand solutions with 8-18 carbon atoms is 0.05-0.1 mmol/L, and in the step after depositing amino ligand and/or carboxyl ligand solutions with 8-18 carbon atoms on the surface of prefabricated zinc oxide films, the additive amount of amino ligand and/or carboxyl ligand solutions with 8-18 carbon atoms meets the following requirements: the solution of the amine ligands and/or the carboxyl ligands with 8-18 carbon atoms with the volume of 50 μL-1000 μL is deposited for every 5 mg of the prefabricated zinc oxide film.

When the chain length (13-18 carbon atoms) of ligands is longer, the electron mobility of the sample after ligand exchange will decrease. Thus, the electron mobility can be reduced and the EQE can be improved when the additive amount of ligands with longer chain length is not too much. In addition, when the additive amount of ligands with longer chain length is too much, the solubility of the zinc oxide nanoparticles in polar solvents will be reduced, the film formation of the zinc oxide layer in the final device is affected, and the device performance of the finally obtained QLED device is reduced. However, when the chain length (8-12 carbon atoms) of ligands is short, the electron mobility decreases slightly after the ligand exchange. Thus, the additive amount of the ligands with longer chain length needs to be higher to achieve the purpose of improving EQE. In some embodiments, when the number of the carbon atoms of the amino ligands and/or the carboxyl ligands with 8-18 carbon atoms is between 8 and 12, the additive amount of the amino ligands and/or the carboxyl ligands with 8-18 carbon atoms meets the following requirement: depositing the solution of the amino ligands and/or the carboxyl ligands with 8-12 carbon atoms with a volume of 100 μL-500 μL for every 5 mg of the prefabricated zinc oxide film. When the number of the carbon atoms of the amino ligands and/or the carboxyl ligands with 8-18 carbon atoms are between 13 and 18, the additive amount of the amino ligands and/or the carboxyl ligands with 8-18 carbon atoms meets the following requirement: the solution of the amino ligands and/or the carboxyl ligands with 13-18 carbon atoms with the volume of 50 μL-300 μL is deposited for every 5 mg of prefabricated zinc oxide film.

In this embodiment of the present application, the method of depositing the solution of the amino ligands and/or the carboxyl ligands with 8-18 carbon atoms on the surface of the prefabricated zinc oxide film can adopt the solution processing method, which includes but is not limited to one of the spin coating method, the scratch coating method, the printing method, the spray coating method, the roller coating method, the electrodeposition method, etc.

After depositing the solution of the amino ligands and/or the carboxyl ligands with 8-18 carbon atoms on the surface of the prefabricated zinc oxide film, a drying treatment is performed to enable the ligands in the solution of the amino ligands and/or the carboxyl ligands with 8-18 carbon atoms to fully exchange with the hydroxyl groups on the surface of zinc oxide. In some embodiments, the drying temperature is between 10° C. and 100° C., and the drying time is between 10 minutes and 2 hours. In this condition, electric ligands in the amino ligands and/or the oxyl ligands with 8-18 carbon atoms fully react with the hydroxyl groups on the surface of zinc oxide to increase the distances among the zinc oxide nanoparticles after film formation under the effect of the spatial Steric effects, thereby reducing the electron mobility of the zinc oxide ETL after film formation. If the drying temperature is too high or the time for drying treatment is too long, the amino ligands and/or the carboxyl ligands with 8-18 carbon atoms may be quickly dried, and the prefabricated zinc oxide film will become a solid film quickly. Thus, the ligands in the amino ligands and/or the carboxyl ligands with 8-18 carbon atoms are not prone to fully react with the hydroxyl groups on the surface of zinc oxide. When the drying temperature is too low or the time for drying treatment is too short, the prefabricated zinc oxide film is not prone to be fully dried, the preparation of the next layer is affected, and especially, the quality of electrode evaporation is affected. In some embodiments, the drying temperature is in a range of 10° C.-50° C., and the drying time is between 30 minutes and 2 hours.

In one possible implementation, the QLED is a non-inverted QLED, and the prefabricated device substrate includes an anode substrate and a quantum dot luminescent layer bonded to the anode substrate. In some embodiments, the prefabricated device substrate further includes a hole functional layer arranged between the anode substrate and the quantum dot luminescent layer. Where, the hole functional layer includes at least one of a hole transport layer, a hole injection layer, and an electron barrier layer.

In one possible implementation, the QLED is an inverted QLED, and the prefabricated device substrate is a cathode substrate. In some embodiments, the prefabricated device substrate further includes an electron injection layer bonded to the cathode surface of the cathode substrate.

In some embodiments, the first ETL can serve as an ETL separately.

In some embodiments, the ETL includes two layers of zinc oxide films or n thin film lamination units each of which is composed of two layers of zinc oxide films. The two layers of zinc oxide films are referred to as the first ETL and the second ETL, respectively, and n is greater than or equal to 2. In some embodiments, n is an integer greater than or equal to 2 and less than or equal to 9. Where, at least the first ETL is the zinc oxide film having the surface bonded with the amino ligands and/or the carboxyl ligands with 8-18 carbon atoms, which is prepared by the aforesaid method. Regarding the detail of the second ETL, reference can be made to the second ETL of the QLED device described above.

In some embodiments, the second ETL is the zinc oxide film with the surface hydroxyl content less than or equal to 0.4, or alternatively, the second ETL is a metal doped zinc oxide film. Where, the first ETL can be arranged on one side adjacent to the quantum dot luminescent layer or on the side adjacent to the cathode. Preferably, the second ETL is arranged on one side adjacent to the quantum dot luminescent layer, or the metal doped zinc oxide film is arranged on one side adjacent to the quantum dot luminescent layer, and a smoother zinc oxide film is obtained.

In some embodiments, the ETL includes a three-layer zinc oxide film, which is referred to as the first ETL, the second ETL, and the third ETL, respectively. Where, at least the first ETL is the zinc oxide film prepared by the above method and having the surface bonded with the amino ligands and/or the carboxyl ligands with 8-18 carbon atoms. The second ETL and the third ETL can refer to the embodiments where the ETL in the QLED device includes the third ETL.

In this embodiment of the present application, the preparation method of the zinc oxide film with the surface hydroxyl content greater than or equal to 0.6 can refer to the previous text.

In some embodiments, the preparation method for zinc oxide film with the surface hydroxyl content less than or equal to 0.4, includes:
mixing the zinc salt solution with the alkaline solution to prepare the zinc oxide nanoparticles; dissolving the zinc oxide nanoparticles to obtain the zinc oxide colloidal solution; adding an acid solution to the zinc oxide colloidal solution, adjusting the pH value of the zinc oxide colloidal solution to between 7 and 8 to obtain the zinc oxide solution;
forming a zinc oxide solution on a prefabricated device substrate of the zinc oxide film with the surface hydroxyl content less than or equal to 0.4, and removing the solvent to prepare the zinc oxide film with the surface hydroxyl content less than or equal to 0.4.

In some embodiments, in the step of adding the acid solution to the zinc oxide colloidal solution and adjusting the pH value of the zinc oxide colloidal solution to be between 7 and 8, the acid solution is added to the zinc oxide colloidal solution to obtain the mixed solution with a pH value between 7.2 and 7.8.

In some embodiments, in the step of adding the acid solution to the zinc oxide colloidal solution and adjusting the pH value of the zinc oxide colloidal solution to be between 7 and 8, the acid solution is added to the zinc oxide colloidal solution to obtain the mixed solution with a pH value between 7.3 and 7.6.

In some embodiments, the acid in the acid solution is selected from at least one of hydrochloric acid, sulfuric acid, nitric acid, hydrofluoric acid, formic acid, acetic acid, propionic acid, oxalic acid, and propylene.

In some embodiments, the alkaline liquor is selected from at least one of potassium hydroxide, sodium hydroxide, Lithium hydroxide, TMAH, ammonium hydroxide, ethanolamine, and ethylenediamine.

In some embodiments, the solvent in the zinc salt solution and the solvent in the alkaline solution are independently selected from at least one of water, organic alcohols, organic ethers, and sulfones.

In some embodiments, the solvent in the acid solution is selected from at least one of water, methanol, ethanol, propanol, butanol, ethylene glycol, 2-methoxyethanol and DMSO.

In some embodiments, the zinc oxide film with the surface hydroxyl content less than or equal to 0.4 is the metal doped zinc oxide film, and the zinc salt solution contains doped metal ions, too.

In the above embodiments, the metal doped zinc oxide film refers to the above descriptions, and is not repeatedly described herein in order to save space.

It should be understood that in the aforesaid two embodiments of the present application, when the device is the non-inverted QLED, after the ETL is prepared, evaporating a cathode on the ETL to obtain the QLED is further included. In some embodiments, the preparation of the electron injection layer on the ETL is further included before the cathode is evaporated. When the device is the inverted QLED, after the ETL is prepared, preparing a two-point luminescent layer on the ETL, and evaporating the anode on the quantum dot luminescent layer to obtain the QLED are further included. In some embodiments, the preparation of the hole functional layer on the quantum dot luminescent layer is further included before the anode is evaporated.

In the embodiment of the present application, the solution processing method is adopted preferably for the formation method of the hole functional layer (including at least one layer of the hole injection layer, the hole transport layer, and the electron barrier layer) and the quantum dot luminescent layer. The solution processing method includes but is not limited to one of the spin coating method, the scratch coating method, the printing method, the spray coating method, the roller coating method, the electrodeposition method, etc.

In the aforesaid implementation method of the present application, the prepared QLED is packaged. Either commonly used machine packaging or manual packaging is used for packaging processing. Preferably, in the environment of packaging processing, both the oxygen content and the water content are below 0.1 ppm to ensure the stability of the QLED device. The curing resin used for packaging is acrylic resin, acrylate resin, or epoxy resin. Resin curing uses UV irradiation, heating, or a combination thereof.

In some embodiments, after the prepared QLED is packaged according to the performance requirement of the QLED device and one or more treatments, including ultraviolet irradiation, heating, positive and negative pressure, external electric field, and external magnetic field, is/are performed on QLED device to improve one or more aspects of the performance of the QLED device. Where the atmosphere during the process can be air or inert gas.

The present application is further described with reference to embodiments.

Firstly, three detection methods used in the embodiments of the present application are introduced:

(1) X-ray photoelectron spectroscopy (XPS) is a surface analysis method, which uses X-rays of certain energy to radiate a sample to excite the inner layer electrons or valence electron of atoms or molecules. The electrons excited by photons are referred to as photoelectrons. The energy and the quantity of photoelectrons can be detected and the composition of the object to be measured is obtained. This technology can effectively distinguish the presence of three chemical states of oxygen in the zinc oxide material, the three chemical states of oxygen are lattice oxygen connected to metal atoms, oxygen defect formed during crystal growth, and hydroxyl oxygen respectively. When the surface hydroxyl testing is performed using the X-ray photoelectron spectroscopy (XPS), with a device model of Thermo Fisher NEXSA. A sample preparation method includes: diluting the prepared zinc oxide solution to 30 mg/mL, spin coating the diluted zinc oxide solution onto a pre-treated glass sheet, and spin coating the zinc oxide solution into a film. Where, a calculation method for hydroxyl content is a ratio of hydroxyl oxygen peak area to lattice oxygen peak area, that is, the ratio of hydroxyl content, which is expressed as

$${R}_{O H} = \frac{{A}_{O H}}{{A}_{M O}} ,$$

as shown in FIG. 11.

(2) a test method for external quantum efficiency (EQE) of JVL (current density-voltage-luminescence) device.

device model: Keithley 2400/6485

The EQE parameters mainly include six parameters of voltage, current, luminescence, external quantum dot efficiency, power efficiency, and luminescence spectrum. A certain voltage output is applied to the device in a black box to enable the device to be conductive and emit light, the current is recorded in time, and the light source is collected through a silicon photodiode. The spectral data is analyzed, color coordinates are obtained, and human vision function G(λ) and normalized electroluminescence spectrum S(λ) are calculated. Thus, the calculation method of the current efficiency ηA is formulized as:

$${η}_{A} = \frac{L}{{J}_{D}}$$

Where, L represents the luminescence read by the silicon photodiode, JD represents the device's current density, which is equal to the ratio of the device area (a) to the current (I) flowing through the device.

The calculation method for the EQE ηEQE is formulized as:

$${η}_{E Q E} = \frac{q π}{h c} \cdot \frac{\int λ S ( λ ) dλ}{\int G ( λ ) S ( λ ) dλ} \cdot {η}_{A}$$

Where, q represents elementary charge, h represents Planck constant, and c represents the speed of light in vacuum.

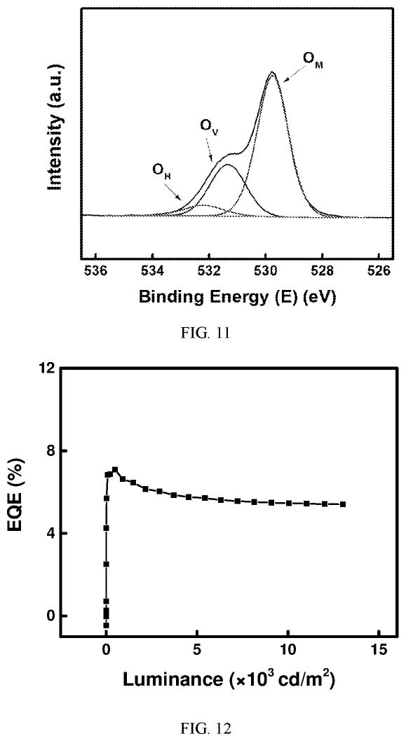

As shown in the embodiment of FIG. 12, the highest value of EQE in the EQE luminescence curve is the external quantum efficiency of the device.

(3) QLED lifetime test system

Model: new vision NVO-QLED-LT-128

Working Principle:

The 128 channel QLED lifetime test system controls a digital IO card of NI (American National Instruments) to realize chip select and output of digital signals through PCI bus communication of a central processing computer. The corresponding digital signal is converted into analog signal through a digital to analog converter chip to complete current output (I), and data acquisition is realized through a data acquisition card. The collection of luminescence is achieved by converting optical signals into electrical signals through sensors, and simulating luminescence changes (L) using the electrical signals.

Test Method:

QLED Lifetime Testing Method (Constant Current Method)

(A) three to four different constant current densities (such as 100 mA cm\hat{ }2, 50 mA cm\hat{ }2, 20 mA cm\hat{ }2, 10 mA cm\hat{ }2) are selected, and the starting luminescence under the corresponding condition is tested.

(B) the constant current is maintained and the changes in luminescence and device voltage over time are recorded.

(C) The time during which the device is decayed to T95, T80, T75, and T50 at different constant currents is recorded.

(D) An acceleration factor is calculated through curve fitting.

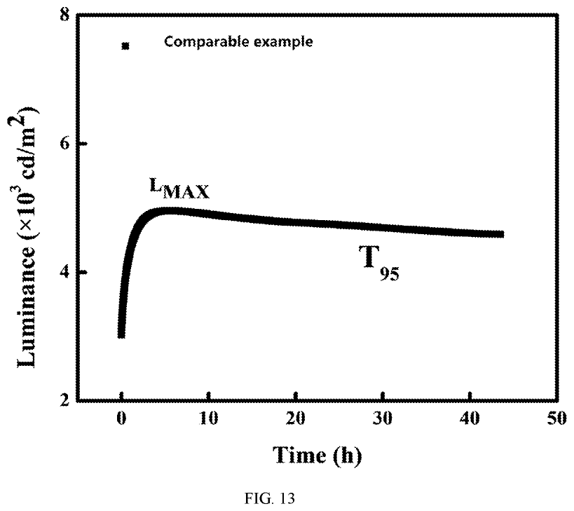

(E) The lifetime of the device 1000 nit T95, T80, T75, and T50 is speculated through empirical formulas, as shown in FIG. 13.

The calculation method is expressed as T_{T95@1000nits}=(L_{MA}/1000)\hat{ }A*T95

Where, L_{MAX}—the highest luminescence

A—the acceleration factor

T95—the time during which the device is decayed from the highest luminescence to 95%.

### Embodiment 1

An quantum dot light-emitting diode (QLED), including an anode substrate and a cathode being oppositely arranged, a quantum dot luminescent layer arranged between the anode and cathode, a hole transport layer arranged between the anode and quantum dot luminescent layer, a hole injection layer arranged between the anode and hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdₓZn₁₋ₓSe/ZnSe (40 nm), the ETL is ZnO material (50 nm) prepared by the following method, and the cathode is Ag electrode (100 nm).

The aforesaid preparation method of the QLED includes:
preparing the hole injection layer, the hole transport layer, and the quantum dot luminescent layer sequentially on the anode substrate;
preparing the ETL on the quantum dot luminescent layer;
evaporating or sputtering a top electrode on a zinc oxide ETL or a doped zinc oxide ETL to obtain the QLED.

Where the preparation method of the ETL is as follows:

Step One:
(A) dissolving a zinc acetate in a dimethyl sulfoxide at room temperature to prepare a zinc salt solution with a concentration of 0.6 mol/L, and dissolving sodium hydroxide in methanol at room temperature to obtain an alkaline solution with a concentration of 0.96 mol/L. The molar ratio of hydroxide ions to zinc ions is 1.6:1;
(B) adjusting the temperature of the zinc salt solution to 40° C., dropping alkali into the zinc salt solution according to the molar ratio of hydroxide ions to zinc ions of 1.6:1, and then continuously stirring the mixed solution for reacting for 90 minutes when the reaction temperature is kept at 40° C.;
(C) After adding the precipitating agent with a volume ratio of 4.5:1 to the mixed solution after the reaction, white precipitates are generated in the mixed solution.
(D) dissolving the obtained white precipitates, adding a potassium hydroxide solution with a concentration of 0.2 mol/L to the zinc oxide colloidal solution to adjust the pH value of the solution to 8, thereby obtaining a zinc oxide colloidal solution with a hydroxyl content of 0.85.

Step Two:

Forming the zinc oxide colloidal solution on the quantum dot luminescent layer, removing the solvent to prepare the zinc oxide film with the surface hydroxyl content of 0.85, that is, the ETL. The thickness of the zinc oxide film is 50 nm.

X-ray photoelectron spectroscopy (XPS) is used to detect the hydroxyl groups in the zinc oxide used for preparing the ETL, and the hydroxyl content of the ETL was determined as 0.85.

### Comparative Example 1

The difference between the comparative example 1 and the embodiment 1 lies in the use of commercially available ordinary zinc oxide nanoparticles as the ETL material. X-ray photoelectron spectroscopy (XPS) is used to detect hydroxyl groups in the zinc oxide used for preparing the ETL, and the hydroxyl content of the ETL is determined as 0.5.

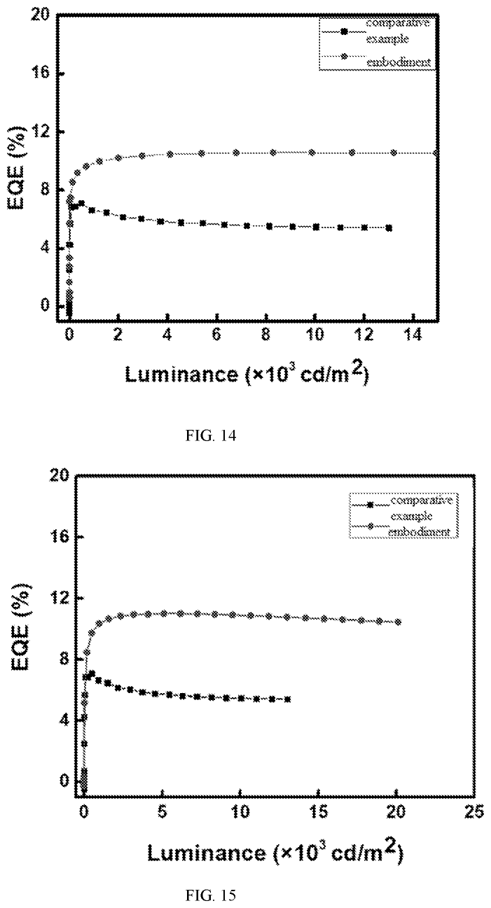

The test results of the lifetimes of the QLED devices provided by the embodiment 1 and the comparative example 1 are shown in FIG. 14.

### Embodiment 2

An quantum dot light-emitting diode (QLED), including an anode substrate and a cathode being oppositely arranged, a quantum dot luminescent layer arranged between the anode and cathode, a hole transport layer arranged between the anode and quantum dot luminescent layer, a hole injection layer arranged between the anode and the hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdₓZn₁₋ₓSe/ZnSe (40 nm), the ETL is the ZnO material prepared by the following method, and the cathode is Ag electrode (100 nm).

The aforesaid preparation method of the QLED includes:
preparing the hole injection layer, the hole transport layer, and the quantum dot luminescent layer sequentially on the anode substrate;
preparing the ETL on the quantum dot luminescent layer;
evaporating or sputtering a top electrode on a zinc oxide ETL or a doped zinc oxide ETL to obtain the QLED.

Where, the preparation method of the ETL is as follows:
(1) (A) dissolving a zinc acetate in a dimethyl sulfoxide at room temperature to prepare a zinc salt solution with a concentration of 0.5 mol/L, and dissolving sodium hydroxide in methanol at room temperature to obtain an alkaline solution with a concentration of 0.85 mol/L. The molar ratio of hydroxide ions to zinc ions is 1.7:1;
(B) adjusting the temperature of the zinc salt solution to 60° C., dropping alkali into the zinc salt solution according to the molar ratio of hydroxide ions to zinc ions of 1.7:1, and then continuously stirring the mixed solution for reacting for 90 minutes when the reaction temperature is kept at 60° C.;
(C) generating white precipitates in the mixed solution after adding the precipitating agent with a volume ratio of 3:1 to the mixed solution after the reaction.
(D) dissolving the obtained white precipitates to obtain a zinc oxide colloidal solution with a concentration of 0.6 mol/L.
(2) (A) dissolving the zinc acetate in the dimethyl sulfoxide at room temperature to prepare a zinc salt solution with a concentration of 0.5 mol/L, and dissolving the potassium hydroxide in the methanol at room temperature to obtain an alkaline solution with a concentration of 0.85 mol/L. The molar ratio of hydroxide ions to zinc ions is 1.7:1;
(B) Adjusting the temperature of the zinc salt solution to 60° C., adding alkali droplets into the zinc salt solution according to the molar ratio of hydroxide ions to zinc ions of 1.7:1, and then continuously stirring the mixed solution at the reaction temperature of 60° C. for 90 minutes;
(C) generating white precipitates in the mixed solution after adding a precipitating agent with a volume ratio of 3:1 to the mixed solution after the reaction.
(D) dissolving the obtained white precipitates, adding 0.05 mol/L hydrochloric acid to the zinc oxide colloidal solution to adjust the pH value of the solution to 7.2, and thereby obtaining a second zinc oxide colloidal solution with a hydroxyl content of 0.25;
(3) forming a first zinc oxide colloidal solution on the quantum dot luminescent layer, removing the solvent to prepare a prefabricated zinc oxide film; depositing alkaline liquor on the surface of prefabricated zinc oxide film, the alkaline liquor is 0.05 mol/L potassium hydroxide solution, and the deposition amount of the alkaline liquor and the weight of the lower layer of the prefabricated zinc oxide film meet the following requirement: every 20 v L alkaline solution is used for treatment for every 5 mg of the prefabricated zinc oxide film; performing heating at a temperature of 80° C. for 30 minutes, removing the solvent to prepare the first zinc oxide film with the surface hydroxyl content of 0.85, that is, the first ETL; forming a second zinc oxide colloidal solution on the first zinc oxide film, and removing the solvent to prepare a second zinc oxide film with a surface hydroxyl content of 0.25, that is, the second ETL. The thickness of the first zinc oxide layer is 60 nm, and the thickness of the second zinc oxide layer is 40 nm.

X-ray photoelectron spectroscopy (XPS) is used to detect the hydroxyl groups in the zinc oxide used for preparing the first ETL and the second ETL, the hydroxyl content of the first ETL was determined as 0.85, and the hydroxyl content of the second ETL was determined as 0.25.

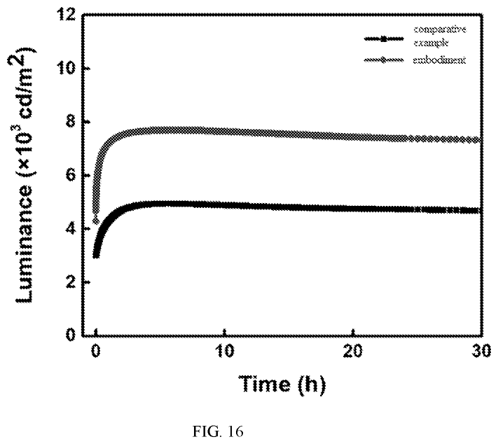

The test results of EQEs of the QLED devices provided by the embodiment 2 and the comparative example 1 are shown in FIG. 15. The test results of the lifetimes of the QLED devices provided by the embodiment 2 and the comparative example 1 are shown in FIG. 16.

### Embodiment 3

A quantum dot light-emitting diode (QLED) includes an anode substrate and a cathode being oppositely arranged, a quantum dot luminescent layer arranged between the anode and cathode, a hole transport layer arranged between the anode and quantum dot luminescent layer, a hole injection layer arranged between the anode and hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdxZn1−xSe/ZnSe (40 nm), the ETL is ZnO material prepared by the following method, and the cathode is Ag electrode (100 nm).

The aforesaid preparation method of the QLED includes:
preparing the hole injection layer, the hole transport layer, and the quantum dot luminescent layer sequentially on the anode substrate;
preparing the ETL on the quantum dot luminescent layer;
evaporating or sputtering a top electrode on a zinc oxide ETL or a doped zinc oxide ETL to obtain the QLED.

Where, the preparation method of the ETL is as follows:
(1) (A) dissolving a zinc acetate in a dimethyl sulfoxide at room temperature to prepare a zinc salt solution with a concentration of 0.5 mol/L, and dissolving the sodium hydroxide in methanol at room temperature to obtain an alkaline solution with a concentration of 0.85 mol/L. The molar ratio of hydroxide ions to the zinc ions is 1.7:1;
(B) adjusting the temperature of the zinc salt solution to 60° C., adding alkali droplets into the zinc salt solution according to the molar ratio of hydroxide ions to zinc ions of 1.7:1, and then continuously stirring the mixed solution at the reaction temperature of 60° C. for 90 minutes;
(C) generating white precipitates in the mixed solution after adding a precipitating agent with a volume ratio of 3:1 to the mixed solution after the reaction, dissolving the white obtained precipitate to obtain a first zinc oxide colloidal solution with a surface hydroxyl content of 0.88, after cleaning the precipitate with a reaction solvent of methanol for one time.
(2) (A) dissolving a zinc acetate in a dimethyl sulfoxide at room temperature to prepare a zinc salt solution with a concentration of 0.5 mol/L, and dissolving a sodium hydroxide in a methanol at room temperature to obtain an alkaline solution with a concentration of 0.85 mol/L. The molar ratio of hydroxide ions to zinc ions is 1.7:1;
(B) adjusting the temperature of the zinc salt solution to 60° C., adding alkali droplets into the zinc salt solution according to the molar ratio of hydroxide ions to zinc ions of 1.7:1, and then continuously stirring the mixed solution at the reaction temperature of 60° C. for 90 minutes;
(C) generating white precipitates in the mixed solution, after adding a precipitating agent with a volume ratio of 4:1 to the mixed solution after the reaction;
(D) dissolving the obtained white precipitates, adding 0.05 mol/L hydrochloric acid to the zinc oxide colloidal solution to adjust the pH value of the solution to 7.2, thereby obtaining a second zinc oxide colloidal solution with a hydroxyl content of 0.22.
(3) (A) Dissolving the zinc acetate in the dimethyl sulfoxide at room temperature to prepare the zinc salt solution with the concentration of 0.5 mol/L, and dissolving the sodium hydroxide in the methanol at room temperature to obtain the alkaline solution with the concentration of 0.85 mol/L. The molar ratio of hydroxide ions to zinc ions is 1.7:1;
(B) adjusting the temperature of the zinc salt solution to 60° C., adding the alkali droplets into the zinc salt solution according to the molar ratio of hydroxide ions to zinc ions of 1.7:1, and then continuously stirring the mixed solution at the reaction temperature of 60° C. for 90 minutes;
(C) generating white precipitates in the mixed solution, after adding the precipitation agent with the volume ratio of 3:1 to the mixed solution after the reaction.
(D) dissolving the obtained white precipitates, adding 0.05 mol/L potassium hydroxide solution to the zinc oxide colloidal solution to adjust the pH of the solution to 8.2, thereby obtaining the second zinc oxide colloidal solution with 0.85 hydroxyl content.
(4) Forming a first zinc oxide colloidal solution on the quantum dot luminescent layer, removing the solvent to prepare the first zinc oxide film with the surface hydroxyl content of 0.88; forming a second zinc oxide colloidal solution on the first zinc oxide film, removing the solvent to prepare the second zinc oxide film with the surface hydroxyl content of 0.22; forming a third zinc oxide colloidal solution on the second zinc oxide film, and removing the solvent to prepare the third zinc oxide film with the surface hydroxyl content of 0.85. The thickness of the first zinc oxide layer is 30 nm, the thickness of the second zinc oxide layer is 60 nm, and the thickness of the third zinc oxide layer is 30 nm.

The X-ray photoelectron spectroscopy (XPS) is used to detect the hydroxyl groups in the prepared first ETL, the second ETL, and the third ETL. The hydroxyl content of the first ETL is determined as 0.88, the hydroxyl content of the second ETL is determined as 0.22, and the hydroxyl content of the third ETL is determined as 0.85.

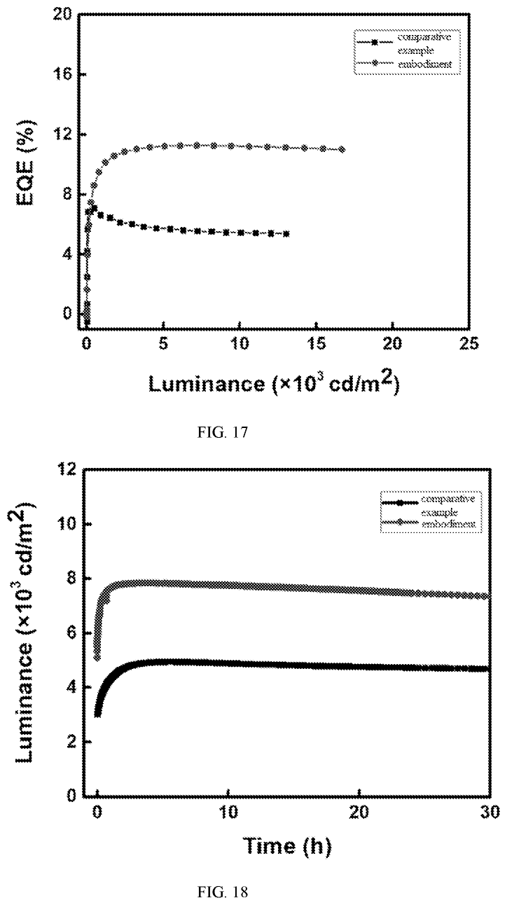

The test results of EQEs of the QLED devices provided by the embodiment 3 and the comparative example 1 are shown in FIG. 17. The test results of the lifetimes of the QLED devices provided by the embodiment 3 and the comparative example 1 are shown in FIG. 18.

performance tests are performed on the QLEDs provided by the aforesaid three examples and the comparative example 1, and the test results are shown in Table 2 below:

| Sample | EQE (%) | Lifetime T95@1000nit (h) | ${R}_{OH} = \frac{{A}_{OH}}{{A}_{MO}}$ |
|---|---|---|---|
| Embodiment 1 | 10.57 | | 0.85 |
| Comparative | 7.09 | 237 | 0.5 |
| example 1 | | | |
| Embodiment 2 | 11.57 | 780 | |
| Embodiment 3 | 13.96 | 989 | |

It should be understood that the testing of the lifetime of the QLED device is different from the characterization of the efficiency of the QLED device. The time for testing the efficiency of the device is usually shorter. Thus, the testing characterizes an initial instantaneous state of the operation of the QLED device. The lifetime of the device characterizes the device's ability to maintain device efficiency after the device is continuously operated and enters a stable state. That is, the lifetime of the device characterizes the balance of carrier injection in the device after entering the stable operating state.

### Embodiment 4

A quantum dot light-emitting diode (QLED) includes an anode substrate and a cathode being oppositely arranged, a quantum dot luminescent layer arranged between the anode and cathode, a hole transport layer arranged between the anode and quantum dot luminescent layer, a hole injection layer arranged between the anode and hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdxZn₁₋ₓSe/ZnSe (40 nm), the ETL is ZnO material (50 nm) prepared by the following method, and the cathode is Ag electrode (100 nm).

The aforesaid preparation method of the QLED mentioned includes:
preparing the hole injection layer, the hole transport layer, and the quantum dot luminescent layer sequentially on the anode substrate;
preparing the ETL on the quantum dot luminescent layer;
evaporation or sputtering the top electrode on the zinc oxide ETL or the doped zinc oxide ETL to obtain the QLED.

The preparation method of the ETL is as follows:
(1) (A) dissolving the zinc acetate dihydrate in the dimethyl sulfoxide at room temperature to prepare the zinc salt solution with a concentration of 0.4 mol/L, and dissolving the lithium hydroxide in the butanol at room temperature to obtain an alkaline solution with a concentration of 0.7 mol/L. The molar ratio of hydroxide ions to zinc ions is 1.75:1;
(B) adjusting the temperature of the zinc salt solution to 40° C., and adding alkali droplets to the zinc salt solution in a molar ratio of hydroxide ions to zinc ions of 1.75:1, then, adding oil amine (0.4 mol/L) for mixture; where the additive amount of oil amino ligands meets the following requirement: the molar ratio of the oil amino ligands to zinc salts in the zinc salt solution is 2:1, and the mixed solution is continuously stirred at a reaction temperature of 40° C. for 120 minutes;
(C) generating white precipitates in the mixed solution after adding the precipitate with a volume ratio of 5:1 to the mixed solution after the reaction.
(D) dissolving the obtained white precipitates to obtain the zinc oxide colloidal solution with a concentration of 0.6 mol/L;
(2) forming a zinc oxide colloidal solution on the quantum dot luminescent layer, and drying the zinc oxide colloidal solution at a temperature of 100° C. to obtain a zinc oxide film with a thickness of 50 nm, that is, the ETL.

### Comparative Example 2

What is different from the embodiment 4 lies in the use of commercially available zinc oxide nanoparticles as the ETL material.

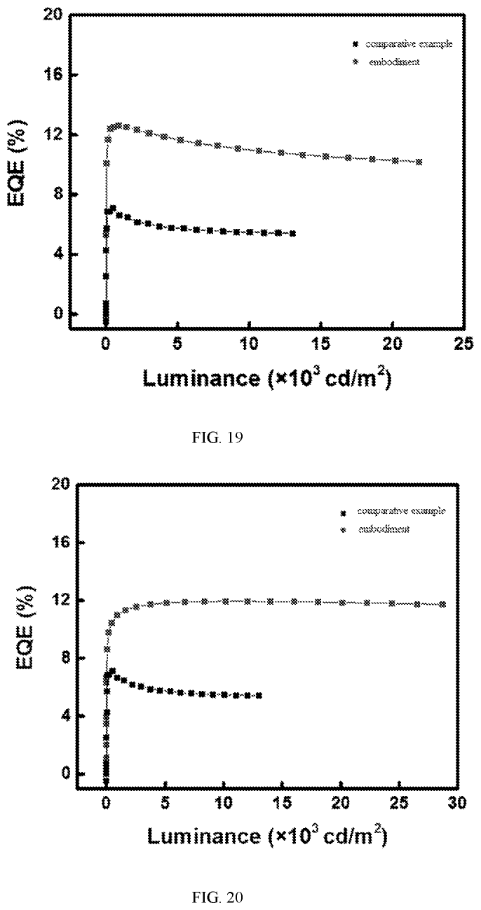

The EQE results of the QLED devices provided by the embodiment 4 and the comparative example 2 are shown in FIG. 19.

### Embodiment 5

A quantum dot light-emitting diode (QLED) includes an anode substrate and cathode being oppositely arranged, a quantum dot luminescent layer arranged between the anode and cathode, a hole transport layer arranged between the anode and quantum dot luminescent layer, a hole injection layer arranged between the anode and hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdxZn₁₋ₓSe/ZnSe (40 nm), the ETL is the ZnO material prepared by the following method, and the cathode is Ag electrode (100 nm).

The aforesaid preparation method of the QLED includes:
preparing the hole injection layer, the hole transport layer, and the quantum dot luminescent layer sequentially on the anode substrate;
preparing the ETL on the quantum dot luminescent layer;
evaporation or sputtering the top electrode on the zinc oxide ETL or the doped zinc oxide ETL to obtain the QLED.

Where the preparation method of the ETL is as follows:
(1) (A) dissolving the zinc acetate dihydrate in the dimethyl sulfoxide at room temperature to prepare a zinc salt solution with a concentration of 0.4 mol/L, and dissolving a lithium hydroxide in a butanol at room temperature to obtain an alkaline solution with a concentration of 0.7 mol/L. The molar ratio of hydroxide ions to zinc ions is 1.75:1;
(B) adjusting the temperature of the zinc salt solution to 40° C., adding alkali droplets into the zinc salt solution according to the molar ratio of hydroxide ions to zinc ions of 1.75:1, and then adding oleic acid (0.4 mol/L) for mixture; where the additive amount of the oleic acid ligands meets the following requirement: the molar ratio of the oleic acid ligands to the zinc salts in the zinc salt solution is 1:1, and stirring the mixed solution continuously under the condition that the reaction temperature is kept at 40° C. for 120 min;
(C) generating white precipitates in the mixed solution, after adding the precipitate with the volume ratio of 5:1 to the mixed solution after the reaction.
(D) dissolving the obtained white precipitates to obtain the zinc oxide colloidal solution with the concentration of 0.6 mol/L.
(2) forming the zinc oxide colloidal solution on the quantum dot luminescent layer, and drying the zinc oxide colloidal solution at a temperature of 100° C. to obtain a zinc oxide film with a thickness of 50 nm, that is, the ETL.

The EQE results of the QLED devices provided by the embodiment 5 and the comparative example 2 are shown in FIG. 20.

### Embodiment 6

A quantum dot light-emitting diode (QLED) includes an anode substrate and a cathode being oppositely arranged, a quantum dot luminescent layer arranged between the anode and cathode, a hole transport layer arranged between the anode and quantum dot luminescent layer, a hole injection layer arranged between the anode and hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdxZn₁₋ₓSe/ZnSe (40 nm), the ETL is the ZnO material prepared by the following method, and the cathode is Ag electrode (100 nm).

The aforesaid preparation method of the QLED includes:
preparing the hole injection layer, the hole transport layer, and the quantum dot luminescent layer sequentially on the anode substrate;
preparing the ETL on the quantum dot luminescent layer;
evaporation or sputtering the top electrode on the zinc oxide ETL or the doped zinc oxide ETL to obtain the QLED.

The preparation method of the ETL is as follows:
(1) (A) Dissolving the zinc acetate dihydrate in the dimethyl sulfoxide at room temperature to prepare a zinc salt solution with a concentration of 0.5 mol/L, and dissolving the lithium hydroxide in the butanol at room temperature to obtain an alkaline solution with a concentration of 0.9 mol/L. The molar ratio of hydroxide ions to zinc ions is 1.8:1;
(B) adjusting the temperature of the zinc salt solution to 40° C., adding alkali droplets into the zinc salt solution according to the molar ratio of hydroxide ions to zinc ions of 1.8:1, and then continuously stirring the mixed solution under the condition that the reaction temperature is kept at 30° C., and reacting for 80 minutes;
(C) generating white precipitates in the mixed solution after adding a precipitation agent with a volume ratio of 4:1 to the mixed solution after the reaction.
(D) dissolving the obtained white precipitates to obtain a zinc oxide colloidal solution with a concentration of 0.6 mol/L.
(2) Forming a first zinc oxide colloidal solution on the quantum dot luminescent layer, removing the solvent to prepare the prefabricated zinc oxide film; depositing oil amine solution (0.4 mol/L) on the surface of the prefabricated zinc oxide film, where the deposition amount of the oil amine solution and the weight of the lower layer of the prefabricated zinc oxide film meet the following requirement: for every 5 mg of prefabricated zinc oxide film, 40 μL oil amine solution is used for treatment and reacted for 20 minutes at a temperature of 120° C., and the solvent is removed to prepare a zinc oxide film with a thickness of 60 nm, that is, the ETL.

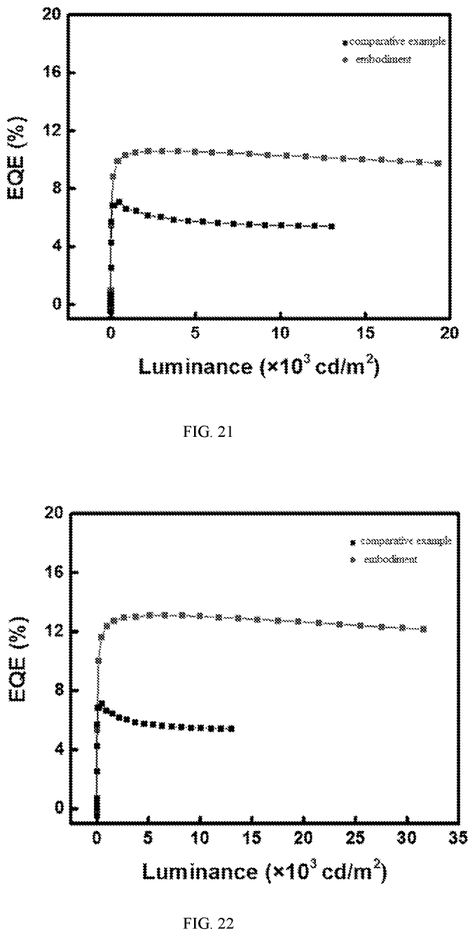

The EQE results of the QLED devices provided by the embodiment 6 and the comparative example 2 are shown in FIG. 21.

### Embodiment 7

A quantum dot light-emitting diode (QLED) includes an anode substrate and a cathode being oppositely arranged, a quantum dot luminescent layer arranged between the anode and cathode, a hole transport layer arranged between the anode and quantum dot luminescent layer, a hole injection layer arranged between the anode and hole transport layer, and an electron transport layer (ETL) arranged between the quantum dot luminescent layer and the cathode. Where the anode is ITO (55 nm), the hole injection layer is PEDOT:PSS (50 nm), the hole transport layer is TFB (30 nm), the quantum dot luminescent layer is red quantum dot CdxZn₁₋ₓSe/ZnSe (40 nm), the ETL is the ZnO material prepared by the following method, and the cathode is Ag electrode (100 nm).

The aforesaid preparation method of the QLED includes:
preparing the hole injection layer, the hole transport layer, and the quantum dot luminescent layer sequentially on the anode substrate;
preparing the ETL on the quantum dot luminescent layer;
evaporation or sputtering the top electrode on the zinc oxide ETL or the doped zinc oxide ETL to obtain the QLED.

The preparation method of the ETL is as follows:
(1) (A) dissolving the zinc acetate dihydrate in the dimethyl sulfoxide at room temperature to prepare a zinc salt solution with a concentration of 0.5 mol/L, and dissolve the lithium hydroxide in the butanol at room temperature to obtain an alkaline solution with a concentration of 0.9 mol/L. The molar ratio of hydroxide ions to zinc ions is 1.8:1;
(B) adjusting the temperature of the zinc salt solution to 40° C., adding alkali droplets into the zinc salt solution according to the molar ratio of hydroxide ions to zinc ions of 1.8:1, and then continuously stirring the mixed solution under the condition that the reaction temperature is kept at 30° C., and reacting for 80 minutes;
(C) generating white precipitates in the mixed solution after adding the precipitation agent with the volume ratio of 4:1 to the mixed solution after the reaction.
(D) dissolving the obtained white precipitates to obtain the zinc oxide colloidal solution with the concentration of 0.6 mol/L;
(2) forming the first zinc oxide colloidal solution on the quantum dot luminescent layer, removing the solvent to prepare a prefabricated zinc oxide film; depositing oleic acid solution (0.4 mol/L) on the surface of prefabricated zinc oxide film, where the deposition amount of the oleic acid solution and the weight of the lower layer of the prefabricated zinc oxide film meet the following requirement: for every 5 mg of prefabricated zinc oxide film, 30 μL of oleic acid solution is used for treatment and reacting for 20 minutes at a temperature of 120° C. The solvent was removed to prepare a zinc oxide film with a thickness of 60 nm, and the ETL.

The EQE results of the QLED devices provided by the embodiment 7 and the comparative example 2 are shown in FIG. 22.

The EQEs of the QLED devices provided by the aforesaid embodiment 4, embodiment 5, embodiment 6 and embodiment 7 and the comparative example 2 are tested using a JVL (current density-voltage-luminescence) device EQE test method, which have been described above.

The test results of the QLEDs provided by the four embodiments and the comparative examples are shown in table 3 below:

| Sample | External quantum efficiency EQE |
|---|---|
| Embodiment 1 | 12.62% |
| Comparative example 1 | 7.09% |
| Embodiment 2 | 11.95% |
| Embodiment 3 | 10.58% |
| Embodiment 4 | 13.12% |

It should be understood that the testing of the lifetime of the QLED device is different from the characterization of the efficiency of the QLED device. The time for testing the efficiency of the device is usually shorter. Thus, the testing characterizes an initial instantaneous state of the operation of the QLED device. The lifetime of the device characterizes the device's ability to maintain device efficiency after the device is continuously operated and enters a stable state. That is, the lifetime of the device characterizes the balance of carrier injection in the device after entering the stable operating state.

The foregoing only includes preferable embodiments of the present application and is not intended to limit the present application. Any modification, equivalent substitution, and improvement, which are made within the spirit and principle of the present application, should all be included in the scope of protection of the present application.

What is claimed is:

1. A quantum dot light-emitting diode (QLED), comprising an anode and a cathode being oppositely arranged, a quantum dot luminescent layer arranged between the anode and cathode, and an electron transport layer (ETL) arranged between the quantum dot luminescent layer and the cathode;
wherein the ETL comprises a first ETL, and the first ETL is a zinc oxide film with a surface hydroxyl content being greater than or equal to 0.6; or alternatively,
the ETL contains zinc oxide, and a surface of at least some of the zinc oxide contains amino ligands and/or carboxyl ligands with 8-18 carbon atoms.

2. The QLED according to claim 1, wherein the ETL is the first ETL, and the zinc oxide in the first ETL is a metal doped zinc oxide or an undoped zinc oxide.

3. The QLED according to claim 1, wherein when the ETL contains the zinc oxide, the ETL comprises the first ETL containing the zinc oxide, and the surface of the zinc oxide forming the first ETL contains the amino ligands and/or the carboxyl ligands with 8-18 carbon atoms.

4. The QLED according to claim 3, wherein the ETL is the first ETL, and the zinc oxide forming the first ETL is an undoped zinc oxide or a metal doped zinc oxide.

5. The QLED according to claim 1, wherein the ETL further comprises a second ETL arranged on a surface of one side of the first ETL adjacent to the cathode or the quantum dot luminescent layer, and wherein the second ETL is a zinc oxide film or a metal doped zinc oxide with a surface hydroxyl content being less than or equal to 0.4.

6. The QLED according to claim 5, wherein the ETL is composed of the first ETL and the second ETL, and the second ETL is more adjacent to the quantum dot luminescent layer as compared to the first ETL.

7. The QLED according to claim 6, wherein the ETL comprises n thin film laminated layer units, each of the n film lamination layer units is composed of the first ETL and the second ETL, wherein n is greater than or equal to 2.

8. The QLED according to claim 5, wherein the ETL further comprises a third ETL.

9. The QLED according to claim 8, wherein the third ETL is a zinc oxide film with a surface hydroxyl content being greater than or equal to 0.6.

10. The QLED according to claim 9, wherein the third ETL is arranged on a surface of a side of the second ETL away from the first ETL, and the second ETL is a zinc oxide film with a surface hydroxyl content less than or equal to 0.4.

11-26. (canceled)

27. A preparation method of a quantum dot light-emitting diode (QLED), wherein the QLED comprises an anode and a cathode being oppositely arranged, a quantum dot luminescent layer arranged between the anode and cathode, and an electron transport layer (ETL) arranged between the quantum dot luminescent layer and the cathode; wherein the ETL comprises a first ETL, and the first ETL is a zinc oxide film with a surface hydroxyl content being greater than or equal to 0.6;
a preparation method of the zinc oxide film with the surface hydroxyl content being greater than or equal to 0.6, comprises:
mixing a zinc salt solution with a first alkaline solution for reaction, and adding a precipitating agent to the mixed solution to collect a precipitate after the reaction is completed; after cleaning the precipitate two times or less than two times with a reaction solvent, dissolving obtained white precipitate to obtain a zinc oxide colloidal solution; and
forming the zinc oxide colloidal solution on a prefabricated device substrate for preparing the zinc oxide film with a surface hydroxyl content being greater than or equal to 0.6, removing a solvent to prepare the zinc oxide film with the surface hydroxyl content being greater than or equal to 0.6.

28. The preparation method of the QLED according to claim 27, wherein an alkali in the first alkaline solution is selected from alkalis with K_{b}>10⁻¹, and a number of times of cleaning is less than or equal to 2; or
the alkali in the first alkaline solution is selected from alkalis with K^{b}<10⁻¹, and the number of times of cleaning is less than or equal to 1.

29. The preparation method of the QLED according to claim 28, wherein the alkalis with K_{b}>10⁻¹ is selected from at least one of potassium hydroxide, sodium hydroxide and Lithium hydroxide, and the alkalis with K_{b}<10⁻¹ is selected from at least one of tetramethylammonium hydroxide (TMAH), ammonium hydroxide, ethanolamine and ethylenediamine.

30. The preparation method of the QLED according to claim 29, wherein the reaction solvent is selected from at least one of water, organic alcohols, organic ethers, and sulfones.

31. The preparation method of the QLED according to claim 30, wherein the reaction solvent is selected from at least one of water, methanol, ethanol, propanol, butanol, ethylene glycol, 2-methoxyethanol and dimethylsulfoxide (DMSO).

32. The preparation method of the QLED according to claim 27, wherein, in the step of mixing the zinc salt solution with the first alkaline solution, mixing the zinc salt solution with the first alkaline solution according to a molar ratio of 1.5:1 to 2.5:1 of Hydroxide ions to zinc ions.

33. The preparation method of the QLED according to claim 27, wherein the zinc oxide film with the surface hydroxyl content being greater than or equal to 0.6 is the metal doped zinc oxide film, and the zinc salt solution contains doped metal ions, either.

34. A preparation method of an QLED, wherein the QLED comprises an anode and a cathode being oppositely arranged, a quantum dot luminescent layer arranged between the anode and cathode, and an electron transport layer (ETL) arranged between the quantum dot luminescent layer and the cathode; wherein the ETL comprises a first ETL, and a surface of zinc oxide that forms the first ETL is bonded with amino ligands and/or carboxyl ligands with 8-18 carbon atoms;
a preparation method of the first ETL comprises:
preparing a zinc oxide colloidal solution through a solution method by using a zinc salt solution, an alkaline solution, and amino ligands and/or carboxyl ligands with 8-18 carbon atoms as raw materials; wherein the zinc oxide surface in the zinc oxide solution is bonded with the amino ligands and/or the carboxyl ligands with 8-18 carbon atoms; and
forming the zinc oxide colloidal solution on a prefabricated device substrate for preparing the first ETL, and removing the solvent to obtain the first ETL.

35. The preparation method of the QLED according to claim 34, wherein the step of preparing the zinc oxide colloidal solution through the solution method comprises:
mixing the zinc salt solution, the alkaline solution, with the amino ligands and/or carboxyl ligands with 8-18 carbon atoms for reaction, and preparing zinc oxide nanoparticles having surfaces bonded with the amino ligands and/or the carboxyl ligands with 8-18 carbon atoms; and
dissolving the zinc oxide nanoparticles to obtain the zinc oxide colloidal solution.

36. The preparation method of the QLED according to claim 34, wherein the step of preparing the zinc oxide colloidal solution through the solution method comprises:
mixing the zinc salt solution with the alkaline solution for reaction, and adding the amino ligands and/or the carboxyl ligands with 8-18 carbon atoms during a reaction process to prepare zinc oxide nanoparticles having surfaces bonded with the amino ligands and/or the carboxyl ligands with 8-18 carbon atoms; wherein, a reaction time after adding the amino ligands and/or the carboxyl ligands with 8-18 carbon atoms is greater than or equal to 10 minutes; and
dissolving the zinc oxide nanoparticles to obtain the zinc oxide colloidal solution.

37-69. (canceled)
